(19) United States
(12) Patent Application Publication
(10) Pub. No.: US 2010/0203446 A1
(43) Pub. Date: Aug. 12, 2010

(54) CHEMICALLY AMPLIFIED PHOTORESIST COMPOSITION AND METHOD FOR FORMING PATTERN

(75) Inventors: Koji Ichikawa, Osaka (JP); Masako Sugihara, Nishinomiya-shi (JP); Yusuke Fuji, Osaka (JP)

Correspondence Address: BIRCH STEWART KOLASCH & BIRCH, PO BOX 747, FALLS CHURCH, VA, 22040-0747, US

(73) Assignee: SUMITOMO CHEMICAL COMPANY, LIMITED, Tokyo (JP)

(21) Appl. No.: 12/700,582

(22) Filed: Feb. 4, 2010

(30) Foreign Application Priority Data
Feb. 6, 2009 (JP) JP2009-026231

(51) Int. Cl. G03F 7/20; G03F 7/004

(52) U.S. Cl. 430/270.1; 430/325

(57) ABSTRACT

A chemically amplified photoresist composition, comprises: an acid generator (A) represented by the formula (I), and a resin which comprises a structural unit (b1) derived from a monomer that becomes soluble in an alkali by an action of an acid, a structural unit (b2) derived from a monomer that has an adamantyl group having at least two hydroxyl groups, and a structural unit (b3) derived from a monomer that has a lactone ring;

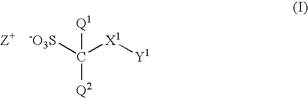

Wherein Q¹ and Q² independently represent a fluorine atom or a C₁ to C₆ perfluoroalkyl group; X¹ represents a single bond or —[CH₂]ₖ—, a —CH₂— contained in the —[CH₂]ₖ— may be replaced by —O— or —CO, and a hydrogen atom contained in the —[CH₂]ₖ— may be replaced by a C₁ to C₄ aliphatic hydrocarbon group; k represents an integer 1 to 17; Y¹ represents an optionally substituted C₄ to C₃₆ saturated cyclic hydrocarbon group, the —CH₂— contained in the saturated cyclic hydrocarbon group may be replaced by —O— or —CO; and Z⁺ represents an organic cation.

### BACKGROUND OF THE INVENTION

1. Field of the Invention

The present invention relates to a chemically amplified photoresist composition and a method for forming pattern, and more specifically to a chemically amplified photoresist composition used in the microfabrication of semiconductors, manufacture of circuit boards such as for liquid crystal display and thermal print heads and the like, and furthermore in other photofabrication processes, and a method for forming pattern using this.

2. Background Information

In the microfabrication of semiconductors, it is preferably for form a and high-resolution pattern, and high resolution, satisfactory line edge roughness, and absence of pattern collapse are required in a chemically amplified photoresist composition.

For example, a chemically amplified photoresist composition was proposed that is composed of a resin from polymerization of a preparation of 2-ethyl-2-adamantyl methacrylate, 3-hydroxy-1-adamantyl methacrylate and α-methacryloyloxy-γ-butyrolactone in a mole ratio of 50:25:25, an acid generator composed of triphenylsulfonium 1-((3-hydroxyadamantyl)methoxycarbonyl) difluoromethanesulfonate, a quencher composed of 2,6-diisopropylaniline and a solvent (for example, patent document: JP2006-257078-A).

Moreover, a chemically amplified photoresist composition was proposed that is composed of a resin composed from the monomers shown below (40:25:8:2 mole % for repeating units), an acid generator composed of triphenylsulfonium perfluorooctanesulfonate and 1-(2-oxo-2-phenylethyl)tetrahydrothiophenium perfluorobutanesulfonate, an amine composed of triphenylimidazole and a solvent (for example, JP-2002-341540-A).

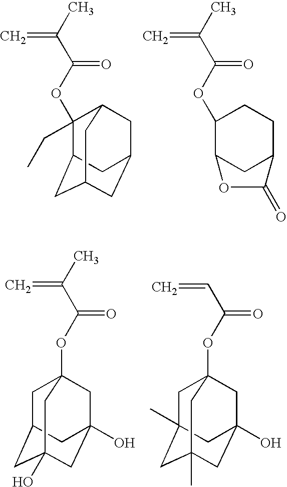

### SUMMARY OF THE INVENTION

The object of the present invention is to provide a chemically amplified photoresist composition that maintains high resolution as is, provides better line edge roughness, and where pattern collapse has been remedied.

The present invention provides following inventions of <1> to <13>.

<1> A chemically amplified photoresist composition, comprising:

an acid generator (A) represented by the formula (I), and

a resin which comprises

a structural unit (b1) derived from a monomer that becomes soluble in an alkali by an action of an acid,

a structural unit (b2) derived from a monomer that has an adamantyl group having at least two hydroxyl groups, and

a structural unit (b3) derived from a monomer that has a lactone ring,

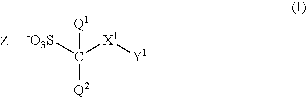

wherein Q¹ and Q² independently represent a fluorine atom or a C₁ to C₆ perfluoroalkyl group;

X¹ represents a single bond or —[CH₂]ₖ—, a —CH₂— contained in the —[CH₂]ₖ— may be replaced by —O— or —CO, and a hydrogen atom contained in the —[CH₂]ₖ— may be replaced by a C₁ to C₄ aliphatic hydrocarbon group;

k represents an integer 1 to 17;

Y¹ represents an optionally substituted C₄ to C₃₆ saturated cyclic hydrocarbon group, and a —CH₂— contained in the saturated cyclic hydrocarbon group may be replaced by —O— or —CO; and

Z⁺ represents an organic cation.

<2> The chemically amplified photoresist composition of <1>, wherein the structural unit (b1) derived from a monomer that becomes soluble in an alkali by the action of the acid represents a structural unit represented by the formula (II);

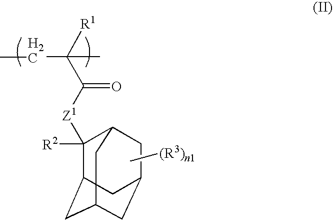

wherein Z¹ represents a single bond or —[CH₂]ₖ₁—, and a —CH₂— contained in the —[CH₂]ₖ₁— may be replaced by —CO—, —O—, —S— or —N[R^{C1}]—;

k1 represents an integer 1 to 17;

R^{c1} represents a hydrogen atom or a C₁ to C₆ aliphatic hydrocarbon group;

R¹ represents a hydrogen atom or a methyl group;

R² represents a C₁ to C₆ aliphatic hydrocarbon group;

R³ represents a methyl group; and

n1 represents an integer 0 to 14.

<3> The chemically amplified photoresist composition of <1> or <2>, wherein the monomer from which the structural unit represented by the formula (II) is derived is 2-methyl-2-adamantylacrylate, 2-methyl-2-adamantylmethacrylate, 2-ethyl-2-adamantylacrylate, 2-ethyl-2-adamantylmethacrylate, 2-isopropyl-2-adamantylacrylate or 2-isopropyl-2-adamantylmethacrylate.

<4> The chemically amplified photoresist composition of any one of <1> to <3>, wherein the structural unit (b2) derived from a monomer that has an adamantyl group having at least two hydroxyl groups represents a structural unit represented by the formula (III);

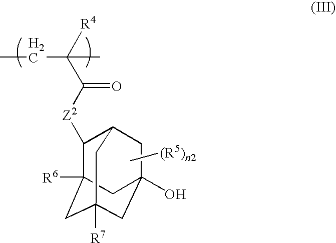

wherein R⁴ represents a hydrogen atom or a methyl group;

R⁵ represents a methyl group;

R⁶ and R⁷ independently represent a hydrogen atom, a methyl group or a hydroxyl group, provided that at least one of either R⁶ and R⁷ represents a hydroxyl group;

n2 represents an integer 0 to 10;

Z² represents a single bond or —[CH₂]ₖ₂—, and a —CH₂— contained in the —[CH₂]ₖ₂— may be replaced by —CO—, —O—, —S— or —N[R^{C2}]—;

K2 represents an integer 1 to 17.

R^{c2} represents a hydrogen atom or a C₁ to C₆ aliphatic hydrocarbon group.

<5> The chemically amplified photoresist composition of any one of <1> to <4>, wherein the monomer from which the structural unit represented by the formula (III) is derived is 3,5-dihydroxy-1-adamantyl acrylate or 3,5-dihydroxy-1-adamantyl methacrylate.

<6> The chemically amplified photoresist composition of any one of <1> to <5>, wherein the structural unit (b3) derived from a monomer that has a lactone ring represents a structural unit represents by the formula (IVa), the formula (IVb) or the formula (IVc);

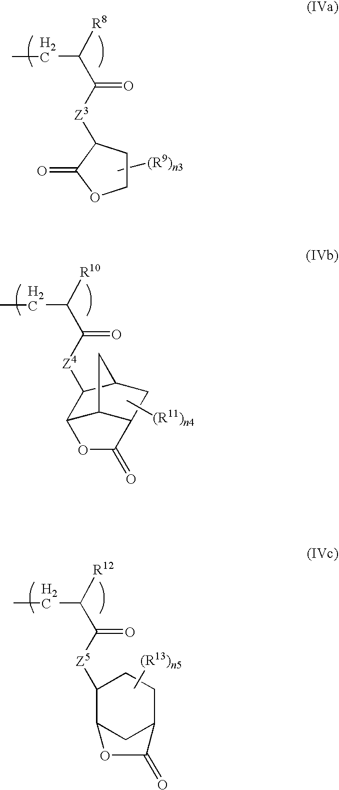

wherein R⁸, R¹⁰ and R¹² independently represent a hydrogen atom or a methyl group;

R⁹ represents a methyl group;

n3 represents an integer 0 to 5,

R¹¹ and R¹³ is independently in each occurrence a carboxy group, a cyano group or a C₁ to C₄ hydrocarbon group;

n4 and n5 represent an integer 0 to 3,

Z³, Z⁴ and Z⁵ independently represent a single bond or —[CH₂]ₖ₃—, and a —CH₂— contained in the —[CH₂]ₖ₃— may be —CO—, —O—, —S— or —N[R^{C3}]—;

k3 represents an integer 1 to 8;

R^{c3} represents a hydrogen atom or a C₁ to C₆ aliphatic hydrocarbon group.

<7> The chemically amplified photoresist composition of any one of <1> to <6>, wherein the Y¹ of the formula (I) is a group represented by the formula (Y1).

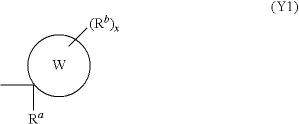

wherein ring W represents a C₃ to C₃₆ saturated cyclic hydrocarbon group, and a —CH₂— contained in the saturated cyclic hydrocarbon group may be replaced by —O— or —CO— group;

R^{a} represents a hydrogen atom or a C₁ to C₆ hydrocarbon group;

R^{b} is independently in each occurrence halogen atom, a C₁ to C₁₂ aliphatic hydrocarbon group, a C₆ to C₂₀ aromatic hydrocarbon group, a C₇ to C₂₁ aralkyl group, a glycidoxy group or a C₂ to C₄ acyl group; and,

x represents an integer 0 to 8.

<8> The chemically amplified photoresist composition of any one of <1> to <7>, wherein the Z⁺ of the formula (I) is an arylsulfonium cation.

<9> The chemically amplified photoresist composition of any one of <1> to <8>, wherein the anion of the formula (I) is an anion having an adamantane structure, an oxoadamantane structure or a cyclohexane structure.

<10> The chemically amplified photoresist composition of any one of <1> to <9>, wherein the content of the acid generator is adjusted to within a range of 1 to 20 parts by weight with respect to the 100 parts by weight of the resin.

<11> The chemically amplified photoresist composition of any one of <1> to <10>, which further contains a nitrogen-containing basic compound.

<12> The chemically amplified photoresist composition of <11>, which the nitrogen-containing basic compound is diisopropylaniline.

<13> A method for forming pattern comprising steps of;

(1) applying the chemically amplified photoresist composition of any one of <1> to <12> onto a substrate;

(2) removing solvent from the applied composition to form a composition layer;

(3) exposing to the composition layer using a exposure device;

(4) heating the exposed composition layer and,

(5) developing the heated composition layer using a developing apparatus.

According to the chemically amplified photoresist composition of the present invention, pattern collapse and defects in the formation of micropatterns due to line edge roughness can be remedied. In addition, patterns with higher resolution can be formed through the use of this chemically amplified photoresist composition.

### DETAILED DESCRIPTION OF THE PREFERRED EMBODIMENTS

The chemically amplified photoresist composition (referred to below simply as “resist composition”) of the present invention contains an acid generator (A) and a resin (B).

In the present specification, unless otherwise noted, when making a suitable choice of carbon number, the exemplified substituent groups are applicable in all of the chemical formulas that have the same substituent groups. Any which are capable of being linear or branched are also included.

Examples of the acid generator (A) include an acid generator represented by the formula (I).

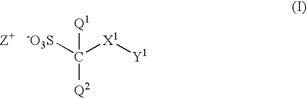

Wherein Q¹ and Q² independently represent a fluorine atom or a C₁ to C₆ perfluoroalkyl group;

X¹ represents a single bond or —[CH₂]ₖ—, a —CH₂— contained in the —[CH₂]ₖ— may be replaced by —O— or —CO—, and a hydrogen atom contained in the —[CH₂]ₖ— may be replaced by a C₁ to C₄ aliphatic hydrocarbon groups;

k represents an integer 1 to 17;

Y¹ represents may be substituted a C₄ to C₃₆ saturated cyclic hydrocarbon group, and a —CH₂— contained in the saturated cyclic hydrocarbon group may be replaced by —O— or —CO—; and

Z⁺ represents an organic cation.

Examples of the perfluoroalkyl group include perfluoromethyl, perfluoroethyl, perfluoro-n-propyl, perfluoro-isopropyl, perfluoro-n-butyl, perfluoro-sec-butyl, perfluoro-tert-butyl, perfluoro-n-pentyl and perfluoro-n-hexyl.

Examples of the —[CH₂]ₖ— include methylene, dimethylene, trimethylene, tetramethylene, pentamethylene, hexamethylene, heptamethylene, octamethylene, nonamethylene, decamethylene, undecamethylene, dodecamethylene, tridecamethylene, tetradecamethylene, pentadecamethylene, hexadecamethylene, heptadecamethylene, ethylene, propylene, isopuropylene, sec-buthylene and tert-buthylene.

Examples of a group in which one —CH₂— contained in the —[CH₂]ₖ— is replaced by —O— or —CO— include —CO—O—X¹¹—(Y¹), —O—CO—X¹¹—(Y¹), —O—X¹¹—(Y¹), —X¹¹—O—(Y¹), —X¹¹—CO—O—(Y¹), —X¹¹—O—CO—(Y¹), X¹¹—O—X¹¹—X¹²—(Y¹), —CO—O—X¹¹—CO—O—(Y¹) and —CO—O—X¹¹—O—(Y¹). Among these, it is preferably —CO—O—X¹¹—(Y¹), —X¹¹—O—(Y¹) and —X¹¹—CO—O—(Y¹), and more preferably —CO—O—X¹¹—(Y¹) and —X¹¹—CO—O—(Y¹), and furthermore preferably —CO—O—X¹¹—(Y¹).

Herein, X¹¹ and X¹² independently represent a C₁ to C₁₅ alkylene group, provided that, for the groups that are the substituted a —CH₂— contained in the alkylene group, the number of atoms constituting the main chain of the abovementioned groups is the same as k, and is 1 to 17.

Examples of the aliphatic hydrocarbon group include an alkyl group such as methyl, ethyl, n-propyl, isopropyl, n-butyl, sec-butyl, tert-butyl, n-pentyl, n-hexyl, heptyl, 2-ethylhexyl, nonyl, decyl, undecyl and dodecyl groups.

Examples of the saturated cyclic hydrocarbon group include cyclopropyl, cyclobutyl, cyclopentyl, cyclohexyl, cycloheptyl, cycloocthyl, cyclononyl, cyclodecyl, norbornyl, 1-adamantyl, 2-adamantyl, isobornyl groups, and following groups.

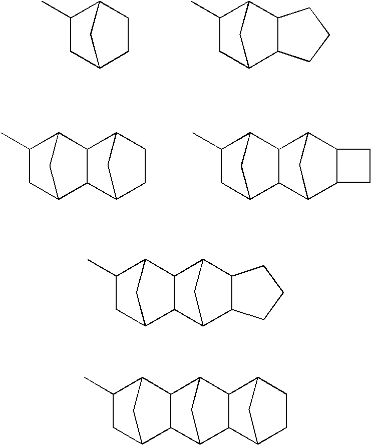

One —CH₂— contained in the saturated cyclic hydrocarbon group may be replaced by —O— or —CO—.

Examples of the substituent of the optionally substituted saturated cyclic hydrocarbon group include a halogen atom, a C₁ to C₆ hydrocarbon group, a C₁ to C₁₂ aliphatic hydrocarbon group, a C₆ to C₂₀ aromatic hydrocarbon group, a C₇ to C₂₁ aralkyl group, a glycidoxy group and a C₂ to C₄ acyl group.

Examples of the halogen atom include fluorine, chlorine, bromine and iodine atoms.

Examples of the hydrocarbon group include aliphatic hydrocarbon groups and cyclic saturated hydrocarbon groups described above.

Examples of the aromatic hydrocarbon group include phenyl, naphthyl, anthranyl, p-methylphenyl, p-tert-butylphenyl and p-adamantylphenyl groups.

Examples of the aralkyl group include benzyl, phenethyl, phenylpropyl, trityl, naphthylmethyl and naphthylethyl groups.

Examples of the acyl group include acetyl, propionyl and butyryl groups.

The Y¹ preferably represents a group represented by the formula (Y1).

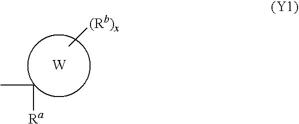

wherein ring W represents a C₃ to C₃₆ saturated cyclic hydrocarbon group, and one —CH₂— contained in the saturated cyclic hydrocarbon group may be replaced by —O— or —CO— group;

R^{a} represents a hydrogen atom or a C₁ to C₆ hydrocarbon group;

R^{b} is independently in each occurrence a halogen atom, a C₁ to C₁₂ aliphatic hydrocarbon group, a C₆ to C₂₀ aromatic hydrocarbon group, a C₇ to C₂₁ aralkyl group, a glycidoxy group or a C₂ to C₄ acyl group; and,

x represents an integer 0 to 8.

Examples of the ring W include a group represented by the formula (W1) to the formula (W25).

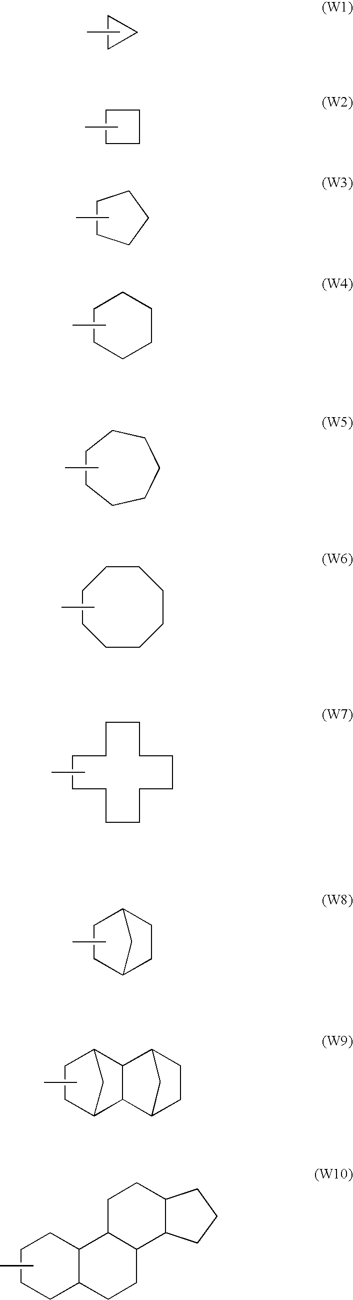

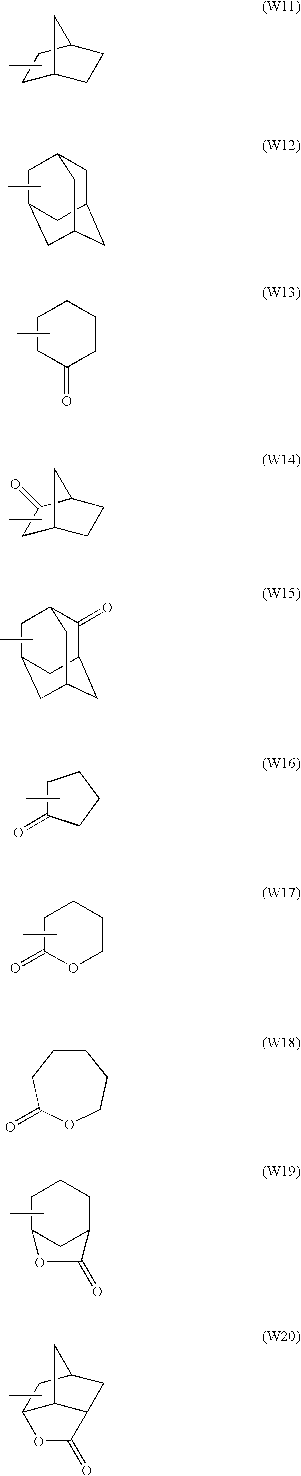

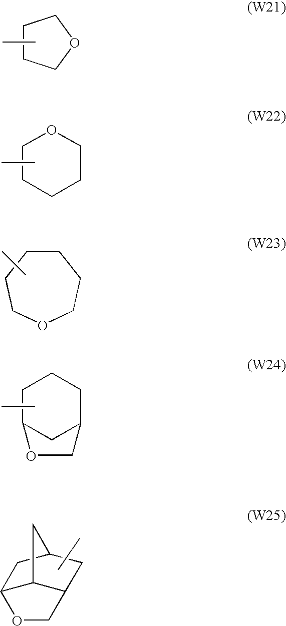

Among these, groups represented by the formula (W12), the formula (W15), the formula (W16) and the formula (W20) are preferable.

Examples of Y¹ group further include;

a group in which a hydrogen atom contained in the ring W is not replaced or is replaced only by a hydrocarbon group, provided that one —CH₂— group contained in the ring W may be replaced by —O—;

a group in which a hydrogen atom contained in the ring W is replaced by a hydroxyl group or a hydroxyl group-containing group, provided that these containing a lactone structure are excluded;

a group having a lactone structure in which two adjacent —CH₂— groups contained in the ring W are replaced by —O— and —CO— group;

a group having a ketone structure in which one —CH₂— group contained in the ring W is replaced by —CO—; and

a group in which a hydrogen atom contained in the ring W is replaced by an aromatic hydrocarbon group.

Examples of Y¹ in which a hydrogen atom contained in the ring W is not replaced or is replaced only by a hydrocarbon group, provided that one —CH₂— group contained in the ring W may be replaced by —O— include the groups below. The bonding hand can be at any desired position other than the positions shown below (likewise below):

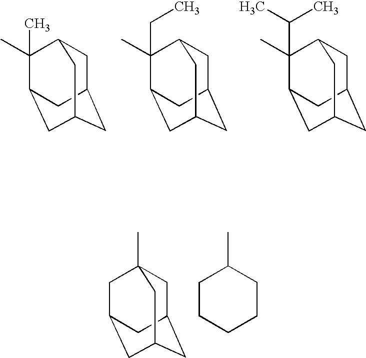

Examples of Y¹ in which a hydrogen atom is substituted with an aromatic hydrocarbon group include the groups below.

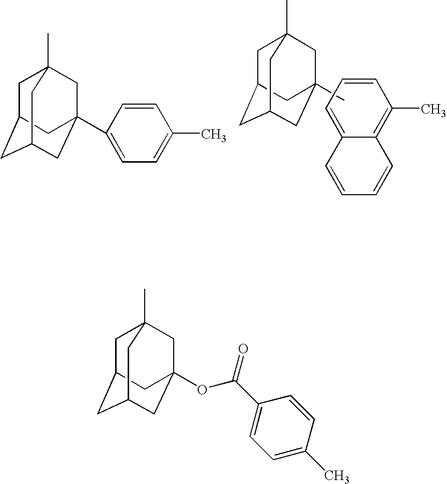

Examples of Y¹ in which a hydrogen atom contained in the ring W is replaced by a hydroxyl group or a hydroxyl group-containing group, provided that these containing a lactone group are excluded, include the groups below.

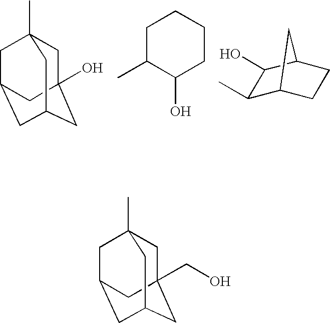

Examples of Y¹ having an ether bond in which one —CH₂— contained in the ring W is replaced by —O— include the groups below.

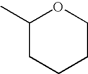

Examples of Y¹ having a lactone structure in which two adjacent —CH₂— contained in the ring W are replaced by —O— and —CO— include the groups below.

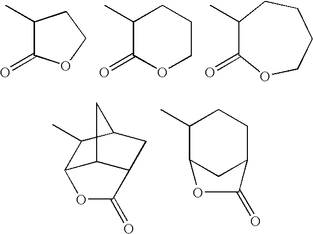

Examples of Y¹ having a ketone structure in which one —CH₂— contained in the ring W is replaced by —CO— include the groups below.

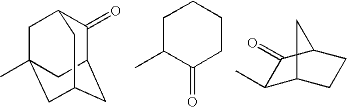

Examples of the anion of the acid generator (A) represented by the formula (I) include the following anions represented by the formula (IA) to the formula (ID).

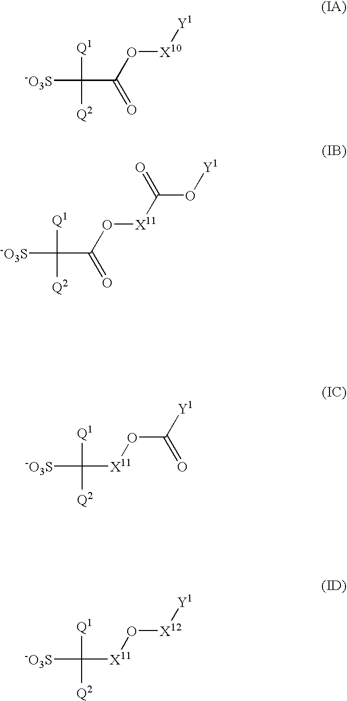

Wherein Q¹, Q² and Y¹ represent the same meaning as defined above formula (I);

X¹⁰ represents a single bond or a C₁ to C₁₅ alkylene group;

X¹¹ and X¹² independently represent a C₁ to C₁₅ alkylene group;

Examples of the alkylene group include methylene, ethylene, n-propylene, isopuropylene, n-buthylene, sec-buthylene, tert-buthylene, n-penthylene and n-hexylene. Among those, the single bond is preferable for the X¹⁰ group.

In the formula (IA), examples of the anion in which a hydrogen atom contained in ring W is replaced only by a hydrocarbon group, provided that a —CH₂— contained in the hydrocarbon group may be replaced by —O—, include the anions below.

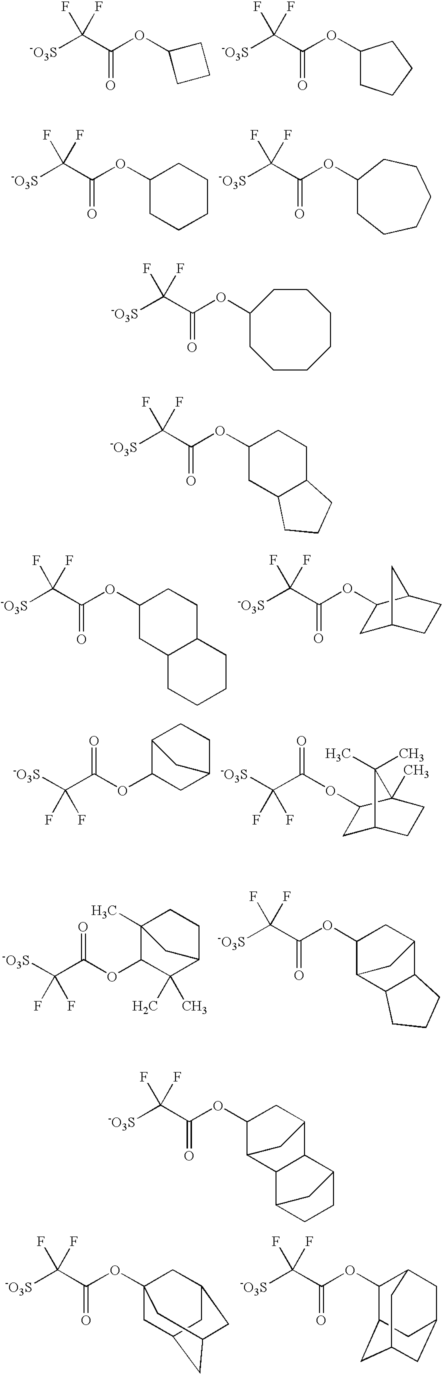

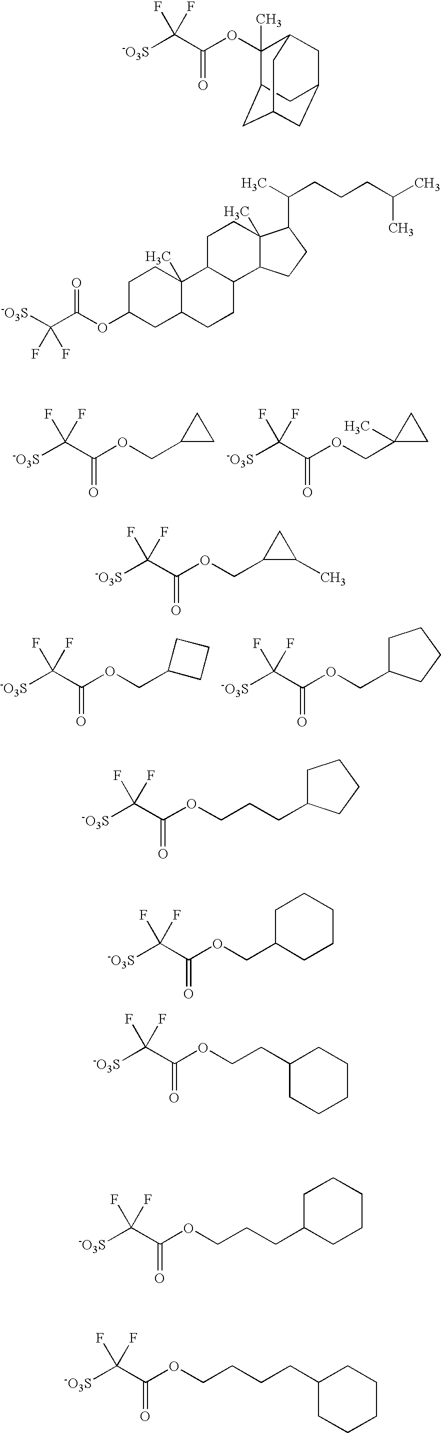

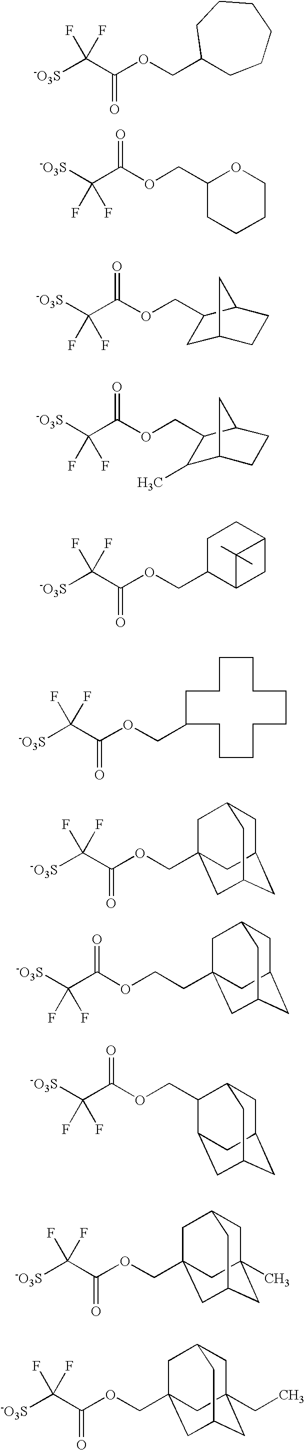

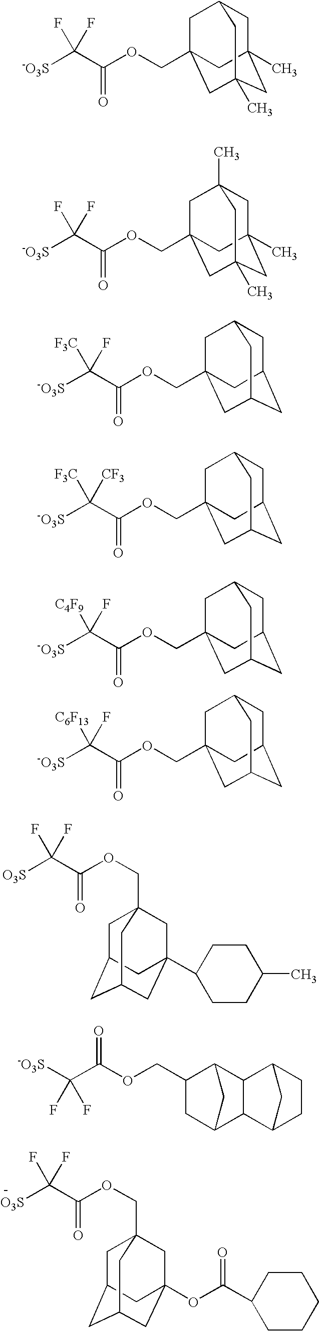

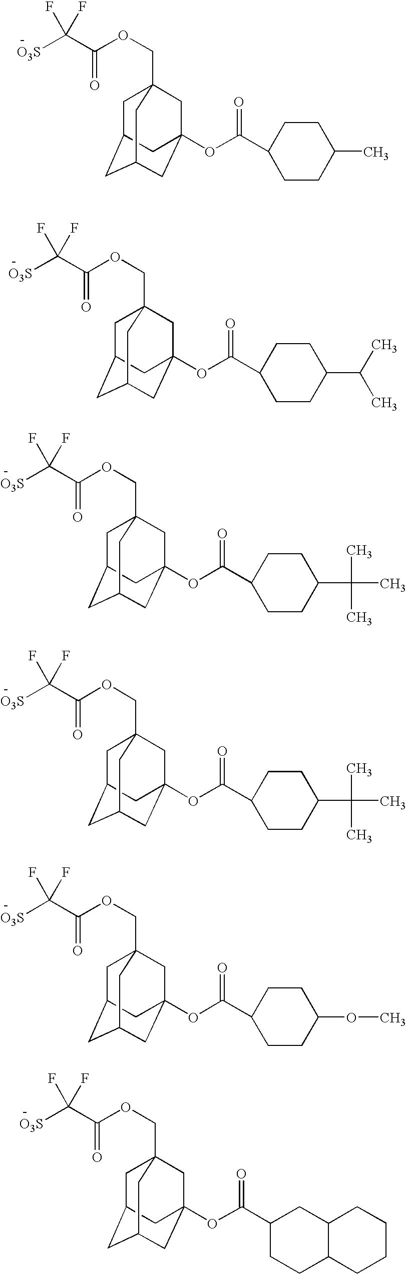

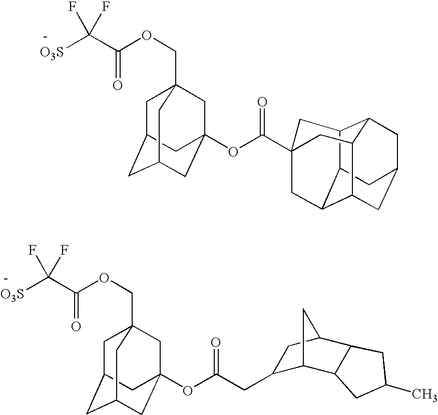

In the formula (IA), examples of the anion in which a hydrogen atom contained in the ring W is replaced by an aromatic hydrocarbon group include the anions below.

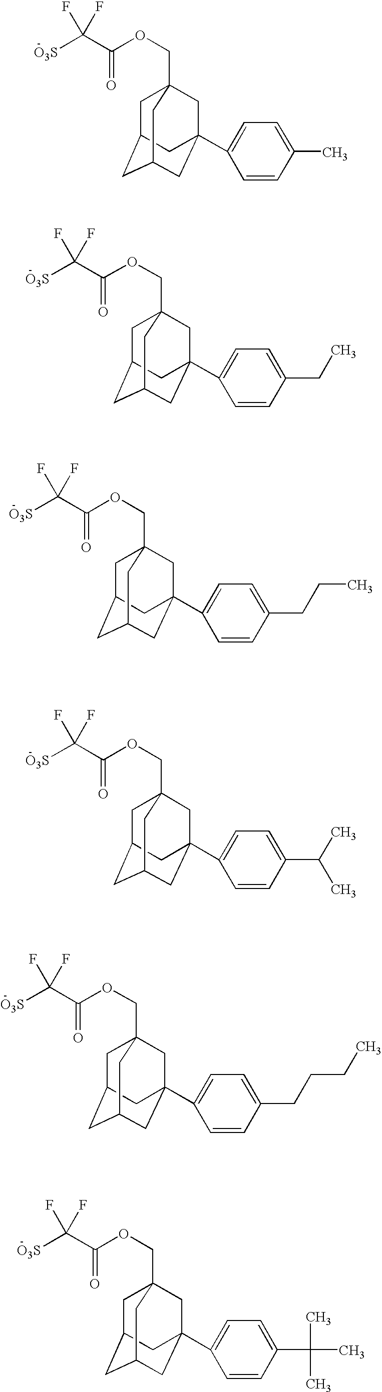

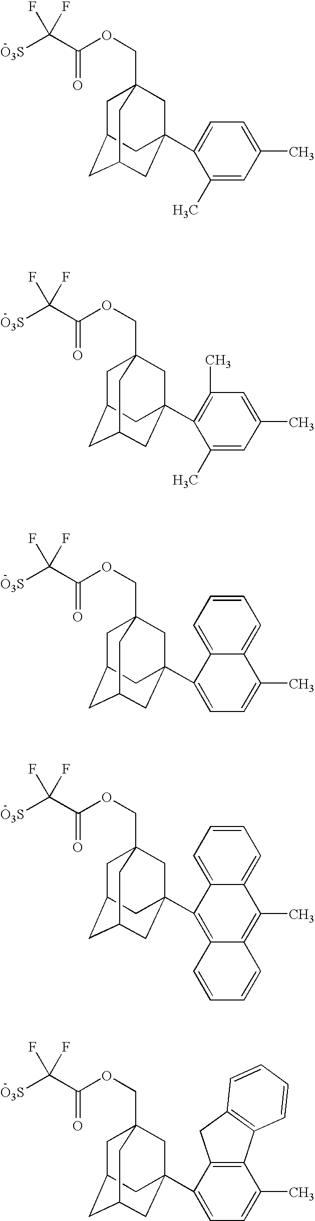

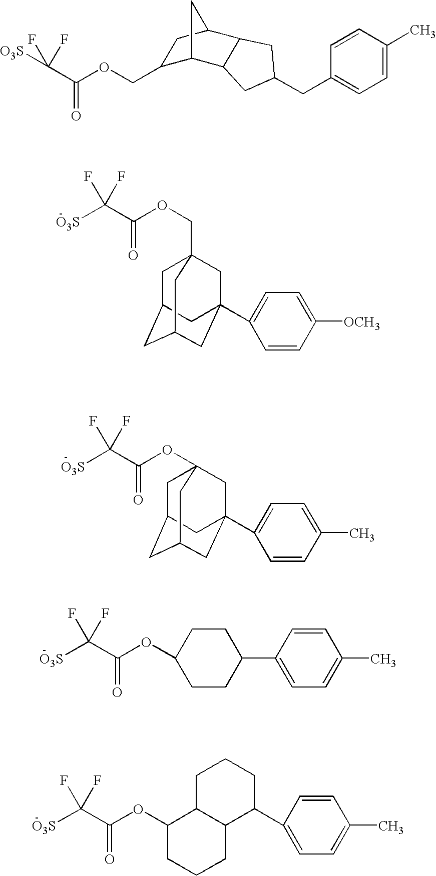

In the formula (IA), examples of the anion in which a hydrogen atom contained in the ring W is replaced by a hydroxyl group or a hydroxyl group-containing group, provided that these containing a lactone structure are excluded, include the anions below.

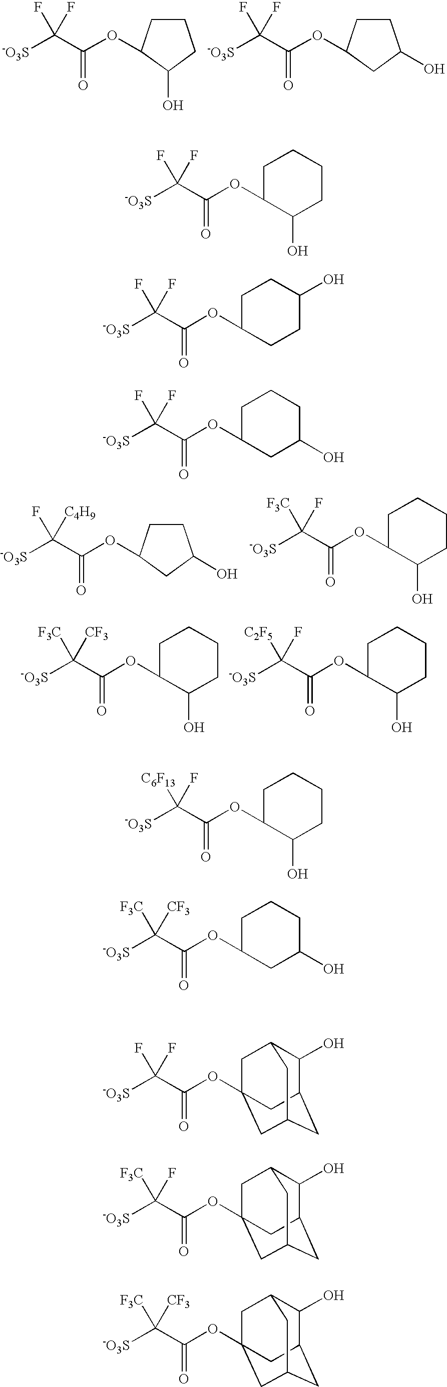

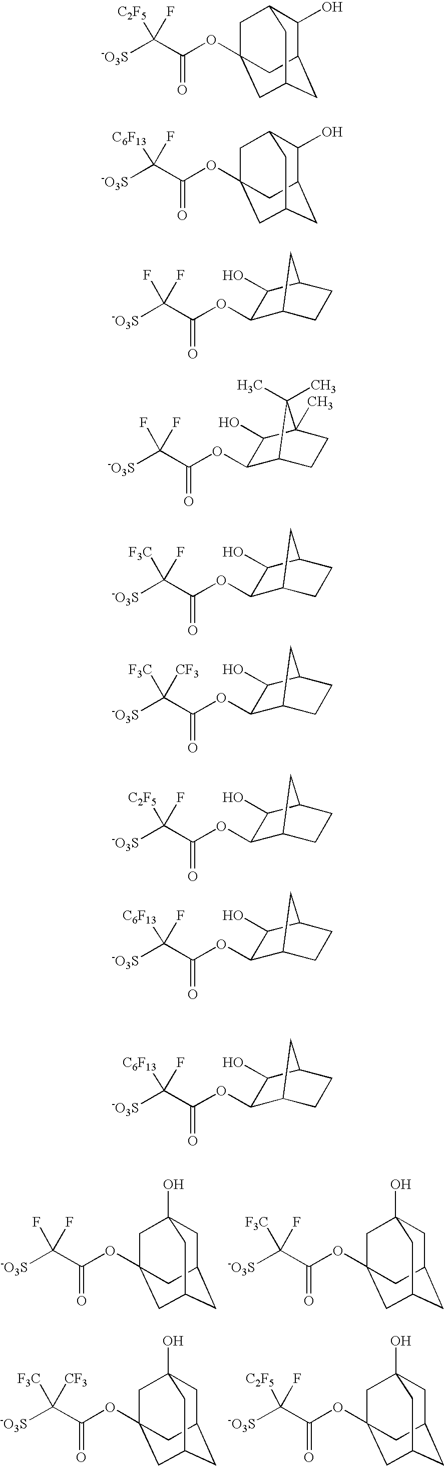

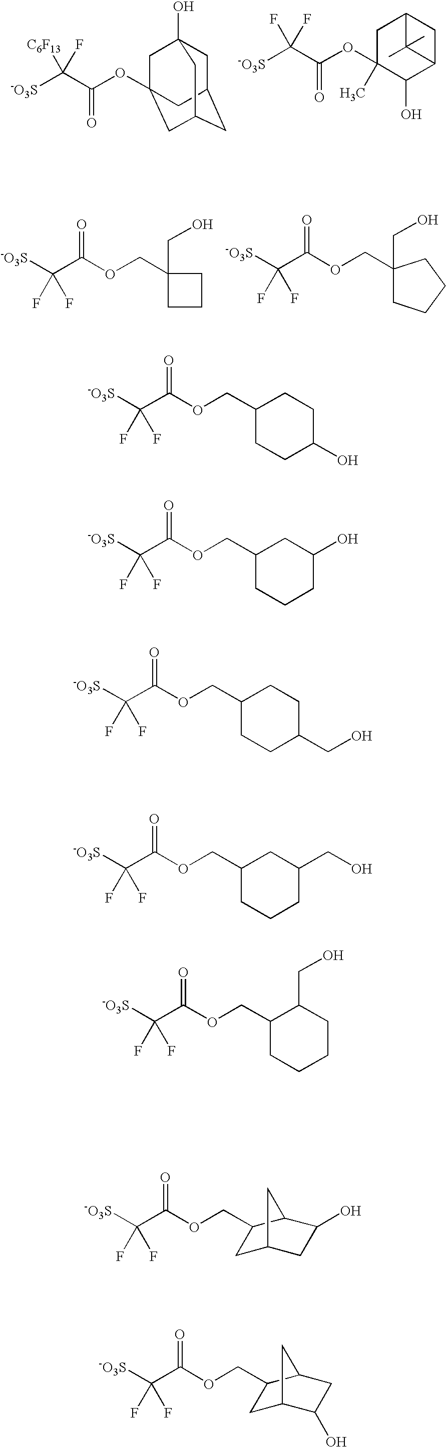

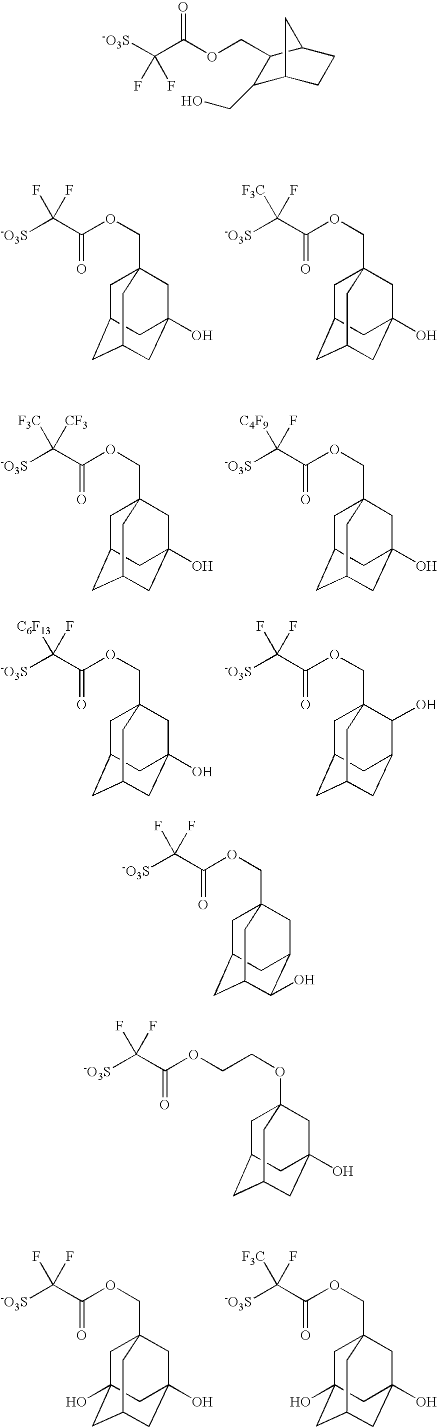

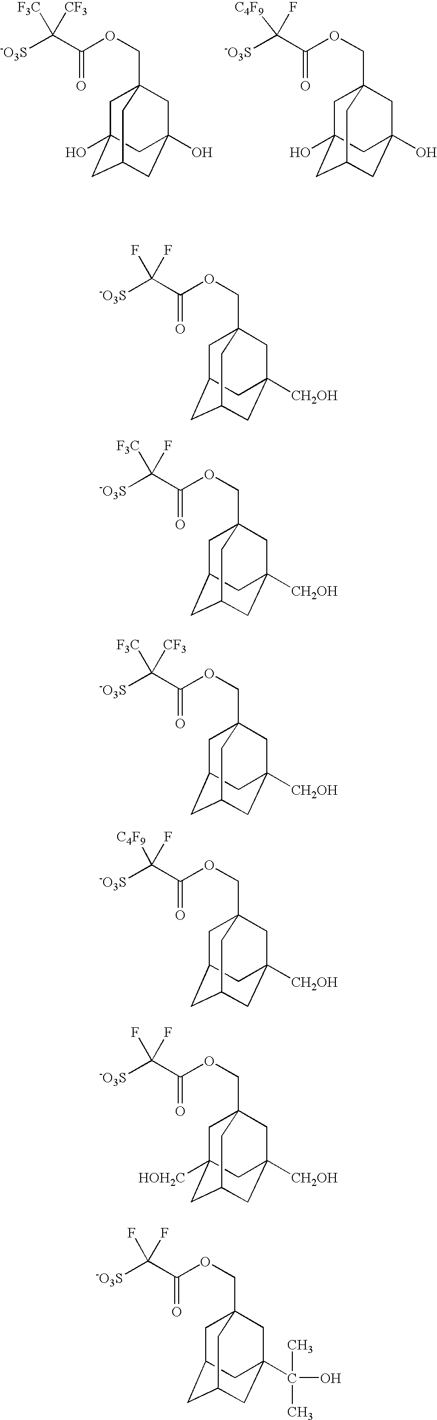

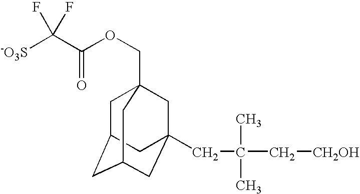

In the formula (IA), examples of the anion having an ether bond in which a —CH₂— contained in the ring W is replaced by —O— include the anions below.

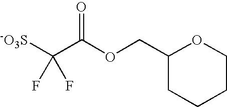

In the formula (IA), examples of the anion having a lactone structure in which two adjacent —CH₂— contained in the ring W are replaced by —O— and —CO— include the anions below.

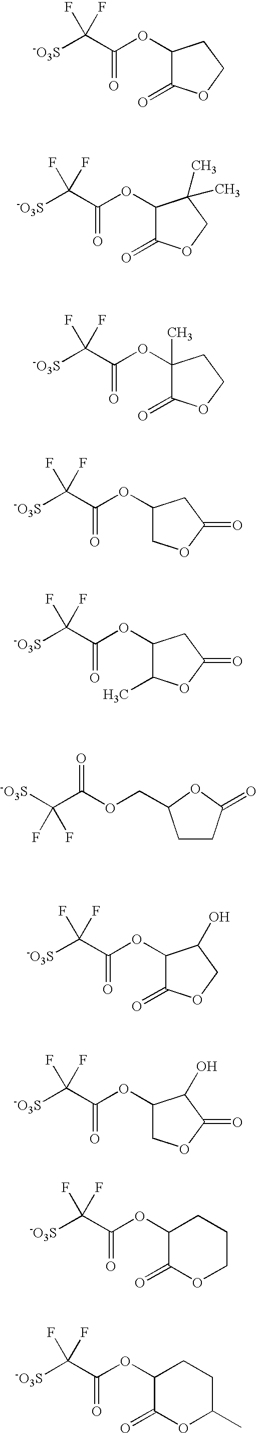

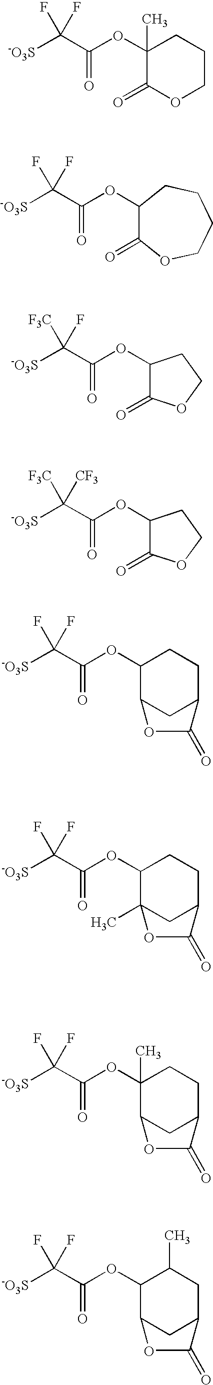

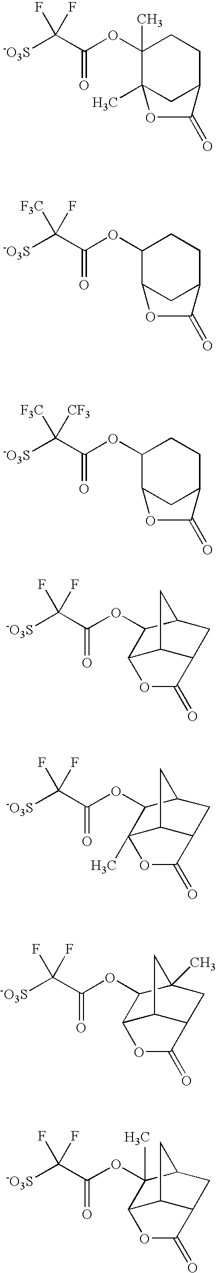

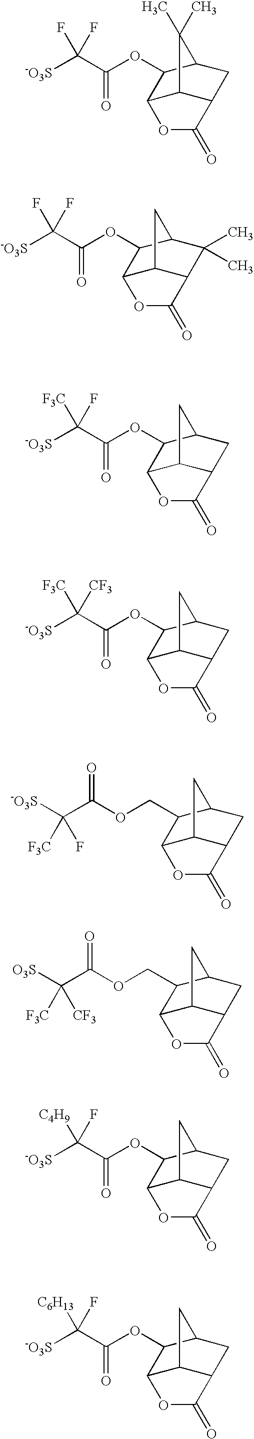

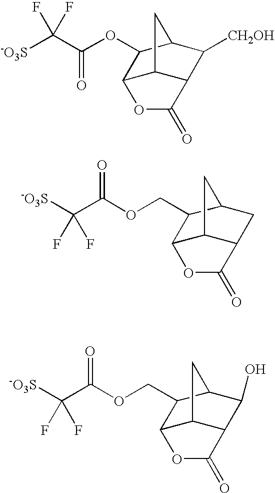

In the formula (IA), examples of the anion having a ketone structure in which a —CH₂— contained in the ring W is replaced by —CO— include the anions below.

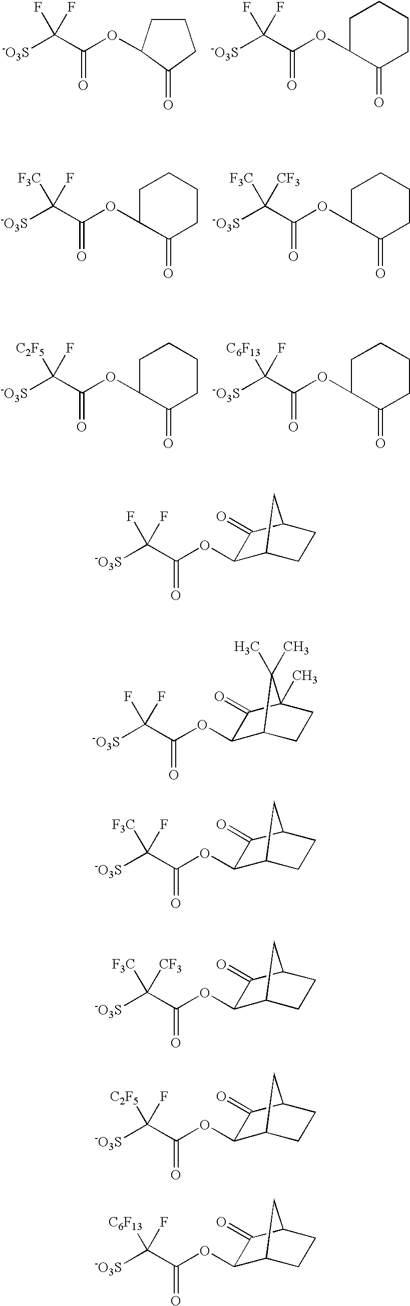

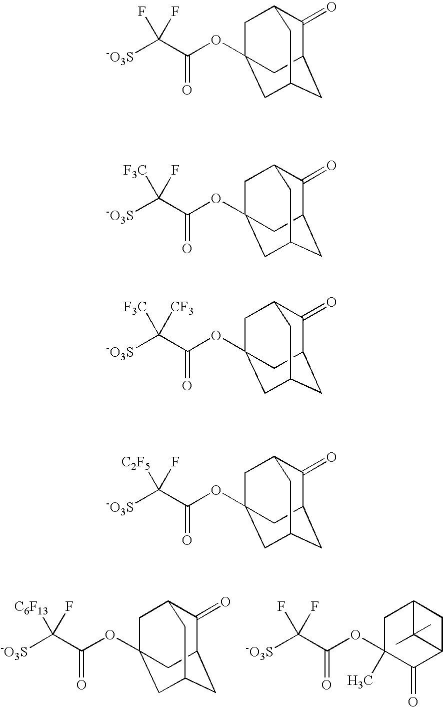

In the formula (IB), examples of the anion in which a hydrogen atom contained in the ring W is not replaced or is replaced only by hydrocarbon group (a —CH₂— contained in the hydrocarbon group may be replaced by a —O—) are the anions below.

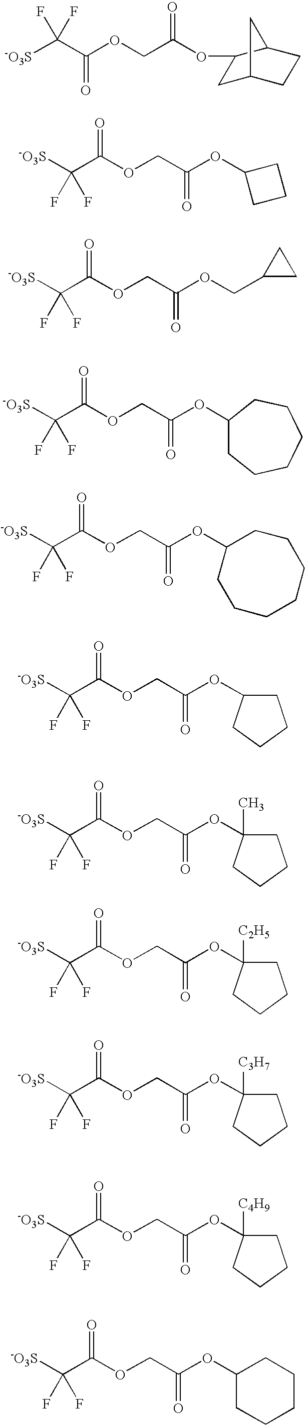

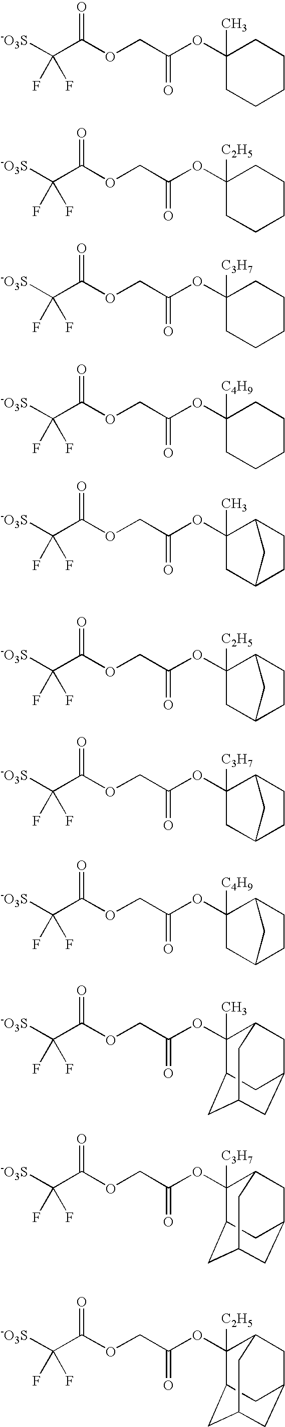

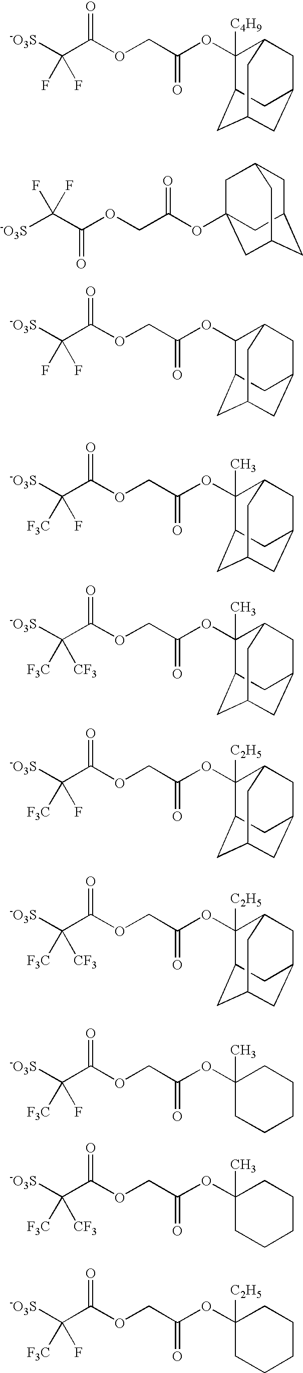

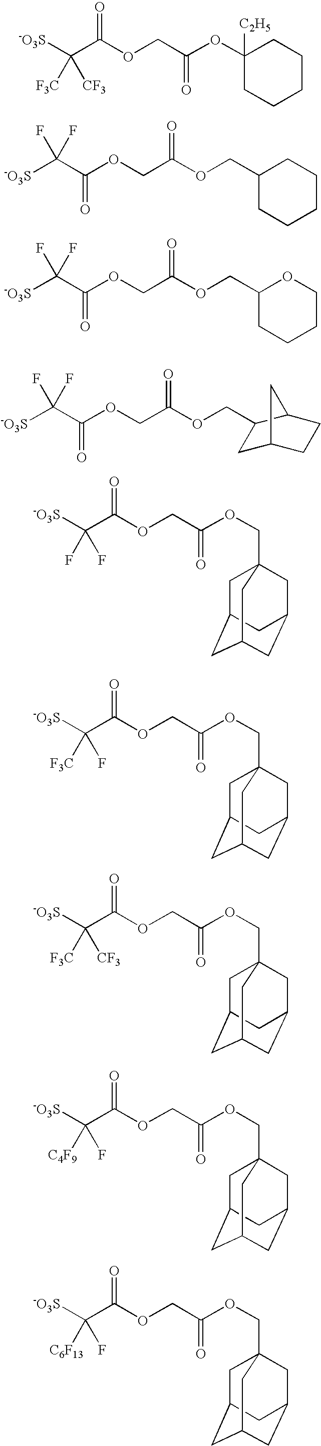

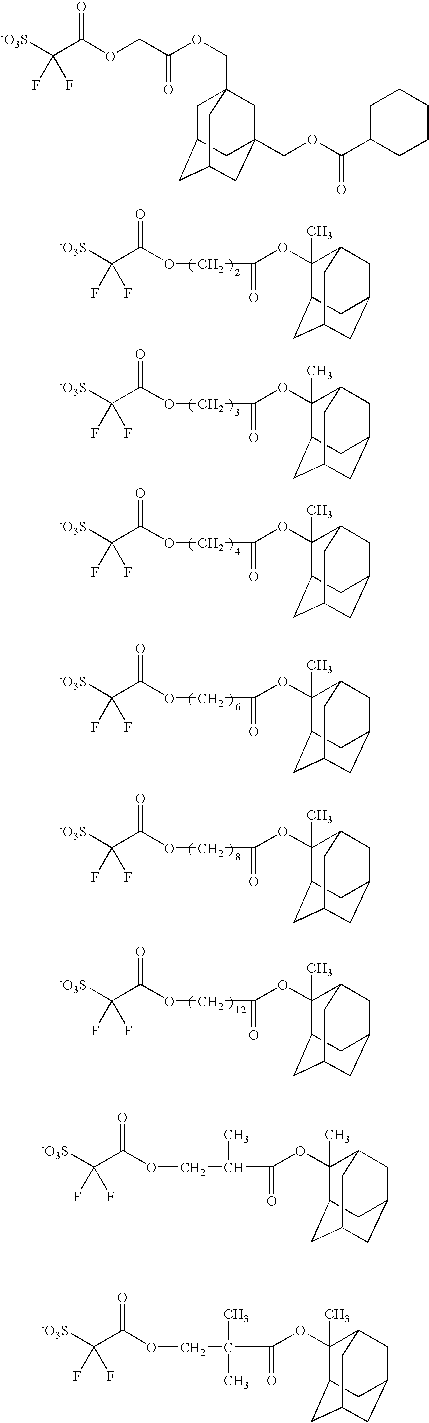

In the formula (IB), examples of the anion in which a hydrogen atom contained in the ring W is replaced by a hydroxyl group or a hydroxyl group-containing group include the anions below.

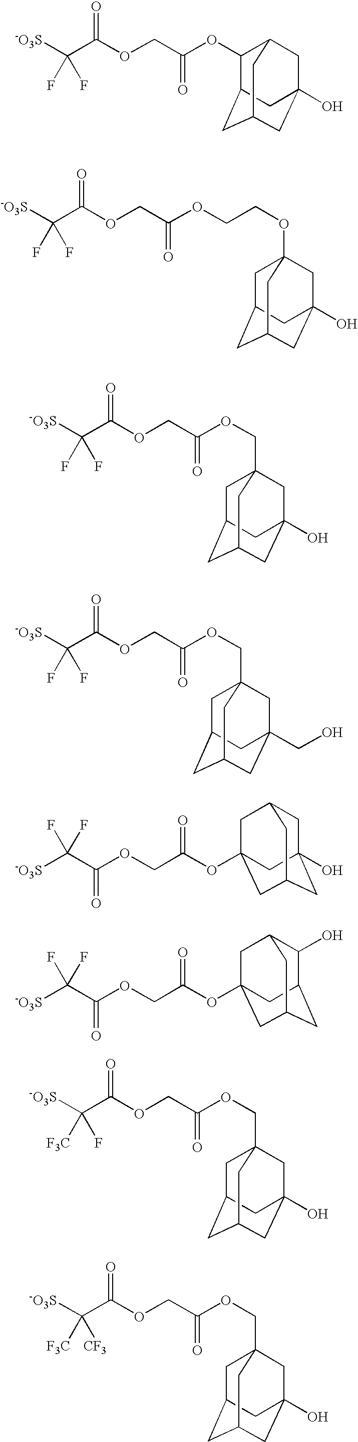

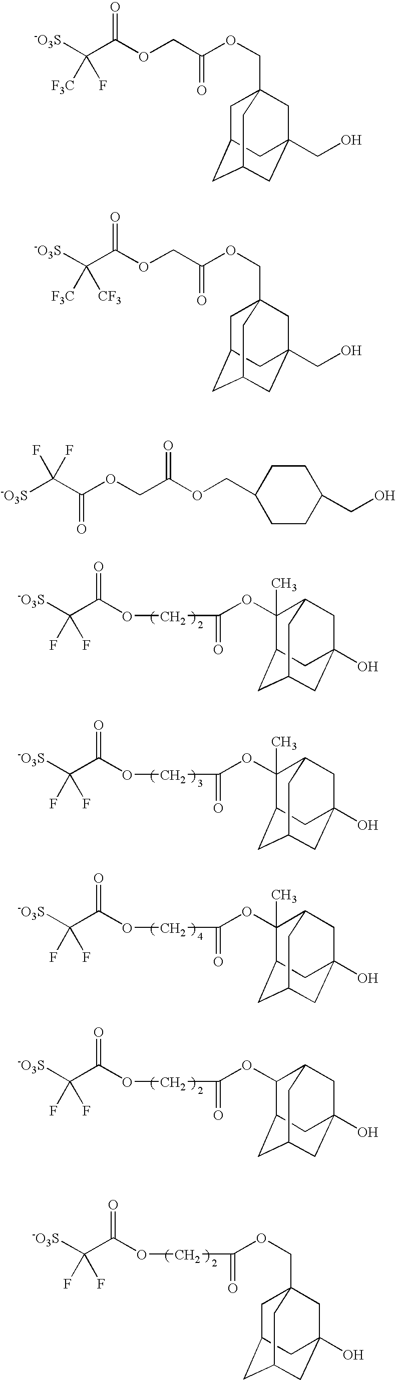

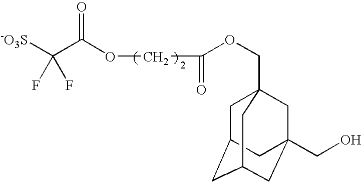

In the formula (IB), examples of the anion having a lactone structure in which two adjacent —CH₂— contained in the ring W is replaced by —O— and —CO— include the anions below.

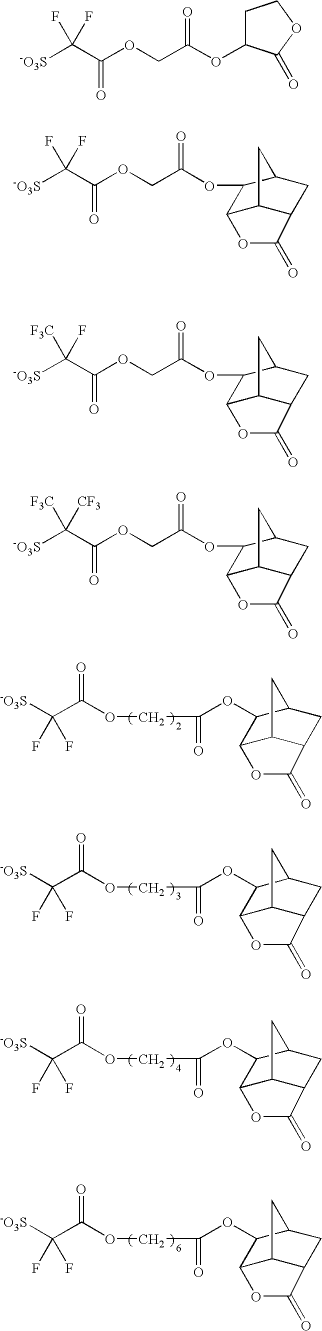

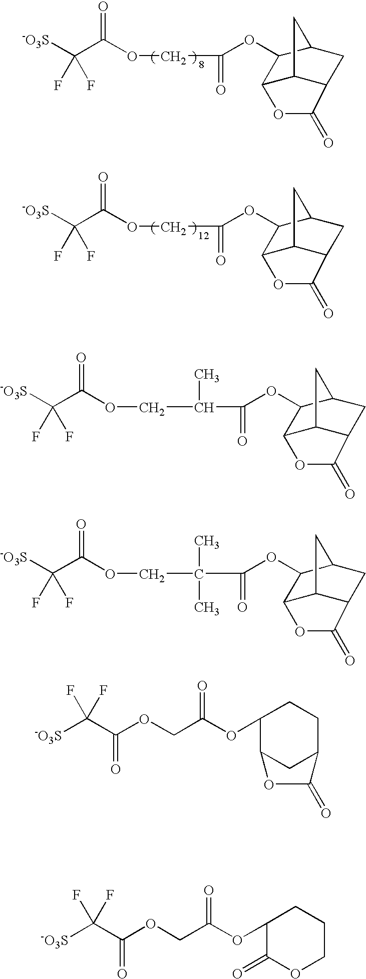

In the formula (IB), examples of the anion having a ketone structure in which one —CH₂— contained in the ring W is replaced by —CO— include the anions below.

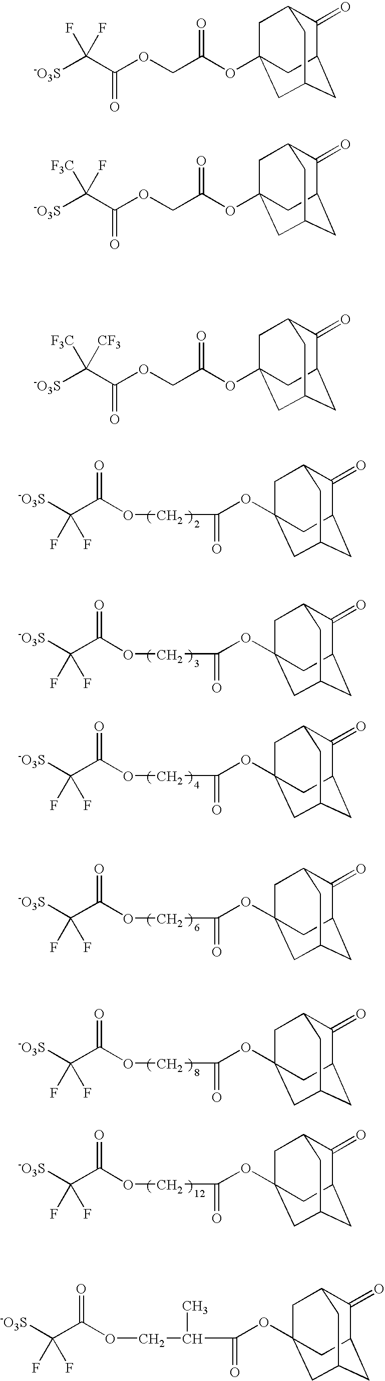

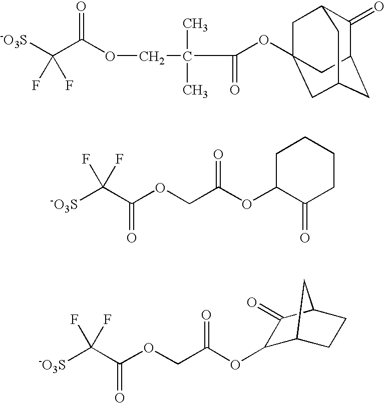

In the formula (IB), examples of the anion in which a hydrogen atom contained in the ring W is replaced by an aromatic hydrocarbon group include the anions below.

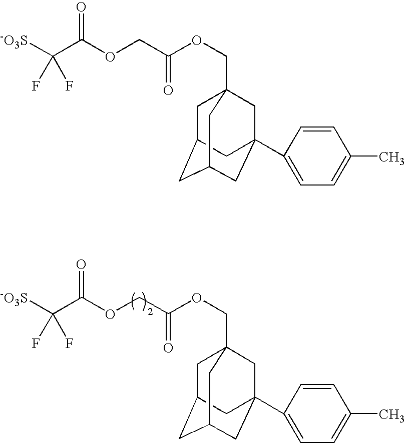

In the formula (IC), examples of the anion in which a hydrogen atom contained in the ring W is not replaced or is replaced only by hydrocarbon group (a —CH₂-contained in the ring W may be replaced by a —O—) are the anions below.

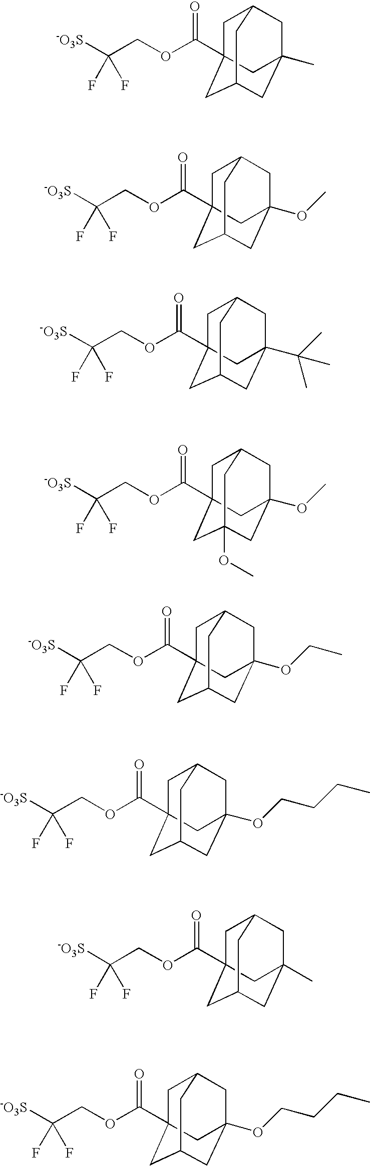

In the formula (IC), examples of the anion in which a hydrogen atom contained in the ring W is replaced by a hydroxyl group or a hydroxyl group-containing group include the anions below.

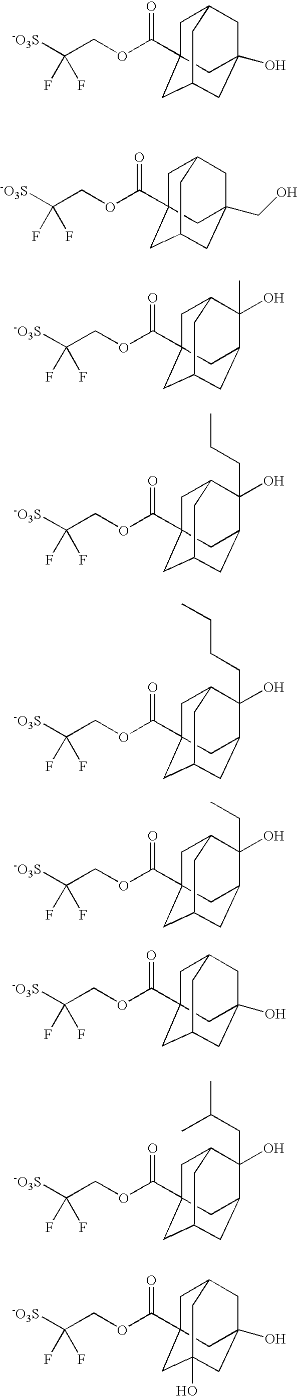

In the formula (IC), examples of the anion having a ketone structure in which one —CH₂— contained in the ring W is replaced by —CO— include the groups below.

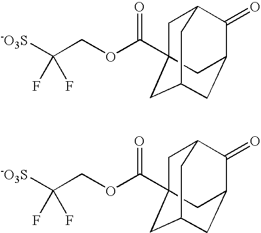

In the formula (ID), examples of the anion in which a hydrogen atom contained in the ring W is not replaced or is replaced only by hydrocarbon group (a —CH₂— contained in the ring W may be replaced by —O—) include the anions below.

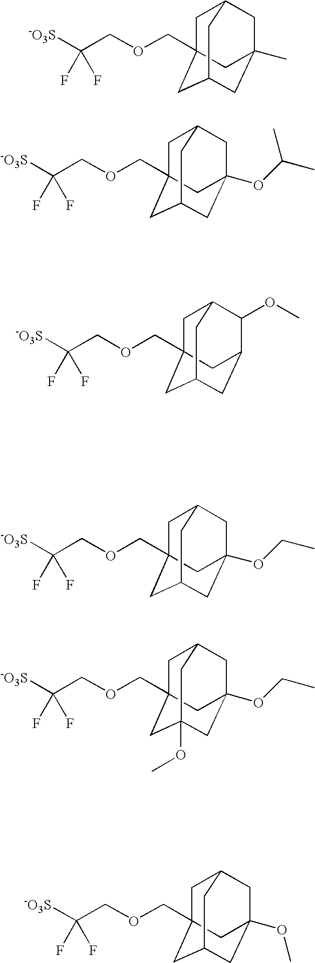

In the formula (ID), examples of the anion in which a hydrogen atom contained in the ring W is replaced by a hydroxyl group or a hydroxyl group-containing group include the anions below.

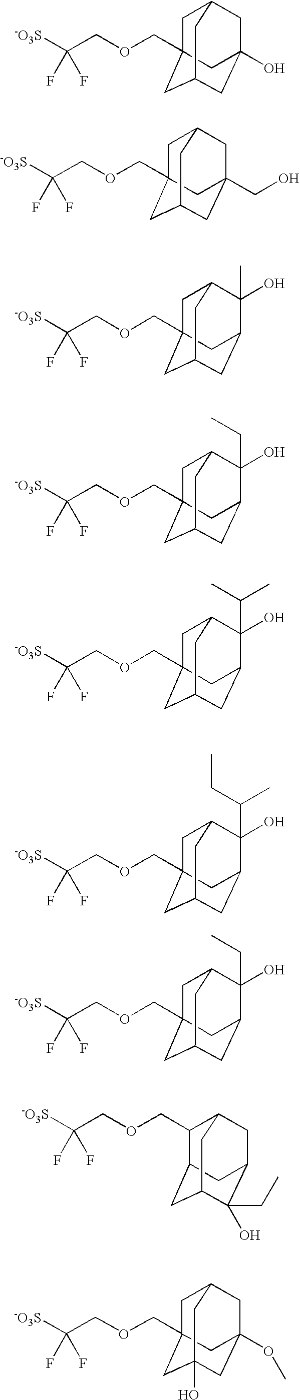

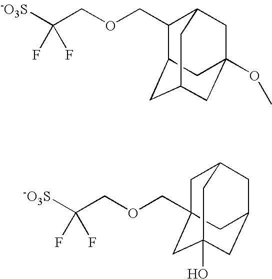

In the formula (ID), examples of the anion having a ketone structure in which one —CH₂— contained in the ring W is replaced by —CO— include the groups below.

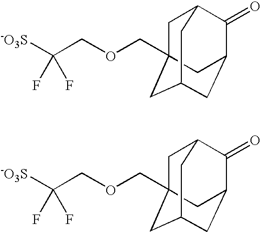

Among anions, these that contain an adamantane structure, an oxoadamantane structure an cyclohexane structure are preferred.

Among these, the anions shown below are more preferred.

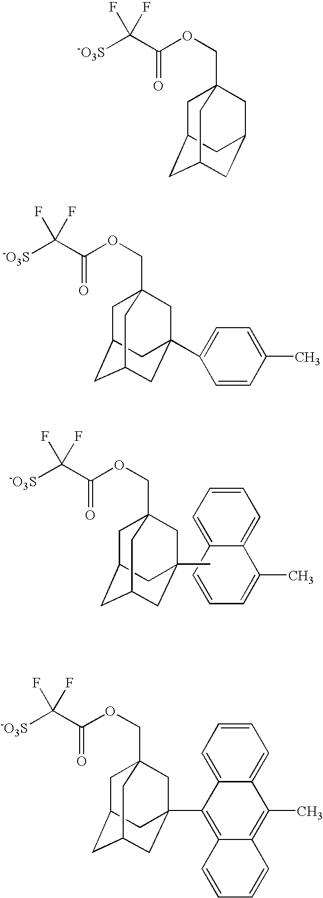

Examples of the Z⁺ in the formula (I) include cations represented by the formula (IXa), the formula (IXb), the formula (IXc) and the formula (IXd).

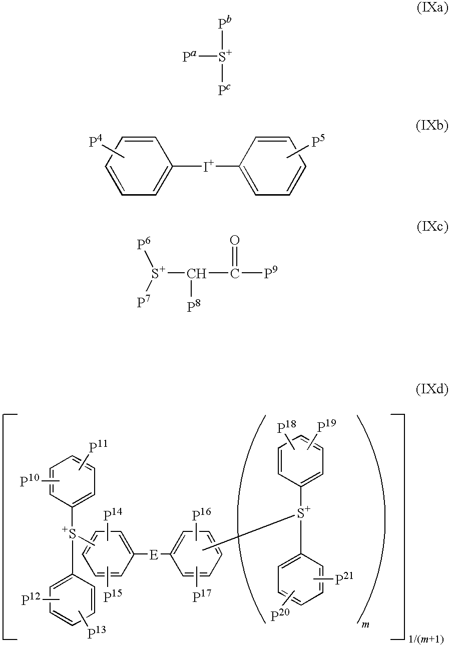

wherein P^{a}, P^{b} and P^{c} independently represent a C₁ to C₃₀ alkyl group or a C₃ to C₃₀ saturated cyclic hydrocarbon group, when any of P^{a}, P^{b} and P^{c} are the alkyl group, the alkyl group may has at least one substituent selected from the group consisting of a hydroxyl group, a C₁ to C₁₂ alkyl group and a C₃ to C₁₂ saturated cyclic hydrocarbon group, and when any of P^{a}, P^{b} and P^{c} are the saturated cyclic hydrocarbon group, the saturated cyclic hydrocarbon group may has at least one substituent selected from the group consisting of a hydroxyl group, a C₁ to C₁₂ alkyl group and a C₁ to C₁₂ alkoxyl group,

P⁴ and P⁵ independently represent a hydrogen atom, a hydroxyl group, a C₁ to C₁₂ alkyl group or a C₁ to C₁₂ alkoxyl group,

P⁶ and P⁷ independently represent a C₁ to C₁₂ alkyl group or a C₃ to C₁₂ cycloalkyl group, or P⁶ and P⁷ may be bonded to form a C₃ to C₁₂ ring,

P⁸ is a hydrogen atom,

P⁹ represents a C₁ to C₁₂ alkyl group, a C₃ to C₁₂ cycloalkyl group or an optionally substituted C₆ to C₂₀ aromatic cyclic group, or P⁸ and P⁹ may be bonded to form a C₃ to C₁₂ ring,

P¹⁰ to P¹² independently represent a hydrogen atom, a hydroxyl group, a C₁ to C₁₂ alkyl group or a C₁ to C₁₂ alkoxyl group,

E represents a sulfur atom or an oxygen atom, and

m represents 0 or 1.

Examples of the alkoxyl group include methoxy, ethoxy, n-propoxy, isopropoxy, n-butoxy, sec-butoxy, tert-butoxy, n-penthoxy, n-hexyloxy, hepthoxy, octyloxy, 2-ethylhexyloxy, nonyloxy, decyloxy, undecyloxy and dodecyloxy groups.

Examples of the cycloalkyl group include the same examples defined above.

Examples of the ring formed by P⁶ and P⁷ bonded together include tetrahydrothiophenium group.

Examples of the substituent of the aromatic cyclic group of P⁹ include a C₁ to C₁₂ aralkyl group.

Examples of the ring formed by P⁸ and P⁹ bonded together include a group represented by the formula (W13) to the formula (W15) described above.

Among the cations represented by the formula (IXa), a cation represented by the formula (IXaa) is preferable.

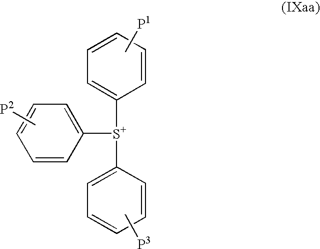

wherein P¹ to P³ independently represent a hydrogen atom, a hydroxyl group, a C₁ to C₁₂ alkyl group, a C₁ to C₁₂ alkoxy group or a C₄ to C₃₆ saturated cyclic hydrocarbon group, and the hydrogen atom contained in the saturated cyclic hydrocarbon group may be replaced by at least one substituent selected from the group consisting of a halogen atom, a hydroxyl group, a C₁ to C₁₂ alkyl group, a C₁ to C₁₂ alkoxy group, a C₆ to C₁₂ aryl group, a C₇ to C₁₂ aralkyl group, a glycidoxy group and a C₂ to C₄ acyl group.

Particularly, examples of the saturated cyclic hydrocarbon group include a group-containing adamantyl structure and isobornyl structure, and 2-alkyl-2-adamantyl group, 1-(1-adamantyl)-1-alkyl group and isobornyl group are preferable.

Specific examples of the cation of the formula (IXaa) include a cation represented by the following formulae.

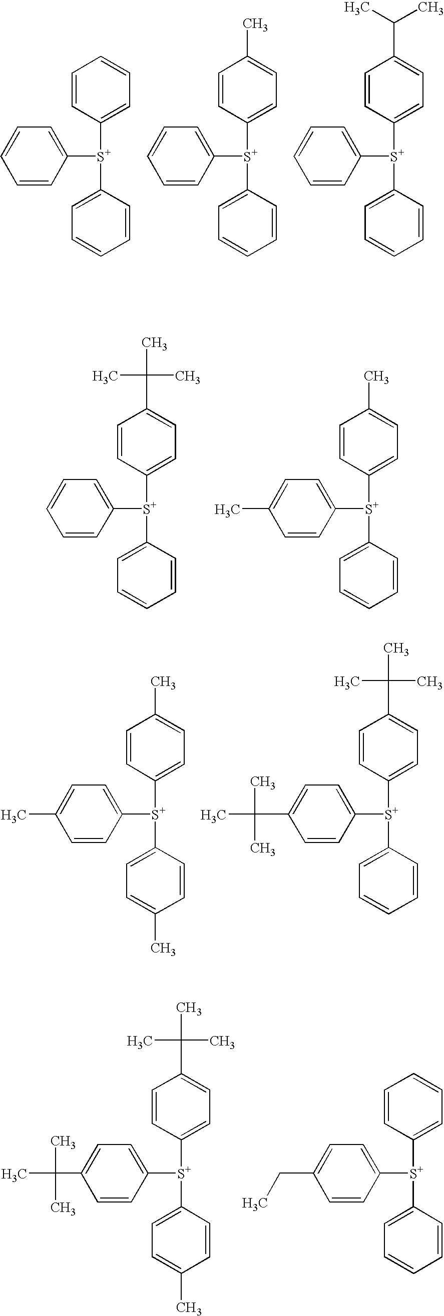

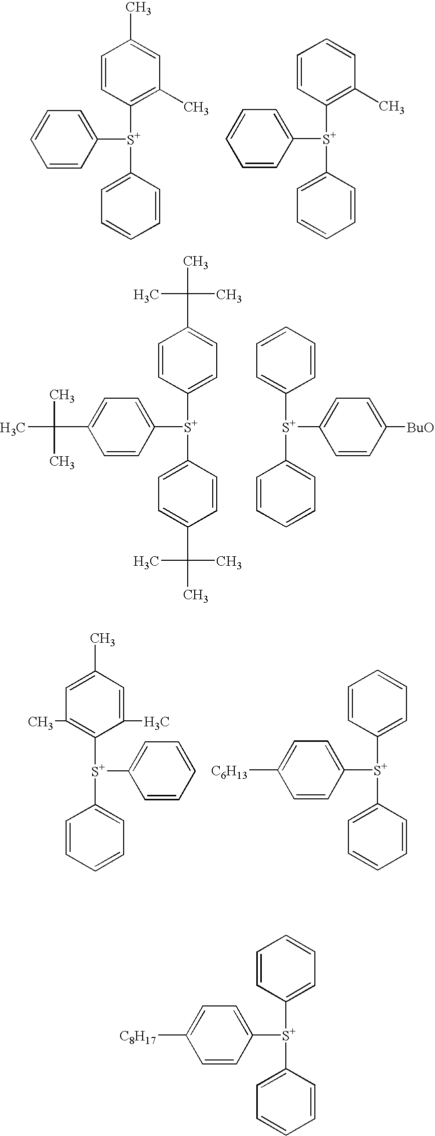

Among the cations represented by the formula (IXaa), a cation represented by the formula (IXaaa) is preferable because of easily-manufacturing.

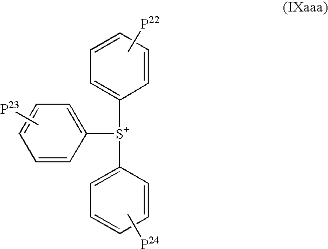

wherein P²², P²³ and P²⁴ independently represent a hydrogen atom, a hydroxyl group, a C₁ to C₁₂ alkyl group or a C₁ to C₁₂ alkoxy group.

Specific examples of the cation of the formula (IXb) include a cation represented by the following formulae.

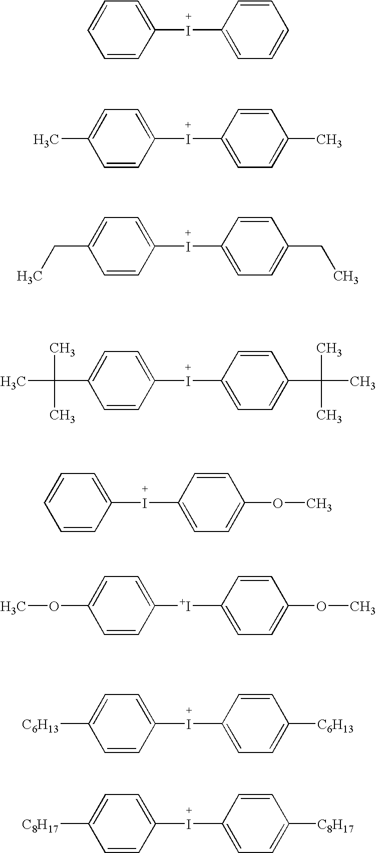

Specific examples of the cation of the formula (IXc) include a cation represented by the following formulae.

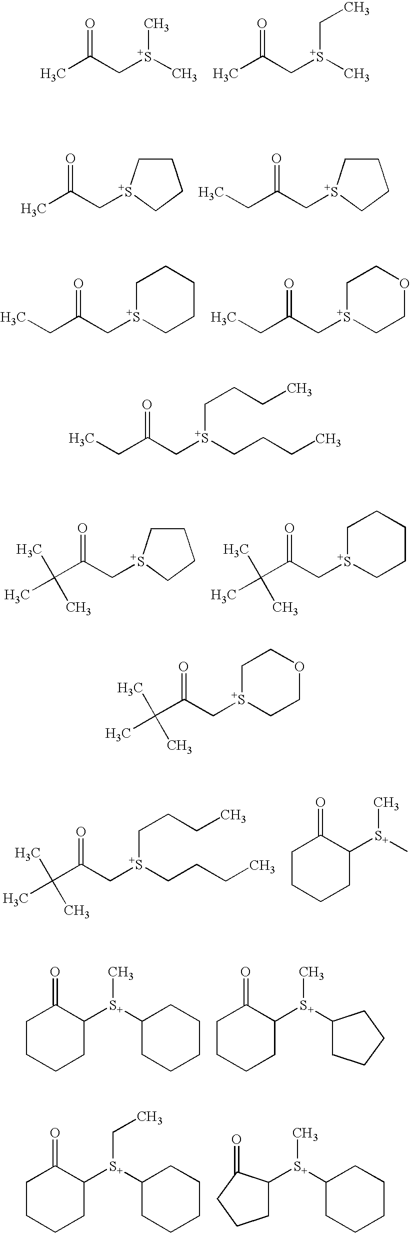

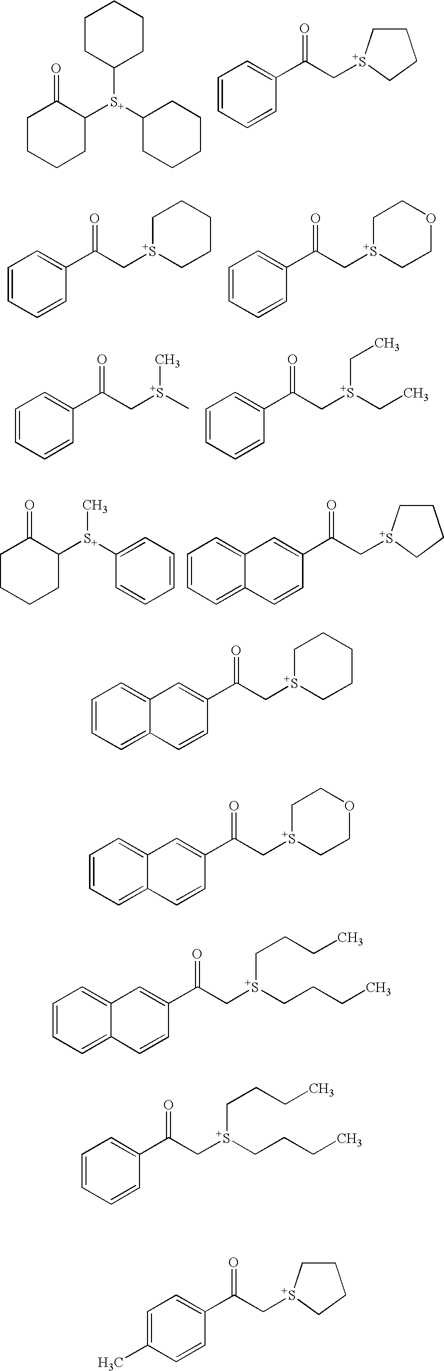

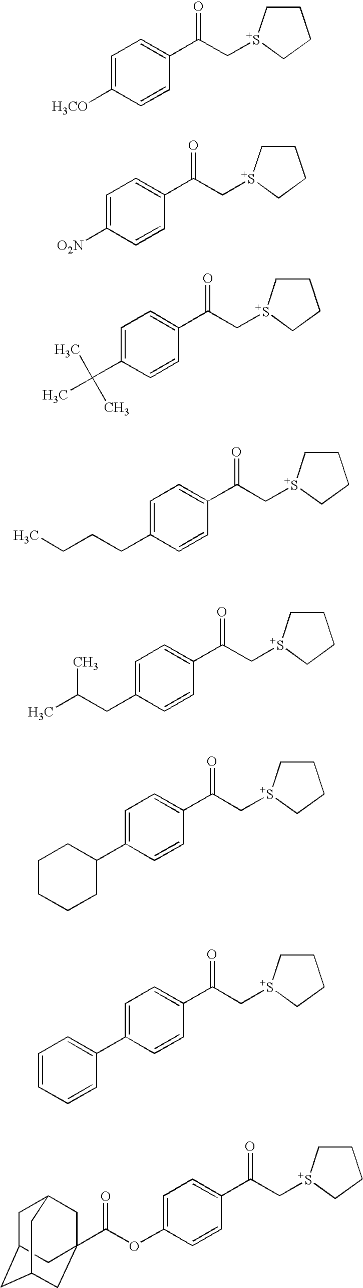

Specific examples of the cation of the formula (IXd) include a cation represented by the following formulae.

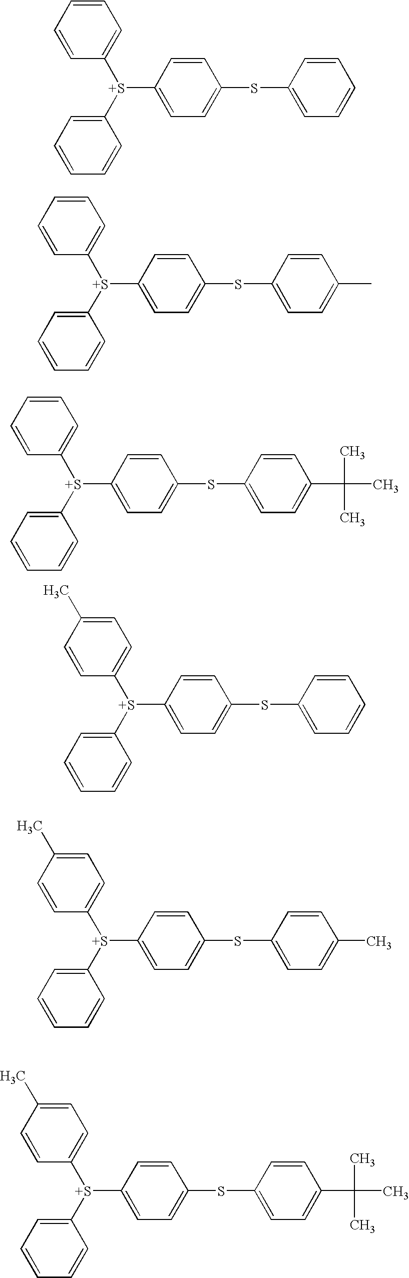

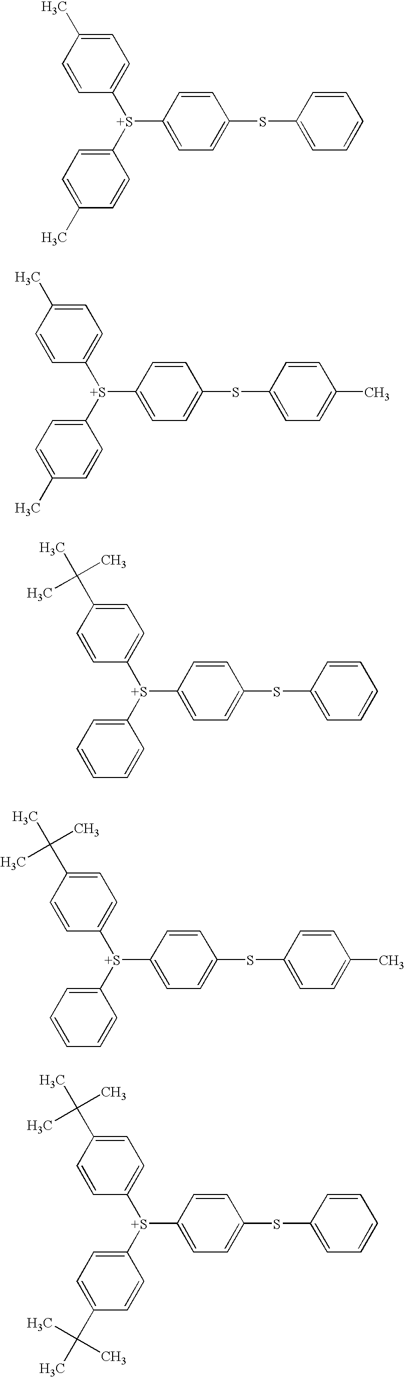

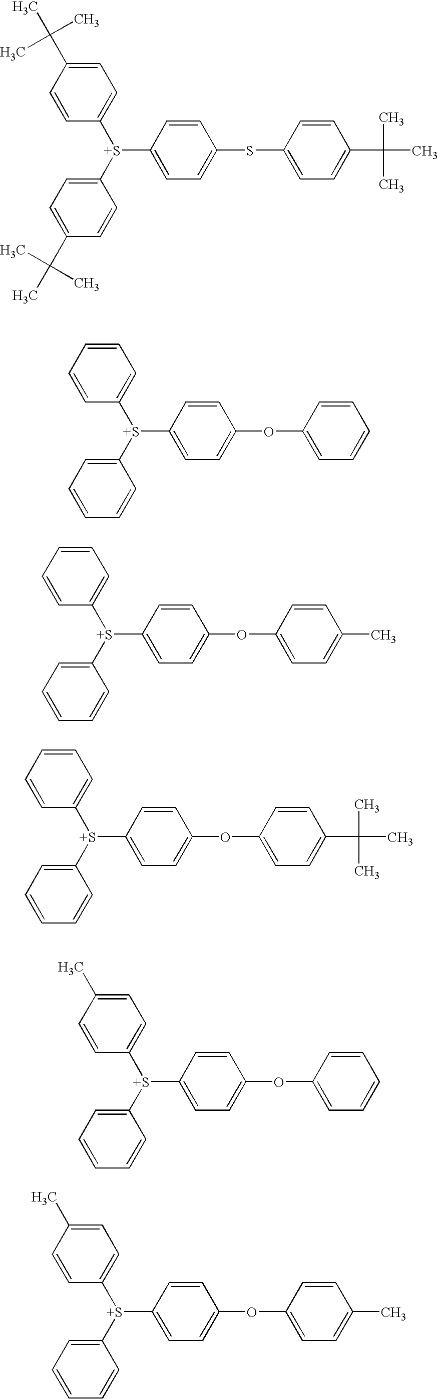

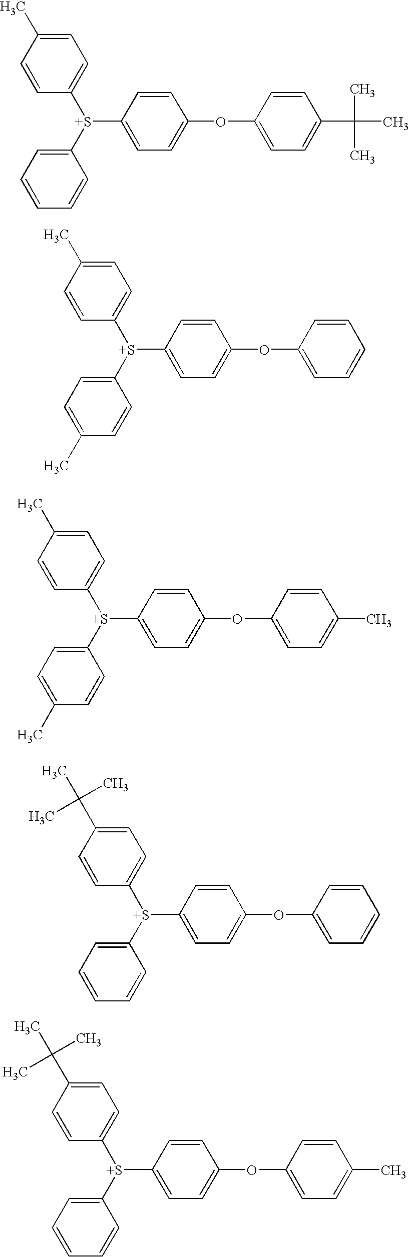

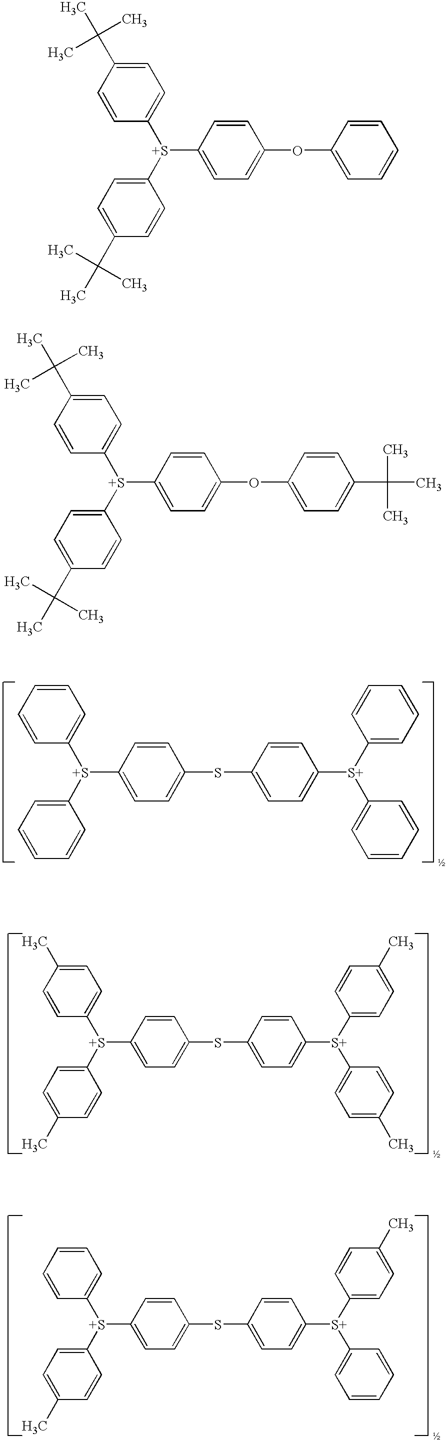

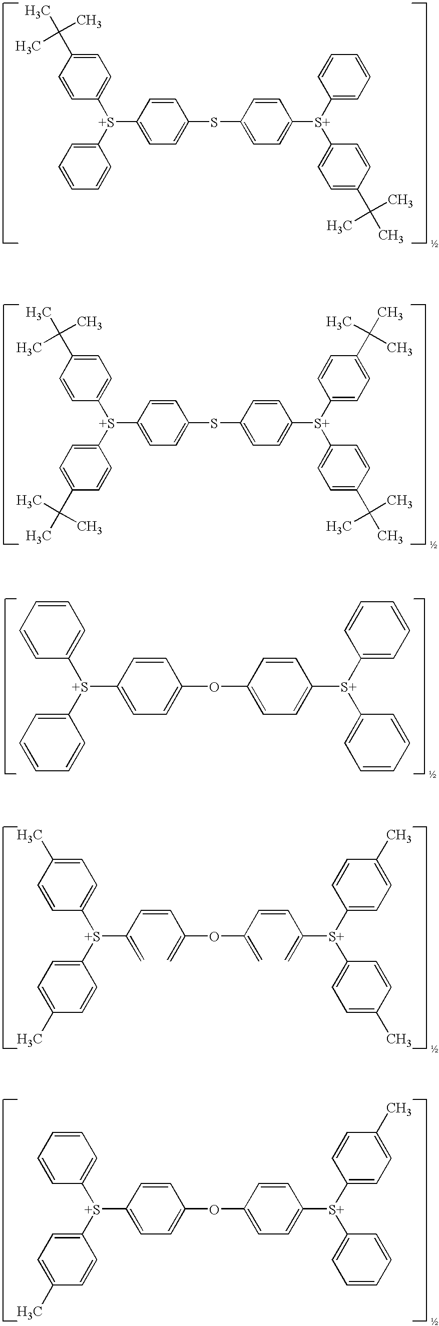

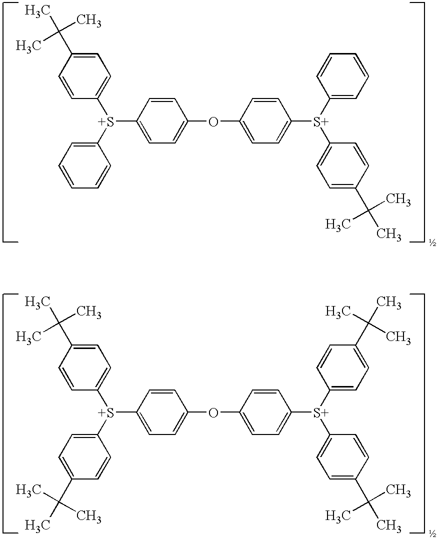

Among theses, an arylsulfonium cation is preferable.

The above-mentioned anions and cations can be combined as desired.

Examples of the compounds represented by the formula (I) include the compounds represented by the formula (Xa) to the formula (Xi). Such compounds are preferred for generating acid to be supplied to resist compositions that exhibit superior resolution performance and pattern shapes.

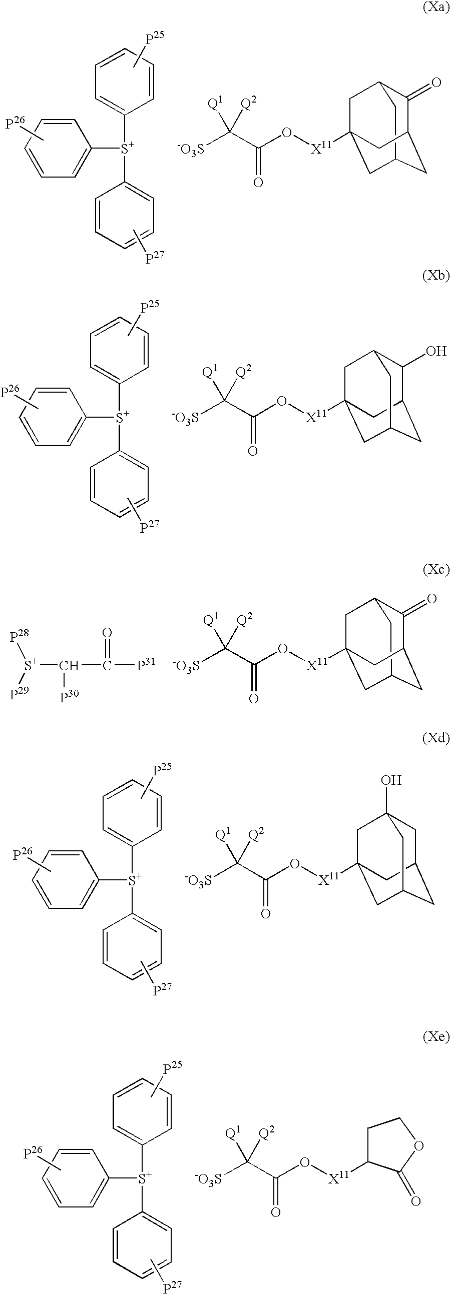

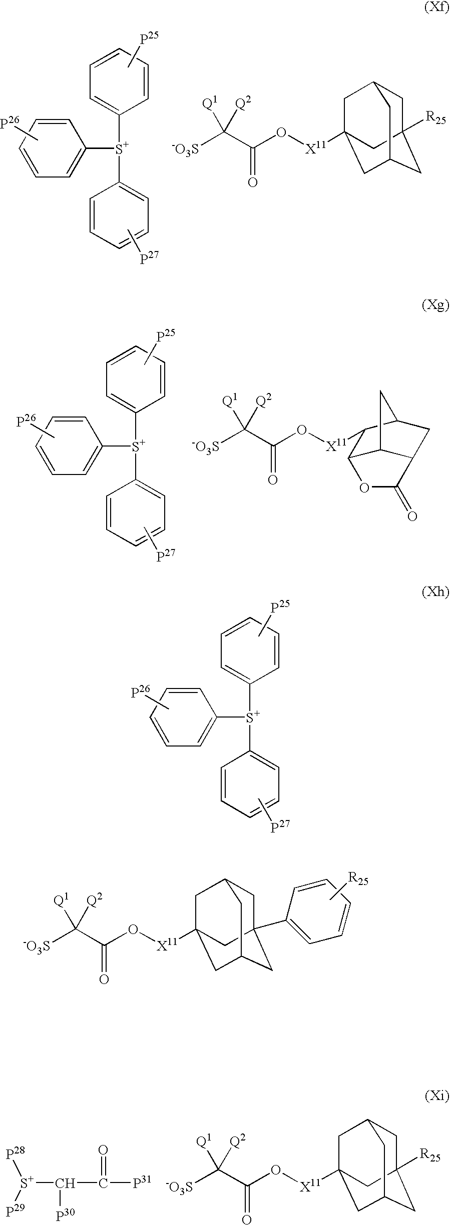

wherein P²⁵, P²⁶ and P²⁷ independently represent a hydrogen atom, a C₁ to C₄ aliphatic hydrocarbon group or a C₄ to C₃₆ saturated cyclic hydrocarbon group,

P²⁸ and P²⁹ independently represent a C₁ to C₁₂ aliphatic hydrocarbon group or a C₄ to C₃₆ saturated cyclic hydrocarbon group, or P²⁸ and P²⁹ can be bonded together to form a C₂ to C₆ ring that includes S⁺,

P³⁰ represent a C₁ to C₁₂ aliphatic hydrocarbon group, a C₄ to C₃₆ saturated cyclic hydrocarbon group or an optionally substituted C₆ to C₂₀ aromatic hydrocarbon group, or P³⁰ and P³¹ can be bonded together to form a C₃ to C₁₂ ring,

herein, the —CH₂— contained in the ring may be replaced by —O—, —S— or —CO—,

Q¹ and Q² have the same meaning as defined above and

X¹³ represents a single bond or a —CH₂— group.

Examples of the ring formed by P²⁸ and P²⁹ bonded together include tetrahydrothiophenium group.

Examples of the ring formed by P³⁰ and P³¹ bonded together include the group represented by the formula (W13) to the formula (W15) described above.

Among the abovementioned combinations, the following acid generators are preferred.

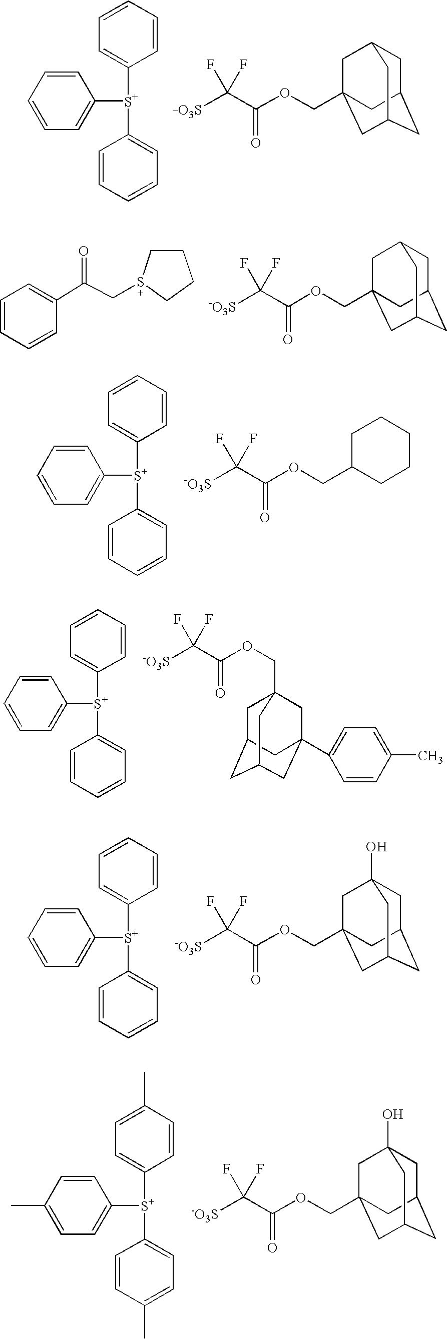

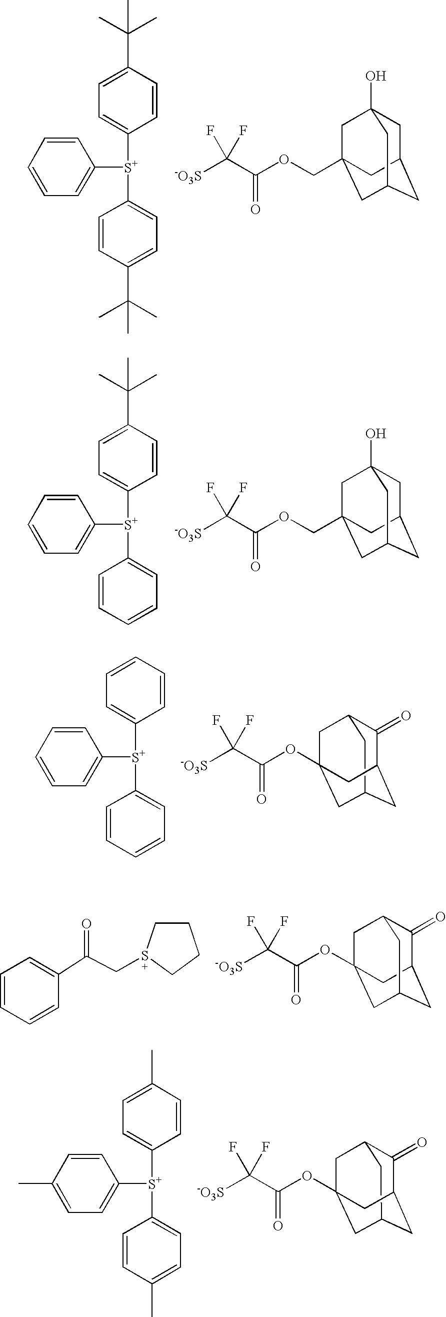

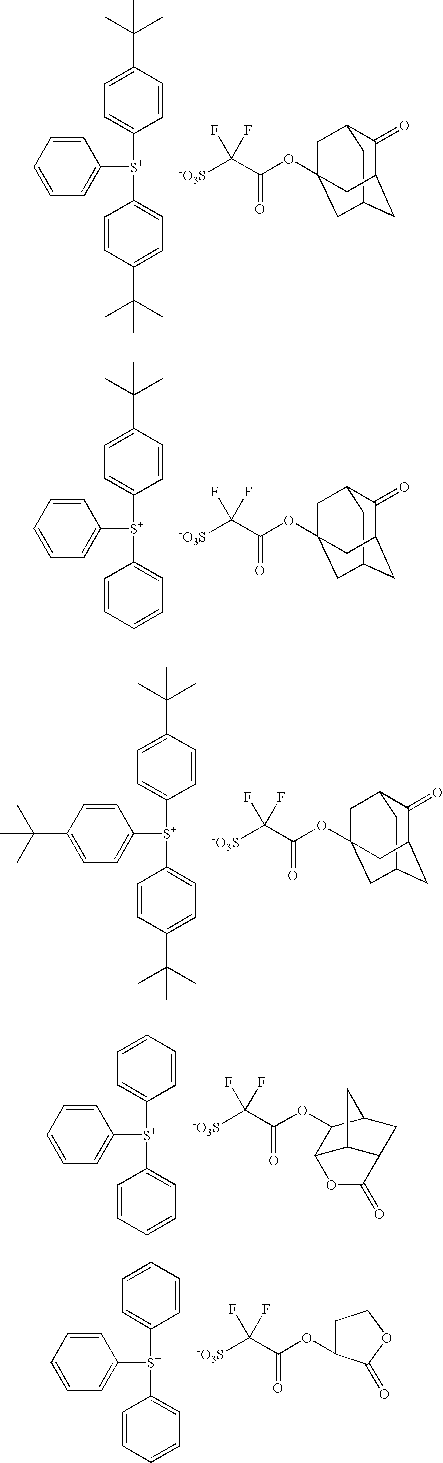

Among these, the acid generators wherein the cation is the cation represented by the formula (IXe) wherein P²², P²³ and P²⁴ are hydrogen atoms and the anion is the anion represented by the formula (IB) are preferable.

The acid generators represented by the formula (I) can be used singly or as combinations of two or more types.

The acid generator (A) represented by the formula (I) can be formed according to the manufacturing methods below. Furthermore, unless specifically stated otherwise, the definitions of substituent groups in the formulas below that show manufacturing methods for an acid generator have the same meaning as defined above.

For example, the acid generator [A] can be manufactured according to a synthesis method wherein the salt represented by the formula (1) and the onium salt represented by the formula (3) are reacted by being stirred in an inert solvent such as acetonitrile, water, methanol, chloroform and methylene chloride, or a aprotic solvent at a temperature in the range of about 0° C. to 150° C., and preferably 0° C. to 100° C.

Examples of aprotic solvents include dichloroethane, toluene, ethylbenzene, monochlorobenzene, acetonitrile and N,N-dimethylformamide.

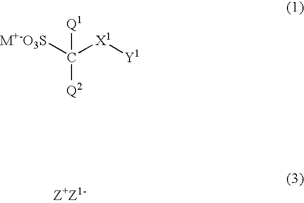

wherein M⁺ represents Li⁺, Na⁺, K⁺ or Ag⁺; and

Z¹⁻ represents F⁻, Cl⁻, Br⁻, I⁻, BF₄⁻, AsF₆⁻, SbF₆⁻, BF₆⁻ or ClO₄⁻.

The amount of the onium salt of the formula (3) used is generally in the range of 0.5 to 2 moles per 1 mole of the salt represented by the formula (1). The acid generator [A] can be recovered by recrystallization, and it can be purified by rinsing with water.

Among the salts represented by the formula (1), the salt having the anion represented in the above-mentioned the formula (IA) can be obtained from an esterification reaction of an alcohol represented by the formula (4) and a carboxylic acid represented by the formula (5).

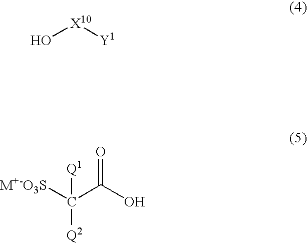

The amount of the carboxylic acid represented by the formula (5) used in the esterification reaction is generally in the range of 0.2 to 3 moles per 1 mole of the alcohol represented by the formula (4), and preferably in the range of 0.5 to 2 moles. The amount of an acid catalyst used in the esterification reaction may be a catalytic amount, and it may be the amount correspond to the amount of the solvent, and is generally in the range of 0.001 to 5 moles.

Additionally, among the salts represented by the formula (1), the salt having the anion represented by the above-mentioned the formula (IIA) can be manufactured, for example, by conducting the esterification reaction of an alcohol represented by the formula (6) and a carboxylic acid represented by the formula (7) followed by a hydrolysis with an alkali metal hydroxide compound represented by MOH.

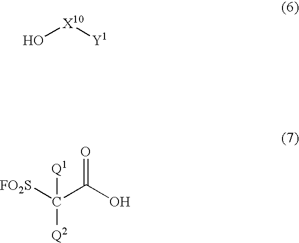

Examples of the MOH include lithium hydroxide, sodium hydroxide and potassium hydroxide, and preferred examples include lithium hydroxide and sodium hydroxide.

The above-mentioned esterification reaction is generally carried out by stirring in the aprotic solvent the same as mentioned above, in the temperature range of 20 to 200° C., preferably in the temperature range of 50 to 150° C.

In the esterification reaction, an organic acid such as p-toluenesulfonic acid, or an inorganic acid such as sulfuric acid may be generally added as an acid catalyst.

Further, a dehydrating agent can be used in the above-mentioned esterification reaction.

Examples of the dehydrating agent include dicyclohexylcarbodiimide, 1-alkyl-2-halopyridinium salt, 1,1-carbonyldiimidazole, bis-(2-oxo-3-oxazolidinyl) phosphinic chloride, 1-ethyl-3-(3-dimethylaminopropyl)carbodiimide hydrochloride, di-2-pyridyl carbonate, di-2-pyridyl thionocarbonate and 6-methyl-2-nitrobenzoic acid anhydride in the presence of 4-(dimethylamino)pyridine.

Performing the esterification reaction using the acid catalyst while water is being removed using a Dean-Stark apparatus or the like, is preferable because it tends to shorten the reaction time (likewise below).

Further, the salt having the anion represented by the above-mentioned the formula (IA) can be obtained by an esterification reaction of an alcohol represented by the formula (9) and a carboxylic acid represented by the formula (8).

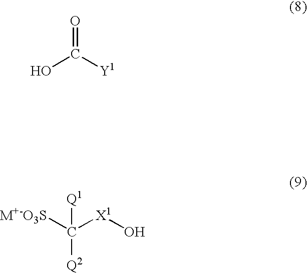

For the above-mentioned reaction, the same methods can be applied in the manufacture of the salts having the anion represented by the formula (IB).

Among the salts represented in the formula (1), the salt having the anion represented by the abovementioned the formula (IC) can be obtained by an esterification reaction of a carboxylic acid represented by the formula (8) and an alcohol represented by the formula (10).

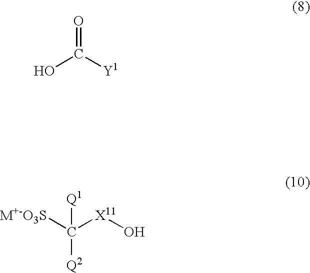

The amount of the alcohol represented by the formula (10) that is used in the esterification reaction is generally in the range of 0.5 to 3 moles per 1 mole of the carboxylic acid represented by the formula (8), and preferably in the range of 1 to 2 moles. The amount of the acid catalyst used in the esterification reaction may be the amount of the catalyst, and may be also the amount correspond to the amount of the solvent, and is generally in the range of 0.001 to 5 moles per 1 mole of the carboxylic acid represented by the formula (8). The amount of the dehydrating agent in the esterification reaction is generally in the range of 0.5 to 5 moles per 1 mole of the carboxylic acid represented by the formula (8), and preferably in the range 1 to 3 moles.

In the esterification reaction of a carboxylic acid represented by the formula (8) and an alcohol represented by formula (10), the carboxylic acid represented by the formula (8) can also be converted to an acid halide followed by carrying out the reaction with the alcohol represented by the formula (10).

Examples of the reagents for conversion to the acid halide include thionyl chloride, thionyl bromide, phosphorus trichloride, phosphorus pentachloride and phosphorus tribromide.

Examples of the solvent used in the conversion reaction to the acid halide include the same aprotic solvents as used above. The reaction is suitably carried out by stirring in the temperature range of 20 to 200° C., and preferably in the temperature range of 50 to 150° C.

In the above-mentioned reaction, an amine compound can be added as a catalyst.

The acid halide obtained can be used in a reaction with the alcohol represented by the formula (10) in an inert solvent (for example, the aprotic solvent), to obtain the salt having the anion represented by the formula (IC). The reaction is preferably carried out in the temperature range of 20 to 200° C., and more preferably in the temperature range of 50 to 150° C. The use of an acid trapping agent is appropriate.

Examples of acid trapping agents include organic bases such as triethylamine and pyridine, or inorganic bases such as sodium hydroxide, potassium carbonate and sodium hydride.

The amount of the acid trapping agent used can also correspond to the amount of solvent, and is generally in the range of 0.001 to 5 moles per 1 mole of the halide, and preferably 1 to 3 moles.

Further, for the manufacturing method for the salt that has the anion represented by the above (IC), after the esterification reaction of a carboxylic acid represented by the formula (8) with an alcohol represented by the formula (11), there is also a method to obtain a hydrolyzed salt with an alkali metal hydroxide compound represented by MOH. M⁺ represents the same meaning as above.

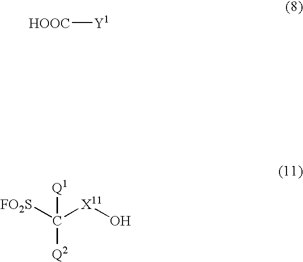

The esterification reaction of a carboxylic acid represented by the formula (8) an alcohol represented by the formula (11) can generally be carried out by stirring in the same aprotic solvent as mentioned above, in the temperature range of 20 to 200° C., preferably in the temperature range of 50 to 150° C.

In the esterification reaction, the acid catalyst that is the same as mentioned above is generally added.

The dehydrating agent such as mentioned above can be added into this esterification reaction.

The amount of the alcohol, the acid catalyst and the dehydrating agent can be the same as above.

Examples of methods for the manufacture of the salt that has an anion represented by the formula (ID) include a first dehydration-condensation of an alcohol represented by the formula (12) and an alcohol represented by the formula (13).

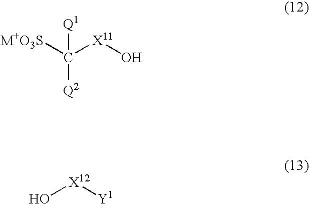

In addition, in a manufacturing method for the salt that has an anion represented by the formula (ID), after the reaction of an alcohol represented by the formula (14) with an alcohol represented by the formula (15), there is also a method to obtain a hydrolyzed salt with an alkali metal hydroxide compound represented by MOH.

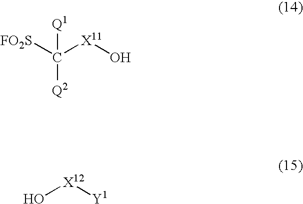

The reaction of the alcohol represented by the formula (14) and the alcohol represented by the formula (15) can generally be carried out by stirring in an aprotic solvent in the temperature range of 20 to 200° C., preferably in the temperature range of 50 to 150° C.

In the above-mentioned reaction, an acid catalyst is generally used.

Furthermore, in the aforementioned reaction, the dehydrating agent as mentioned above can be added.

The amount of the alcohol represented by the formula (14) that is used in the reaction is in the range of 0.5 to 3 moles per 1 mole of the alcohol represented by the formula (15), and preferably in the range of 1 to 2 moles. For the acid catalyst in the etherification reaction, the amount of catalyst can also correspond to the amount of solvent, and is generally in the range of 0.001 to 5 moles per 1 mole of the alcohol represented by the formula (15). The dehydrating agent in the etherification reaction is in the range of 0.5 to 5 moles per 1 mole of the alcohol represented by the formula (15), and is preferably in the range 1 to 3 moles.

For the reaction of the an alcohol represented by the formula (16) and an alcohol represented by the formula (17), the alcohol represented by the formula (17) can be converted into a compound represented by the formula (18), and a reaction can also be carried out with the compound represented by the formula (18) and the alcohol represented by the formula (16).

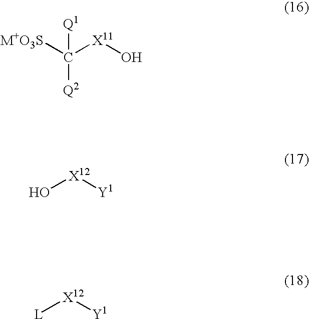

wherein L represents a chloride, bromine, iodine, mesyloxy group, tosyloxy group or trifluoromethanesulfonyloxy group.

The conversion of the alcohol represented by the formula (17) into the compound represented by the formula (18) can be carried out, for example, by reaction of the alcohol represented by the formula (17) with thionyl chloride, thionyl bromide, phosphorus trichloride, phosphorus pentachloride, phosphorus tribromide, mesyl chloride, tosyl chloride or trifluoromethanesulfonic acid anhydride.

The aforementioned reaction is carried out in the above-mentioned inert solvents. Additionally, the aforementioned reaction is carried out by stirring in the temperature range of −70 to 200° C., preferably in the temperature range of −50 to 150° C. Moreover, the use of the acid trapping agent as mentioned above is appropriate.

The amount of the base used can also correspond to the amount of solvent, and is generally in the range of 0.001 to 5 moles per 1 mole of the alcohol represented in the formula (17), preferably in the range of 1 to 3 moles.

By reacting the obtained compound represented by the formula (18) in an inert solvent with the alcohol represented by the formula (16), the salt that has the anion represented by the formula (ID) can be obtained. The reaction is carried out by stirring in the temperature range of 20 to 200° C., preferably in the temperature range of 50 to 150° C.

For the aforementioned reaction, the use of an acid trapping agent is appropriate.

When the acid trapping agent is used, its amount can also correspond to the amount of solvent, and is generally in the range of 0.001 to 5 moles per 1 mole of the compound represented by the formula (18), preferably 1 to 3 moles.

The resin (B) includes a structural unit (b1) derived from a monomer that is made alkali soluble by the action of an acid, a structural unit (b2) derived from a monomer that has an adamantyl group substituted with at least 2 hydroxyl groups, and a structural unit (b3) derived from a monomer that has a lactone ring.

Examples of the structural unit (b1) derived from a monomer that is made alkali soluble by the action of acid include the structural unit represented by the formula (II).

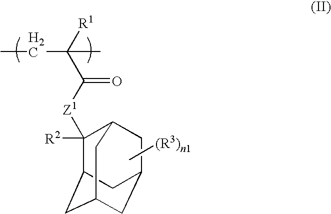

wherein Z¹ represents a single bond or —[CH₂]ₖ₁—, and a —CH₂— contained in —[CH₂]ₖ₁— may be replaced by —CO—, —O—, —S— or —N[R^{C1}]—;

k1 represents an integer 1 to 17;

R^{c1} represents a hydrogen atom or a C₁ to C₆ aliphatic hydrocarbon group;

R¹ represents a hydrogen atom or a methyl group;

R² represents a C₁ to C₆ aliphatic hydrocarbon group;

R³ represents a methyl group; and,

n1 represents an integer 0 to 14.

Examples of a group in which the —CH₂— contained in —[CH₂]ₖ₁— is replaced by —CO—, —O—, —S— or —N[R^{C1}]— include (O)—X¹¹—CO—O—, (O)—X¹¹—O—, (O)—CO—O—X¹¹—, (O)—O—CO—X¹¹—, (O)—X¹¹—S— and (O)[R^{C1}]—, in addition to the aforementioned groups. Among these, it is preferably (O)—X¹¹—CO—O—, (O)—X¹¹—O, —(O)—CO—O—X¹¹— and (O)—O—CO—X¹¹—, in addition to —O— and/or —CO—. The group X¹¹ is the same meaning described above.

The Examples of monomers from which the structural unit represented by the formula (II) is derived include the followings.

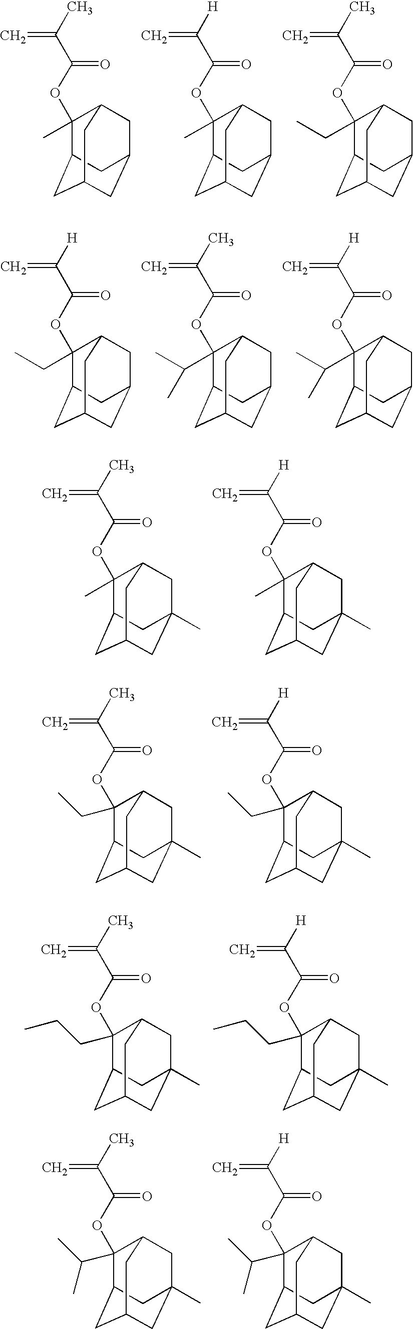

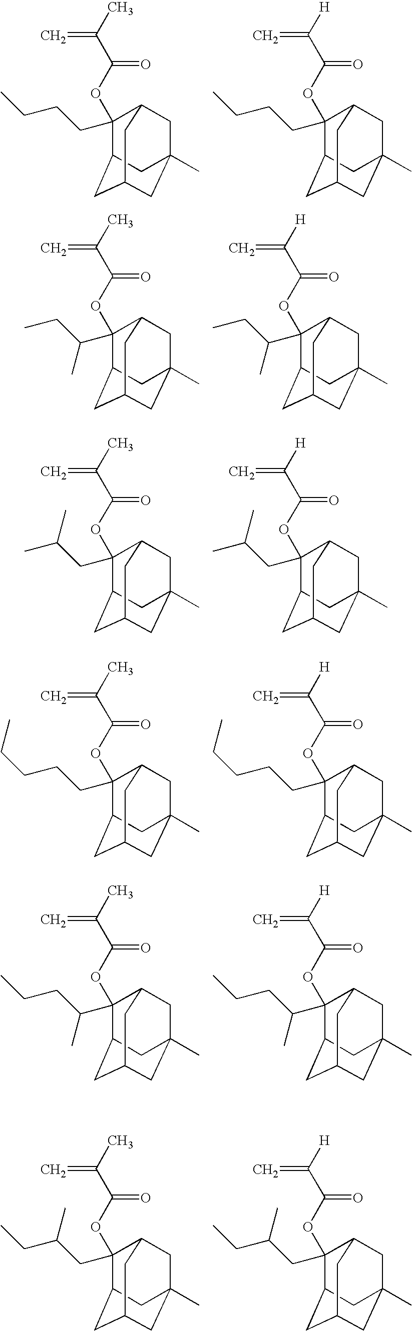

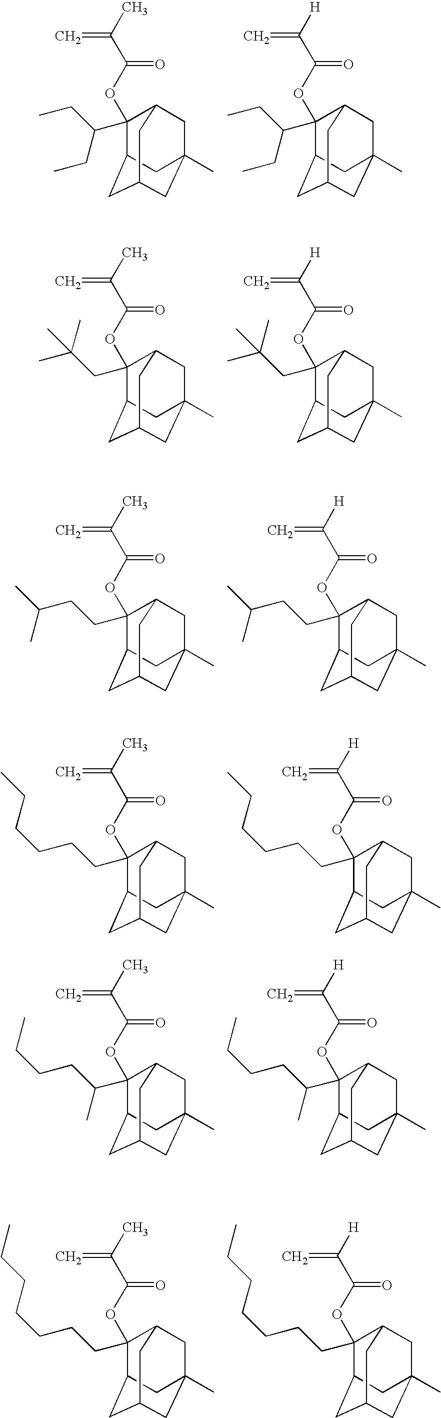

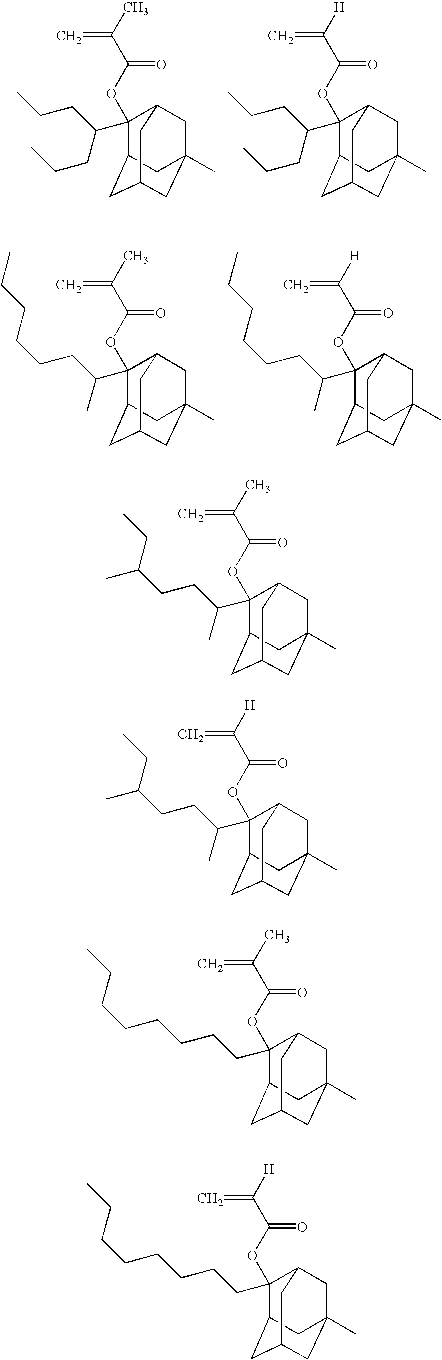

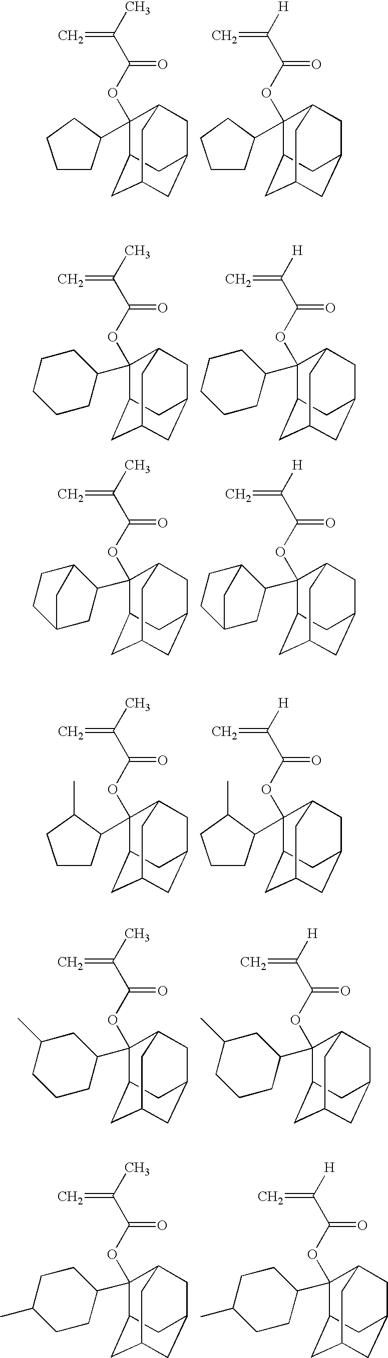

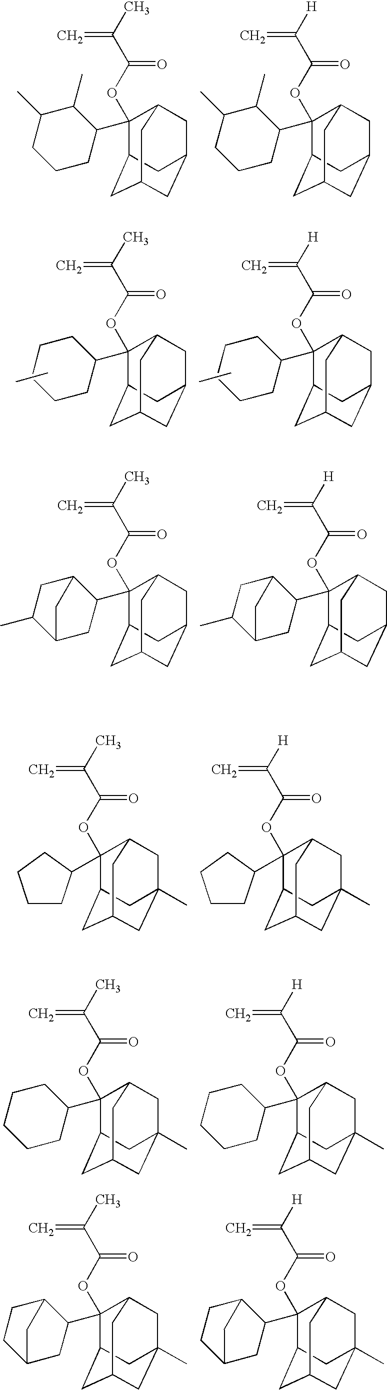

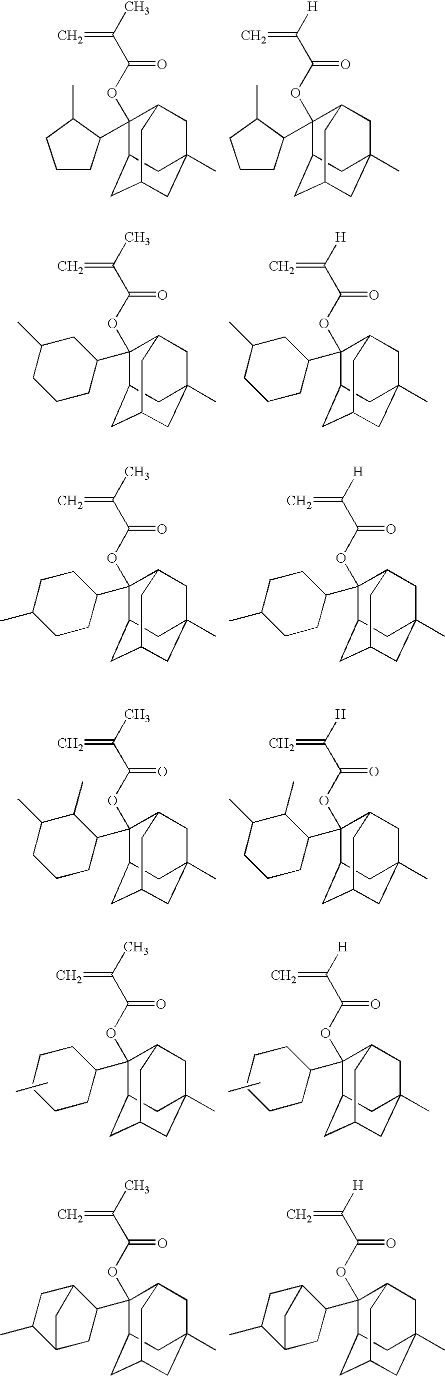

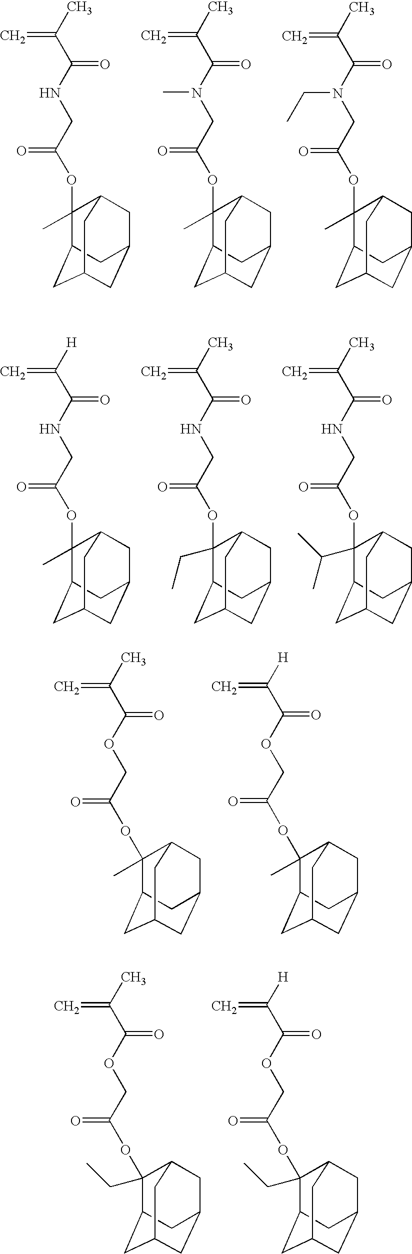

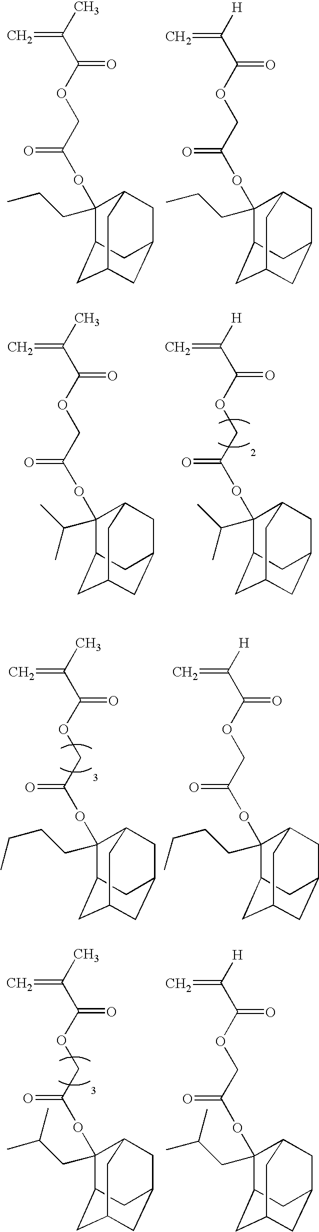

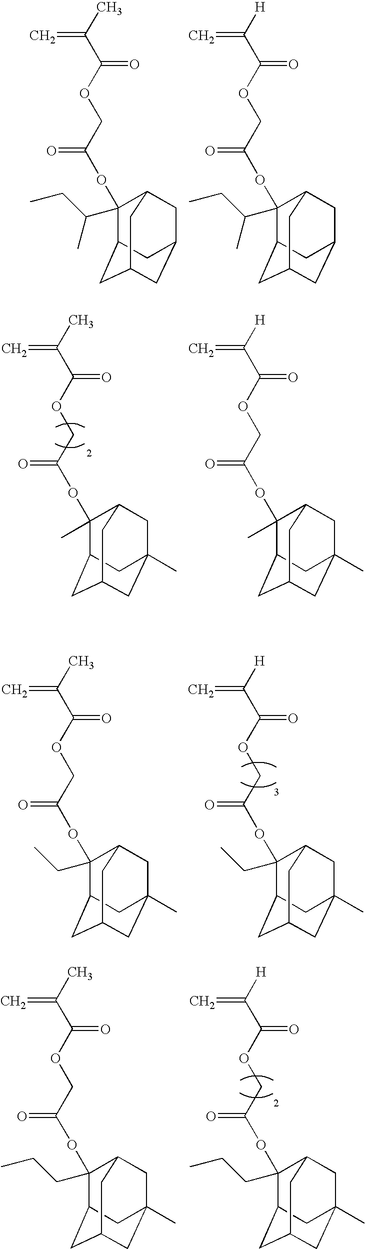

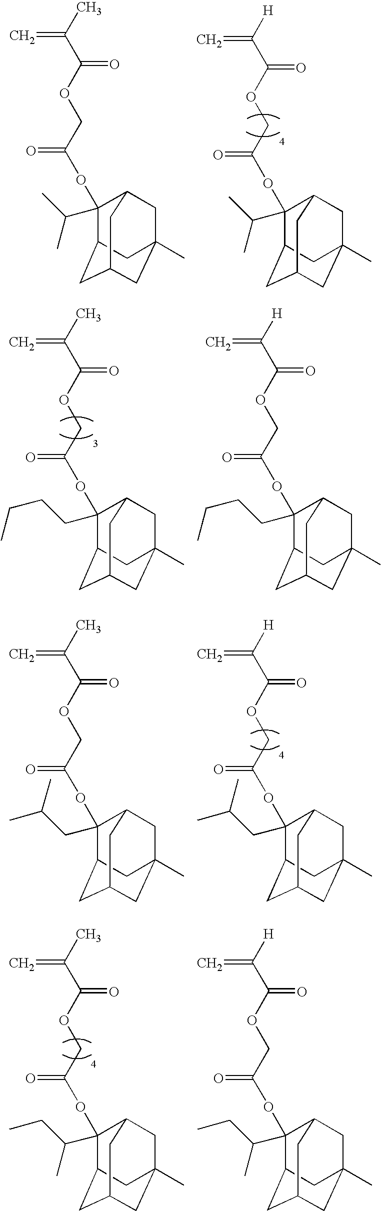

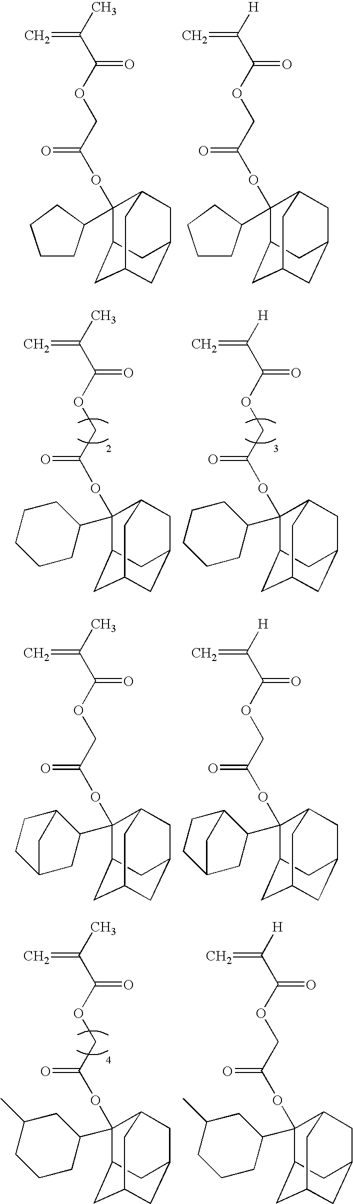

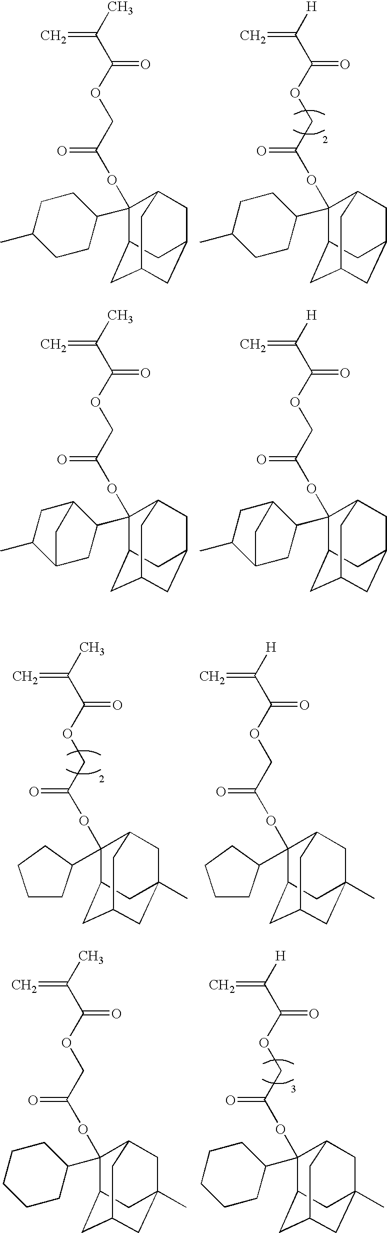

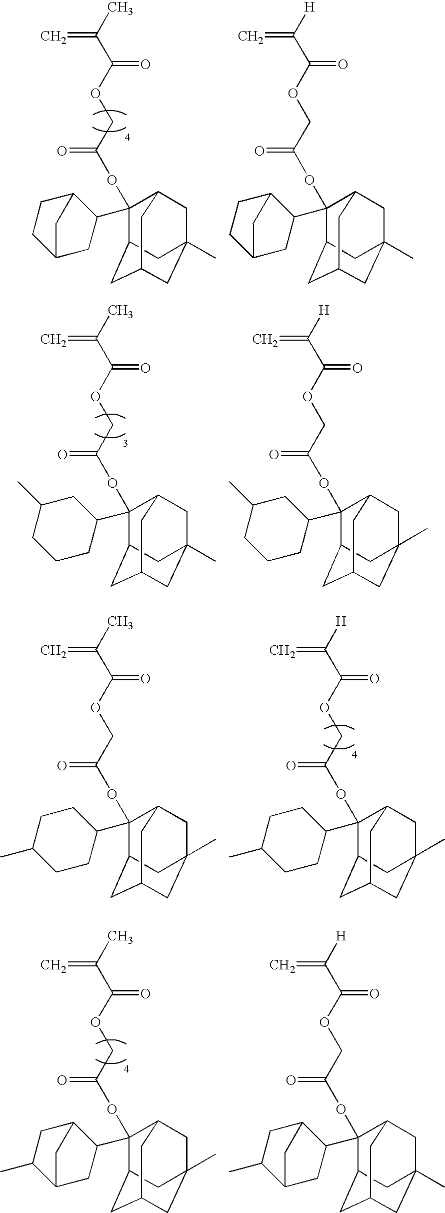

Among these, 2-methyl-2-adamantylacrylate, 2-methyl-2-adamantylmethacrylate, 2-ethyl-2-adamantylacrylate, 2-ethyl-2-adamantylmethacrylate, 2-isopropyl-2-adamantylacrylate, 2-isopropyl-2-adamantylmethacrylate and the like are preferred.

The content of the structural unit (b1) derived from a monomer that becomes soluble in an alkali by the action of the acid are suitably adjusted to within a range of 10 to 95 mol %, and preferably about 15 to 90 mol %, with respect to the total structural units constituting the resin.

The structural unit (b2) derived from a monomer that has the adamantyl group having at least two hydroxyl groups is a structural unit derived from a monomer having the adamantyl group that has two or more hydroxyl groups (however, excluding the —OH group of carboxyl group) in its side chains.

Examples of such structural units include various types of carboxylic acid esters, for example a cycloalkyl ester such as cyclopentyl ester, cyclohexyl ester, and a polycyclic ester such as norbornyl ester, 1-adamantyl ester, 2-adamantyl ester that contains structures wherein the hydrogen atoms are partially substituted with hydroxyl groups.

Examples of the aforementioned (b2) include the structural unit represented by the formula (III).

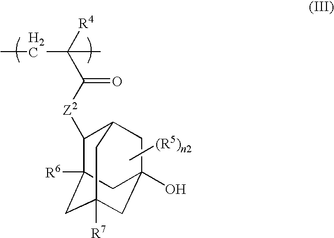

wherein R⁴ represents a hydrogen atom or a methyl group;

R⁵ represents a methyl group;

R⁶ and R⁷ independently represent a hydrogen atom, a methyl group or a hydroxyl group, provided that at least one of either R⁶ and R⁷ represents a hydroxyl group;

n2 represents an integer 0 to 10;

Z² represents a single bond or —[CH₂]ₖ₂—, and a —CH₂— contained in the —[CH₂]ₖ₂— may be replaced by —CO—, —O—, —S— or —N[R^{C2}]—;

k2 represents an integer 1 to 17;

R^{c2} represents a hydrogen atom or a C₁ to C₆ aliphatic hydrocarbon group.

Examples of a group in which —CH₂— contained in the —[CH₂]ₖ₂— is replaced by —CO—, —O—, —S— or —N[R^{C2}]— include (O)—X¹¹—CO—O—, (O)—X¹¹—O—, —(O)—CO—O—X¹¹—, (O)—O—CO—X¹¹—, (O)—X¹¹—S— and (O)[R^{C2}]—, in addition to the aforementioned groups. Among these, it is preferably (O)—X¹¹—CO—O—, —(O)—CO—O—X¹¹— and (O)—O—CO—X¹¹—, in addition to a group substituted with —O— and/or —CO—. The group X¹¹ is the same meaning described above.

The Examples of monomers from which the structural unit represented by the formula (III) is derived include the followings.

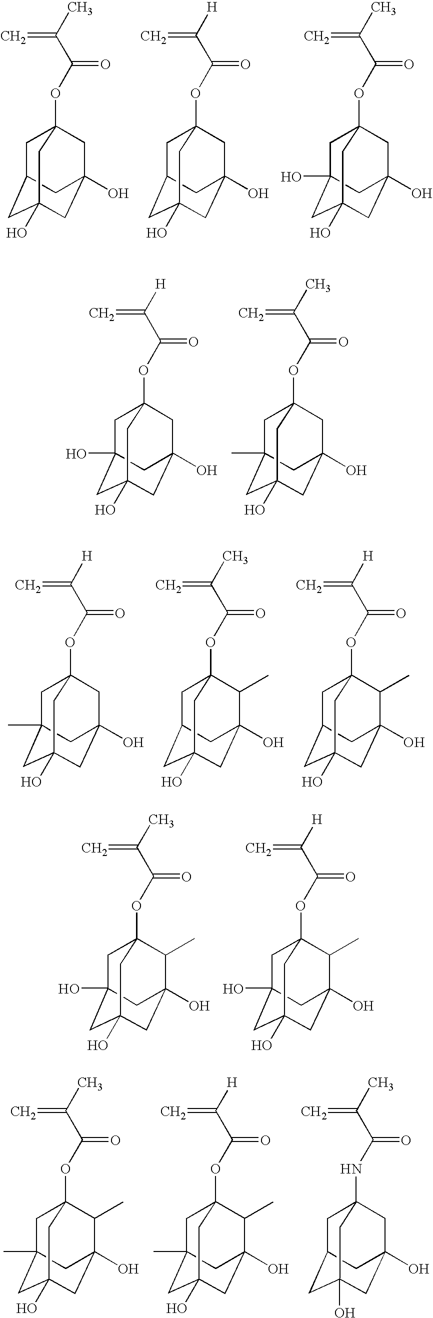

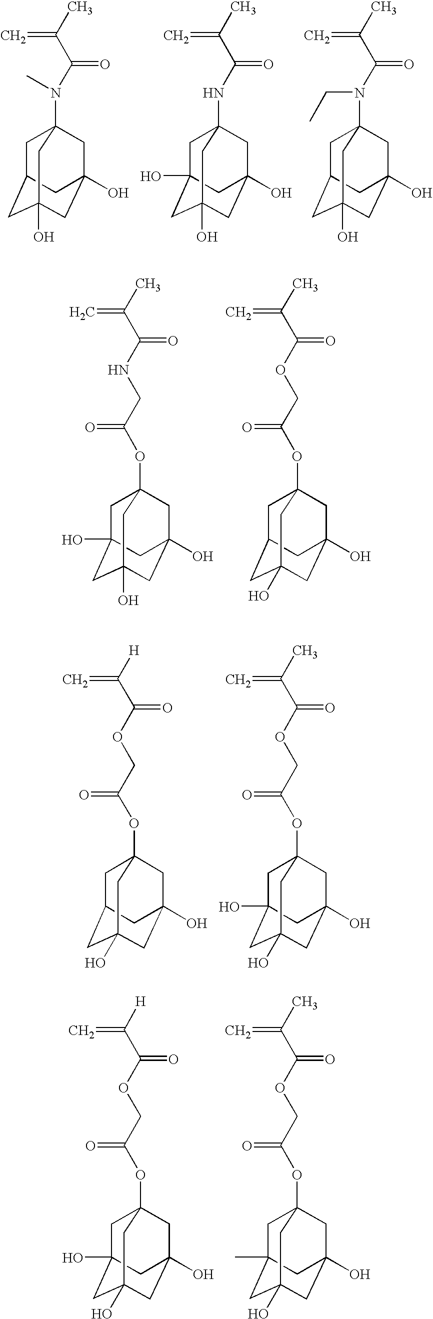

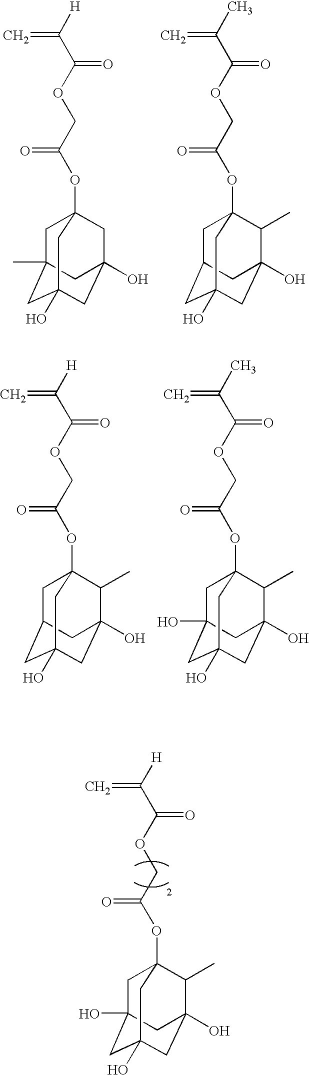

Among these, 3,5-dihydroxy-1-adamantyl acrylate, 3,5-dihydroxy-1-adamantyl methacrylate, 1-(3,5-dihydroxy-1-adamantyloxycarbonyl)methyl acrylate and 1-(3,5-dihydroxy-1-adamantyloxycarbonyl)methyl methacrylate are preferable, and 3,5-dihydroxy-1-adamantyl acrylate and 3,5-dihydroxy-1-adamantyl methacrylate are more preferable.

The content of the structural unit (b2) derived from a monomer that has the adamantyl group having at least two hydroxyl groups is suitably adjusted to within a range of 3 to 45 mol %, and preferably about 5 to 35 mol %, and more preferably about 5 to 30 mol %, with respect to the total structural units constituting the resin.

Examples of the structural unit (b3) derived from a monomer that has a lactone structure include compounds that include the β-butyrolactone structure, compounds that include the γ-butyrolactone structure, and compounds that have the lactone structure added onto a cycloalkyl skeleton or norbornane skeleton.

Among these, examples preferably include structural units represented by either the formula (IVa), the formula (IVb) or the formula (IVc).

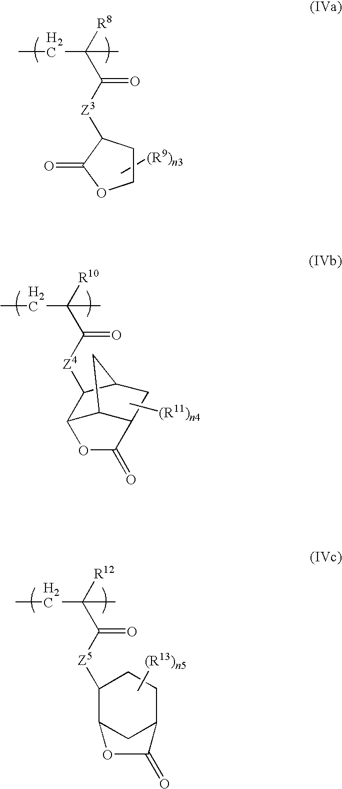

wherein R⁸, R¹⁰ and R¹² independently represents a hydrogen atom or a methyl group;

R⁹ represents a methyl group;

n3 represents an integer 0 to 5, when n3 is 2 or more, the plurality of R⁹ can be the same or different;

R¹¹ and R¹³ are independently in each occurrence a carboxy group, a cyano group or a C1 to C4 hydrocarbon group;

n4 and n5 represent an integer 0 to 3;

Z³, Z⁴ and Z⁵ independently represent a single bond or —[CH₂]ₖ₃—, and a —CH₂— contained in the —[CH₂]ₖ₃— may be replaced by —CO—, —O—, —S— or —N[R^{C3}]—;

k3 represents an integer 1 to 8;

R^{c3} represents a hydrogen atom or a C₁ to C₆ aliphatic hydrocarbon group.

The Examples of monomers from which the structural unit represented by the formula (IVa) is derived include the followings.

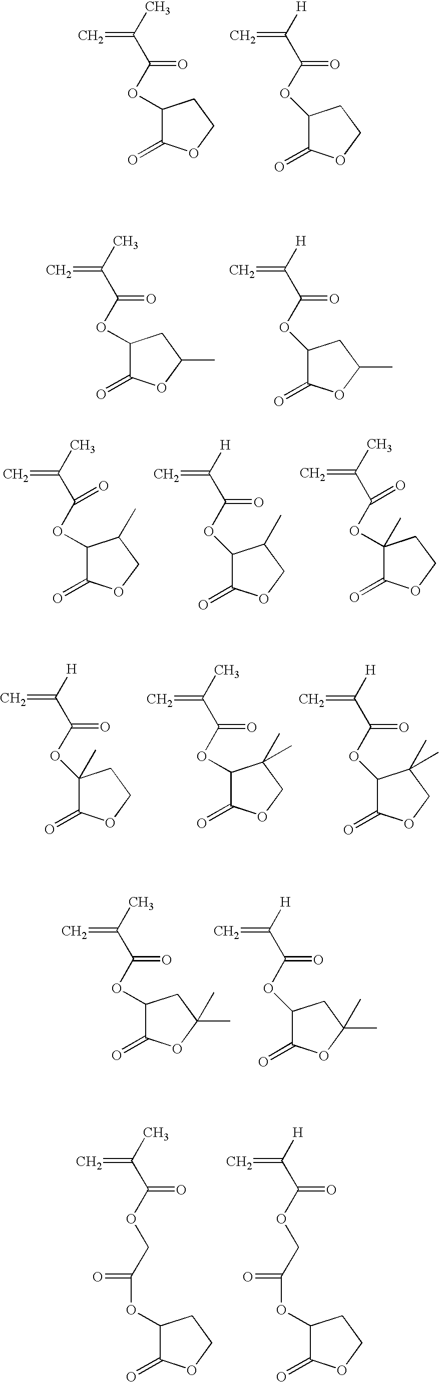

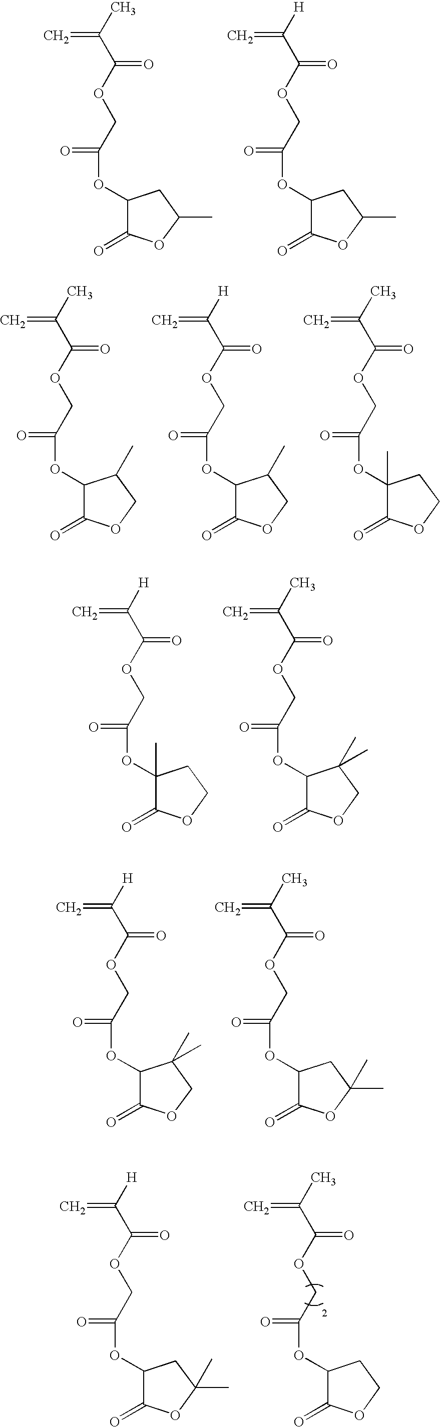

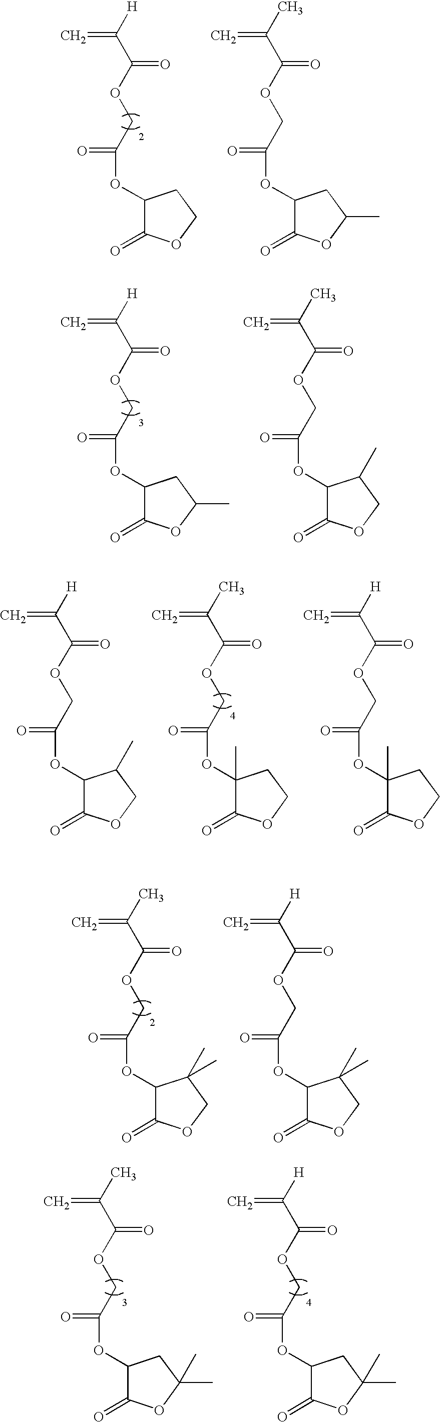

The Examples of monomers from which the structural unit represented by the formula (IVb) is derived include the followings.

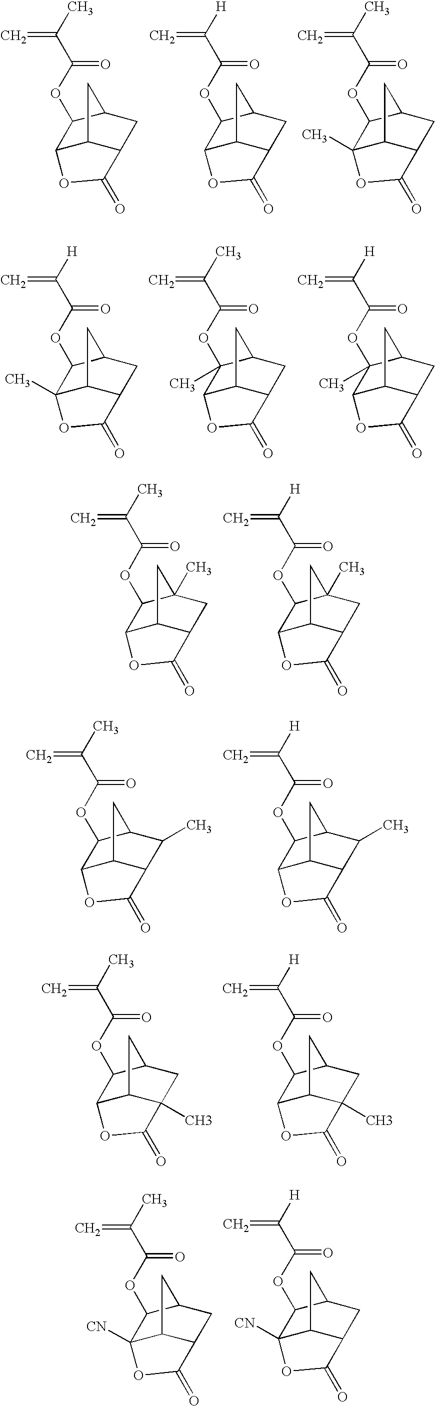

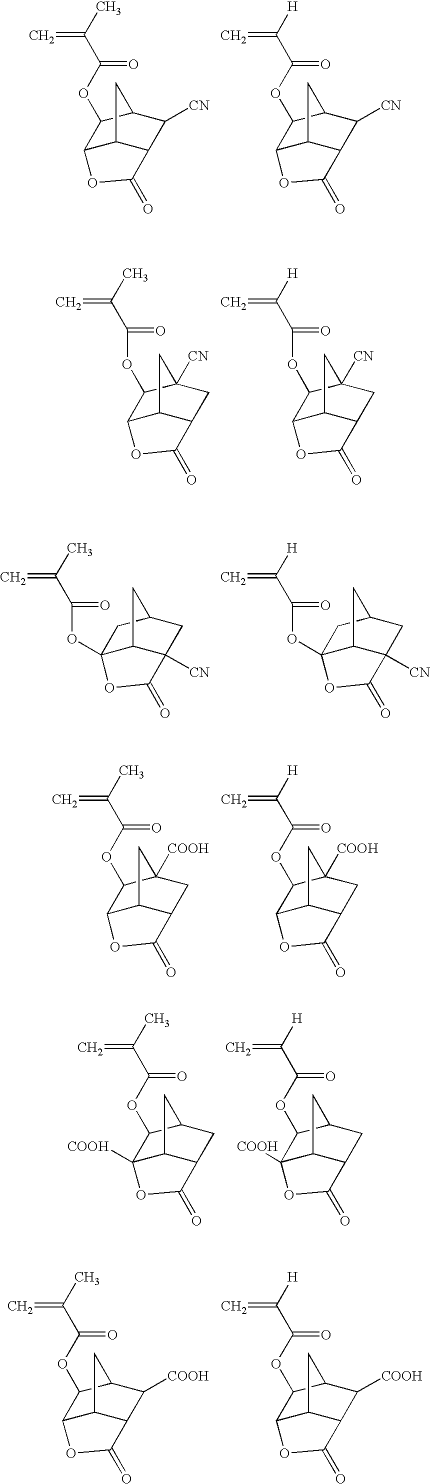

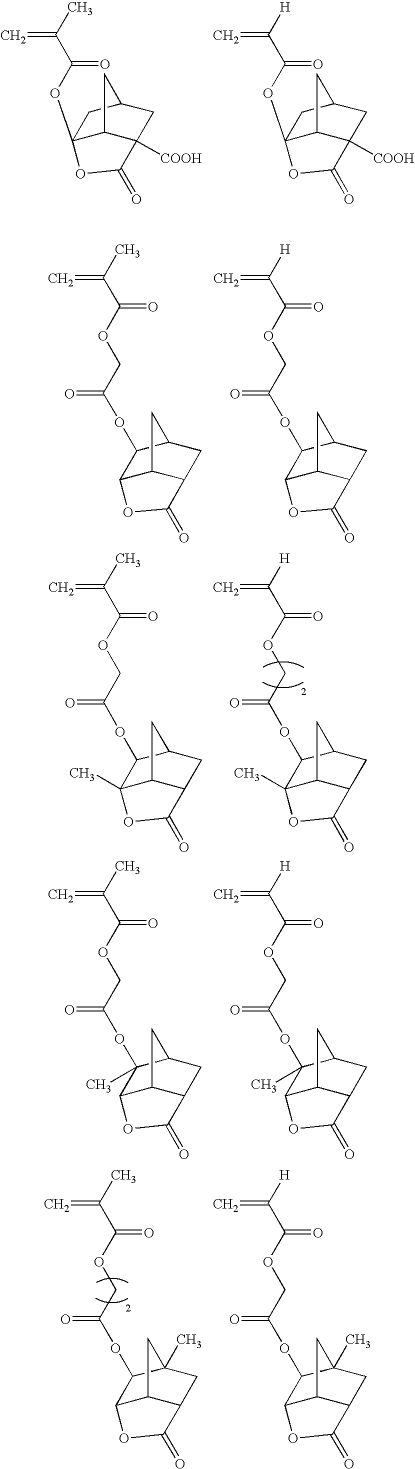

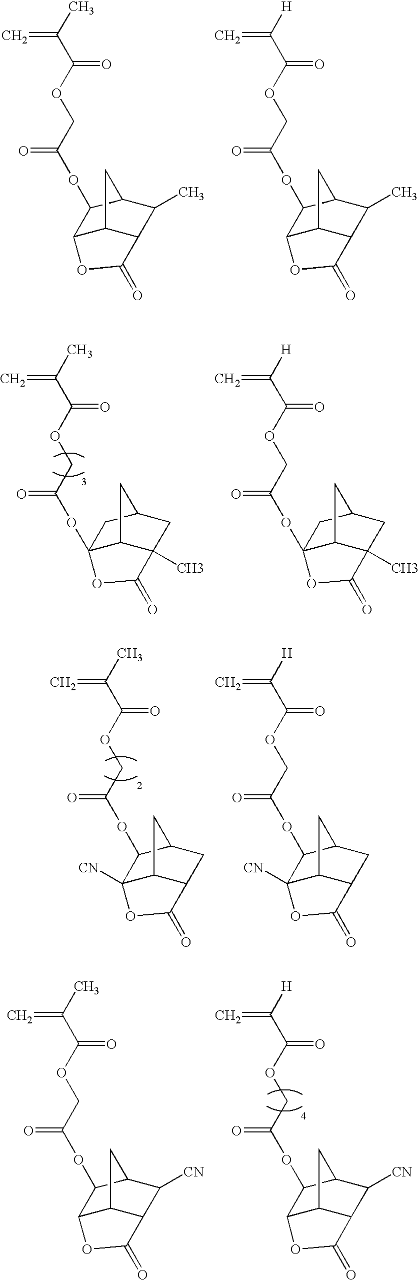

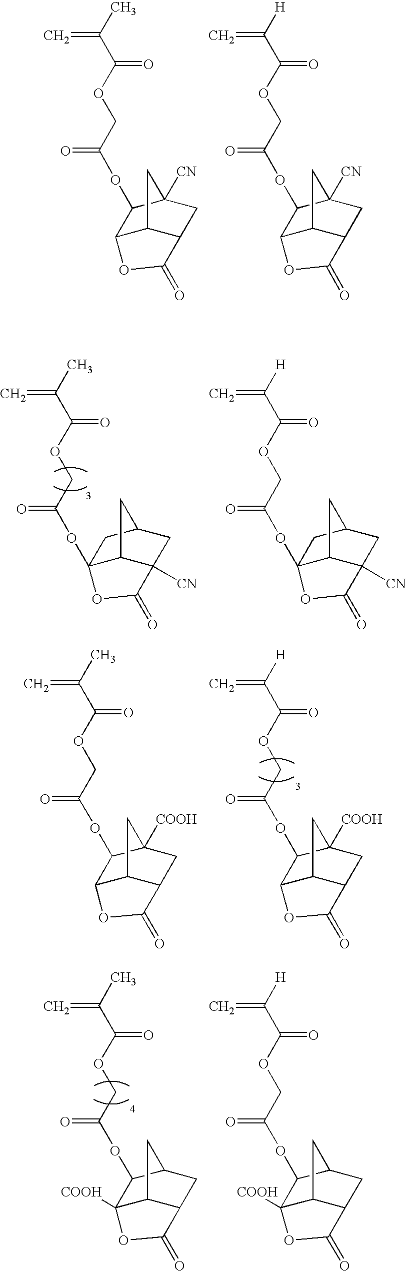

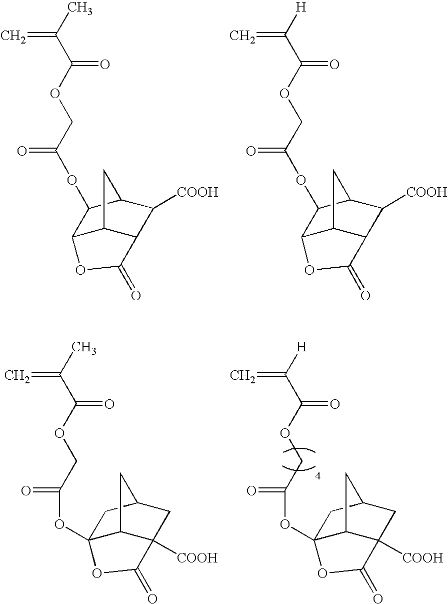

The Examples of monomers from which the structural unit represented by the formula (IVc) is derived include the followings.

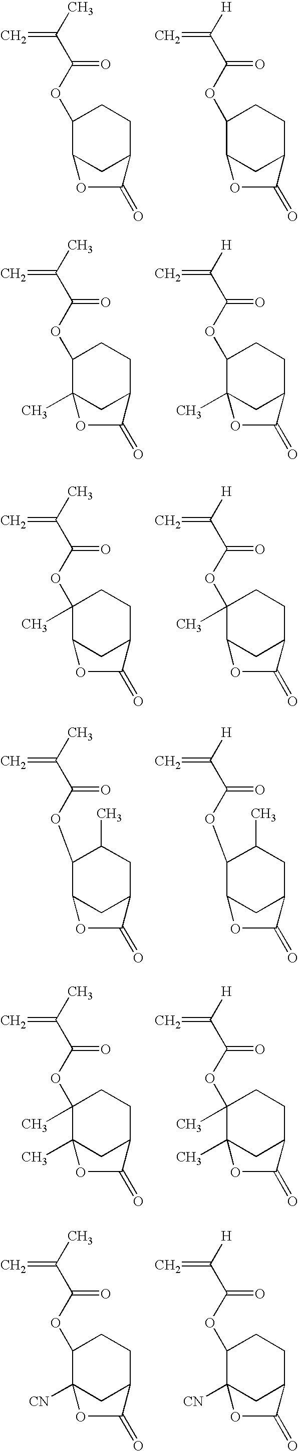

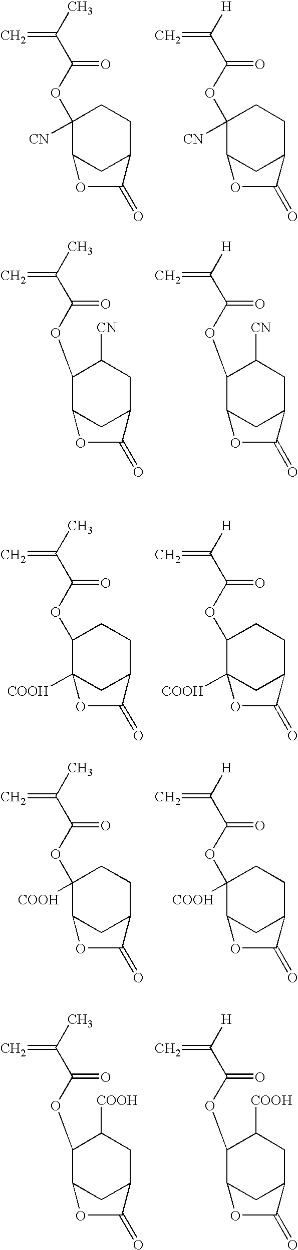

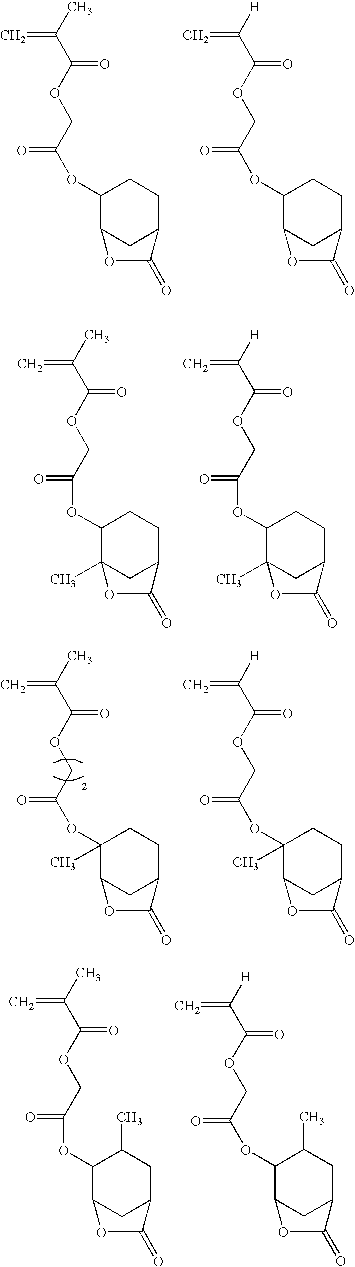

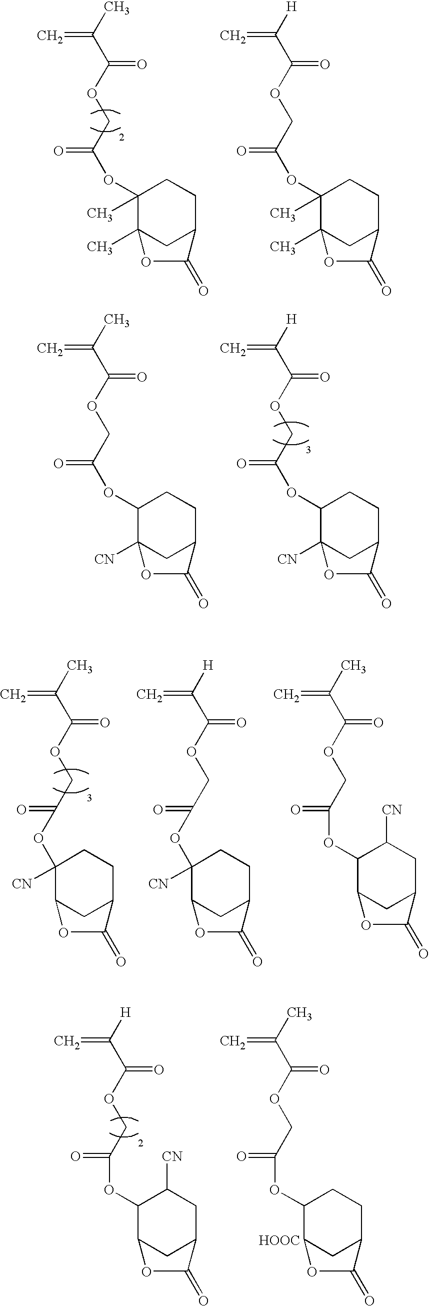

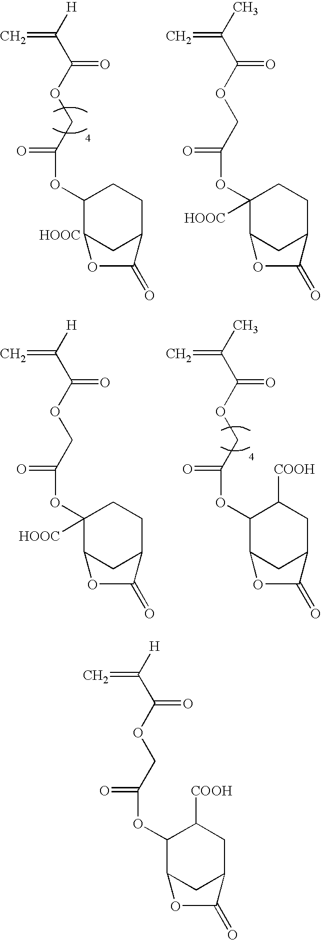

Among these, hexahydro-2-oxo-3,5-methano-2H-cyclopenta[b]furan-6-yl (meth)acrylate, tetrahydro-2-oxo-3-furyl (meth)acrylate, and 2-(5-oxo-4-oxatricyclo[4.2.1.0^{3,7}]nonane-2-yloxy)-2-oxoethyl (meth)acrylate are preferable.

The content of the structural unit (b3) derived from a monomer that has a lactone structure is suitably adjusted to within a range of 5 to 50 mol %, and preferably about 10 to 45 mol %, and more preferably about 15 to 40 mol %, with respect to the total structural units constituting the resin.

The resin has the above-mentioned structural units (b1) to (b3), and may be contain the structural units (b1) to (b3), respectively, and may contain the combination of two or more thereof.

Additionally, it may have one or two or more of structural units other than the structural units [b1] to [b3].

Examples of the structural units other than the structural units (b1) to (b3) include a structural unit having a monohydroxy adamantyl group, more specifically those below.

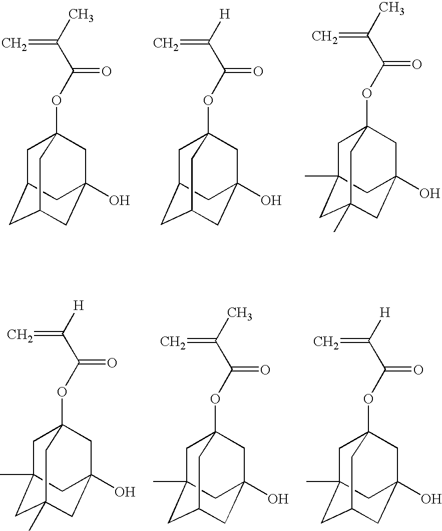

The content of the structural unit having monohydroxy adamantyl group is suitably adjusted to within a range of 5 to 50 mol %, and preferably about 10 to 45 mol %, and more preferably about 15 to 40 mol %, with respect to the total structural units constituting the resin.

The structural unit other than the structural units (b1) to (b3) may also include a structural unit derived from 2-norbornene, for example. The structural unit derived from 2-norbornene is formed upon the opening of the double bond in the norbornene structure, and can be represented by the formula (d). 2-norbornene can be introduced into the main chain during polymerization, for example, by radical polymerization with the combined use of an aliphatic unsaturated dicarboxylic anhydride such as maleic anhydride or itaconic anhydride in addition to the corresponding 2-norbornene. The structural unit derived from maleic anhydride or itaconic anhydride is formed upon the opening of the double bond of maleic anhydride or itaconic anhydride, and can be represented by the formulas (e) and (f), respectively.

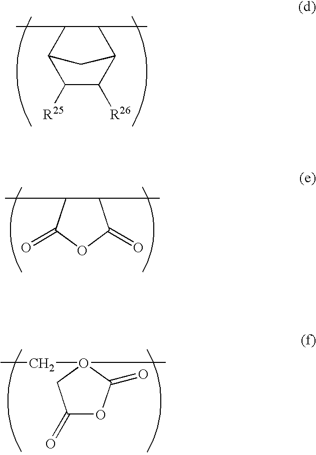

Herein R²⁵ and R²⁶ in the formula (d) independently represent a hydrogen atom, a C₁ to C₃ aliphatic hydrocarbon group, a carboxyl group, a cyano group, or —COOU wherein U is an alcohol residue, or R²⁵ and R²⁶ are bonded together to form a carboxylic anhydride residue represented by —C(═O)OC(═O)—.

The —COOU group is an ester formed from carboxyl group, and examples of the alcohol residue corresponding to U include an optionally substituted C₁ to C₈ aliphatic hydrocarbon group, and 2-oxooxolan-3- or -4-yl group.

Examples of the substituent for the aliphatic hydrocarbon group include a hydroxyl and a C₄ to C₃₆ saturated cyclic hydrocarbon residue groups.

Examples of the aliphatic hydrocarbon group for R²⁵ and R²⁶ include methyl, ethyl and propyl groups, and specific examples of the aliphatic hydrocarbon group to which a hydroxyl group is bonded include hydroxymethyl, and 2-hydroxyethyl groups.

The Examples of monomers from which the norbornene structural represented by the formula (d) is derived include 2-norbornene, 2-hydroxy-5-norbornene, 5-norbornene-2-carboxylic acid, methyl 5-norbornene-2-carboxylate, 2-hydroxy-1-ethyl 5-norbornene-2-carboxylate, 5-norbornene-2-methanol, and 5-norbornene-2,3-dicarboxylic acid anhydride.

The content of the structural unit derived from the monomer represented by the formula (d), the formula (e) or the formula (f) is suitably adjusted to within a range of 2 to 40 mol %, and preferably about 3 to 30 mol %, and more preferably about 5 to 20 mol %, with respect to the total structural units constituting the resin.

When U in —COOU in the formula (d) is an acid-labile group, such as an saturated cyclic ester in which the carbon atom bonded to the oxygen side of the carboxyl group is a quaternary carbon atom, the structural unit will have an acid-labile group, despite having a norbornene structure.

Specific examples of the monomer contain such norbornene structure and the acid-labile group include, t-butyl 5-norbornene-2-carboxylate, 1-cyclohexyl-1-methylethyl 5-norbornene-2-carboxylate, 1-methylcyclohexyl-5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxycyclohexyl)-1-methylethyl 5-norbornene-2-carboxylate, 1-methyl-1-(4-oxocyclohexyl)ethyl 5-norbornene-2-carboxylate, and 1-(1-adamantyl)-1-methylethyl 5-norbornene-2-carboxylate.

The content of the acid generator in the resist composition of the present invention is preferably adjusted to within a range of about 1 to 20 parts by weight, and more preferably about 1 to 15 parts by weight with respect to the 100 parts by weight of the resin.

The resist composition of the present invention may include a basic compound along with the acid generator and resin. As the basic compounds, nitrogen-containing basic compounds are preferable and, amines and ammonium salts are more preferable. The basic compound can be added as a quencher to improve performance from being compromised by the inactivation of the acid while the material is standing after exposure.

The Examples of such basic compounds include those represented by the following formulae.

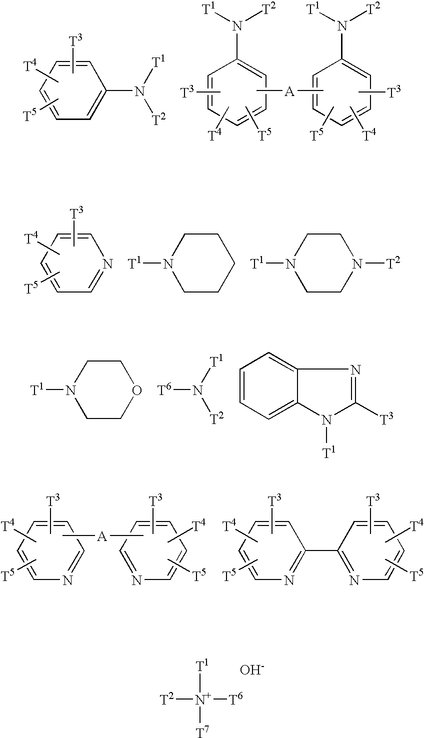

wherein T¹, T², and T⁷ independently represent a hydrogen atom, a C₁ to C₆ aliphatic hydrocarbon group, a C₅ to C₁₀ saturated cyclic hydrocarbon group, or a C₆ to C₂₀ aromatic hydrocarbon group, the hydrogen atom contained in the aliphatic hydrocarbon, saturated cyclic hydrocarbon and aromatic hydrocarbon groups may have at least one substituent selected from the group consisting of a hydroxyl group, an amino group and a C₁ to C₆ alkoxyl group, the hydrogen atom contained in the amino group may substituted with a C₁ to C₄ aliphatic hydrocarbon group;

T³ to T⁵ independently represent a hydrogen atom, a C₁ to C₆ aliphatic hydrocarbon group, a C₁ to C₆ alkoxyl group, a C₅ to C₁₀ saturated cyclic hydrocarbon group, or a C₆ to C₂₀ aromatic hydrocarbon group, the hydrogen atom contained in the aliphatic hydrocarbon, alkoxyl, saturated cyclic hydrocarbon and aromatic hydrocarbon groups may have at least one substituent selected from the group consisting of a hydroxyl group, an amino group and a C₁ to C₆ alkoxy group, the hydrogen atom contained in the amino group may substituted with a C₁ to C₄ aliphatic hydrocarbon group;

T⁶ represents a C₁ to C₆ aliphatic hydrocarbon group and a C₅ to C₁₀ saturated cyclic hydrocarbon group, the hydrogen atom contained in the aliphatic hydrocarbon and saturated cyclic hydrocarbon groups may have at least one substituent selected from the group consisting of a hydroxyl group, an amino group and a C₁ to C₁₀ alkoxy group, the hydrogen atom contained in the amino group may substituted with a C₁ to C₄ aliphatic hydrocarbon group;

A represents a C₁ to C₆ alkylene group, a carbonyl group, an imino group, a sulfide group or a disulfide group.

Examples of such compounds include diisopropylaniline, hexylamine, heptylamine, octylamine, nonylamine, decylamine, aniline, 2-, 3- or 4-methylaniline, 4-nitroaniline, 1- or 2-naphtylamine, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, dibutylamine, dipentylamine, dihexylamine, diheptylamine, dioctylamine, dinonylamine, didecylamine, N-methylaniline, piperidine, diphenylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethydipentylamine, ethyldihexylamine, ethydiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-isopropylaniline, imidazole, pyridine, 4-methylpyridine, 4-methylmidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(4-pyridyloxy)ethane, 4,4′-dipyridyl sulfide, 4,4′-dipyridyl disulfide, 1,2-bis(4-pyridyl)ethylene, 2,2′-dipicolylamine, 3,3′-dipicolylamine, tetramethylammonium hydroxide, tetraisopropylammonium hydroxide, tetrabutylammonium hydroxide, tetra-n-hexylammonium hydroxide, tetra-n-octylammonium hydroxide, phenyltrimethylammonium hydroxide, 3-(trifluoromethyl)phenyltrimethylammonium hydroxide, and choline.

Furthermore, hindered amine compounds with a piperidine skeleton such as those disclosed in JP-A-H11-52575 can be used as a quencher.

Among these, diisopropylaniline and the quaternary ammonium salt described above formula are suitable. Specific examples include tetramethylammonium hydroxide, tetrabutylammonium hydroxide, tetrahexylammonium hydroxide, tetraoctylammonium hydroxide, phenyltrimethylammonium hydroxide, and 3-trifluoromethyl-phenyl trimethylammonium hydroxide.

The content of the basic compound serving as a quencher in the resist composition, if used, is preferably in the range of about 0.01 to 5 parts by weight, and more preferably about 0.05 to 3 parts by weight with respect to 100 parts by weight of the resin.

The resist composition of the present invention is usually a resist solution, with the various ingredients above dissolved in a solvent.

Examples of the solvent include glycol ether esters such as ethylcellosolve acetate, methylcellosolve acetate and propylene glycol monomethyl ether acetate; esters such as ethyl lactate, butyl acetate, amyl acetate and ethyl pyruvate; ketones such as acetone, methyl isobutyl ketone, 2-heptanone and cyclohexanone; cyclic esters such as γ-butyrolactone; and propylene glycol monomethyl ether. These solvents can be used alone or in combination of two or more.

The resist composition can also include various additives such as sensitizers, dissolution inhibitors, other resins, surfactants, stabilizers and dyes, as needed. Any additive that is known in this field can be used.

The method for pattern formation of the present invention includes steps of:

(1) applying the abovementioned resist composition of the present invention onto a substrate;
(2) removing solvent from the applied composition to form a composition layer;
(3) exposing to the composition layer using an exposure device;
(4) heating the exposed composition layer and,
(5) developing the heated composition layer using a developing apparatus.

The application of the resist composition onto the substrate can generally be carried out through the use of a device such as a spin coater.

The removal of the solvent, for example, can either be carried out by evaporation of the solvent using a heating device such as a hotplate, or can be carried out using a decompression device, and a composition layer with the solvent removed is formed. The temperature in this case is usually the range of 50 to 200° C. Moreover, the pressure is usually the range of 1 to 1.0×10⁵ Pa.

The composition layer obtained is exposed to light using an exposure device or a liquid immersion exposure device. In this case, the exposure is generally carried out through a mask that corresponds to the required pattern. Various types of exposure light source can be used, such as irradiation with ultraviolet lasers such as KrF excimer laser (wavelength: 248 nm), ArF excimer laser (wavelength: 193 nm), F₂ laser (wavelength: 157 nm), or irradiation with far-ultraviolet wavelength-converted laser light from a solid-state laser source (YAG or semiconductor laser or the like) or vacuum ultraviolet harmonic laser light or the like.

After exposure, the composition layer is subjected to a heat treatment to promote the deprotection reaction. The heating temperature is generally in the range of 50 to 200° C., preferably in the range of 70 to 150° C.

The composition layer is developed after the heat treatment, generally by utilizing an alkaline developing solution using a developing apparatus. Here, for the alkaline developing solution, various types of aqueous alkaline solutions used in this field can be satisfactory. Examples include aqueous solutions of tetramethylammonium hydroxide and (2-hydroxyethyl)trimethylammonium hydroxide (common name: choline).

After developing, it is preferable to rinse with ultrapure water and to remove any residual water on the substrate and the pattern.

### EXAMPLES

The resist composition of the present invention will be described more specifically by way of examples, which are not construed to limit the scope of the present invention.

All percentages and parts expressing the content or amounts used in the Examples, Comparative Examples and Reference Examples are based on weight, unless otherwise specified.

The weight average molecular weight is a value determined by gel permeation chromatography (Toso Co. ltd. HLC-8120GPC type, coulum: three of TSK gel Multipore HXL-M, solvent: tetrahydroflun) using polystyrene as the standard product.

Columun: TSKgel Multipore H_{XL}-M 3 connecting+guardcolumn (Toso Co. ltd.)

Eluant: tetrahydrofuran

Flow rate: 1.0 mL/min

Detecting device: RI detector

Columun temperature: 40° C.

Injection amount: 100 μL

Standard material for calculating molecular weight: standard polysthylene (Toso Co. ltd.)

The structures of the compounds were verified by NMR (Nippon electric, GX-270 type or EX-270 type) and mass analysis (LC: Agilent 1100 type, MASS: Agilent LC/MSD type or LC/MSD TOF type).

### Synthesis Example 1

### Acid Generator A1

To a mixture of 100 parts of methyl difluoro(fluorosulfonyl)acetate and 150 parts of ion-exchanged water, 230 parts of 30% sodium hydroxide aqueous solution was added in the form of drops in an ice bath. The resultant mixture was refluxed for 3 hours at 100° C., cooled, and then neutralized with 88 parts of concentrated hydrochloric acid. The resulting solution was concentrated, giving 164.4 parts of sodium salt of difluorosulfoacetic acid (containing inorganic salt: 62.7% purity). 1.0 parts of 1,1′-carbonyldiimidazol was added to a mixture of 1.9 parts of the resulting sodium salt of difluorosulfoacetic acid and 9.5 parts of N,N-dimethylformamide, and the resultant mixture was stirred for 2 hours to obtain a mixture.

Also, 0.2 parts of sodium hydride was added to a mixture of 1.1 parts of 3-hydroxyadamantyl methanol and 5.5 parts of N,N-dimethylformamide, and the resultant mixture was stirred for 2 hours. To thus obtained mixture solution, the above obtained mixture was added. The resulting mixture was stirred for 15 hours to obtain a solution containing sodium salt of ((3-hydroxy-1-adamantyl)methoxycarbonyl)difluoromethanesulfonic acid.

To thus obtained solution containing sodium salt of ((3-hydroxy-1-adamantyl)methoxycarbonyl)difluoromethanesulfonic acid 17.2 parts of chloroform and 2.9 pairs of 14.8% triphenylsulfonium chloride were added, and the resulting mixture was stirred for 15 hours, and separated to obtain an organic layer. A residual water layer was extracted with 6.5 parts of chloroform to obtain an organic layer. Further, the residual water layer was repeated extraction to obtain an additional organic layer. The obtained organic layers were mixed, and washed with ion-exchanged water, and the resulting organic layer was concentrated. To the concentrate was added 5.0 parts of tert-butyl methyl ether, the resulting mixture was stirred, and filtrated, giving 0.2 parts of triphenylsulfonium ((3-hydroxy-1-adamantyl)methoxycarbonyl) difluoromethanesulfonate (A1) in the form of a white solid.

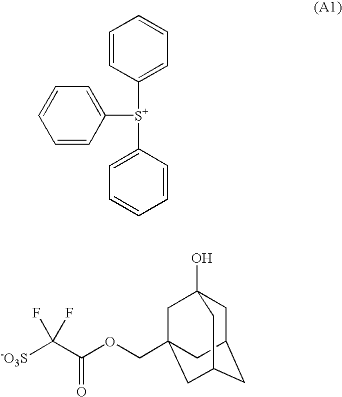

### Synthesis Example 2

### Acid Generator A2

To a mixture of 100 parts of methyl difluoro(fluorosulfonyl)acetate and 250 parts of ion-exchanged water, 230 parts of 30% sodium hydroxide aqueous solution was added in the form of drops in an ice bath. The resultant mixture was refluxed for 3 hours at 100° C., cooled, and then neutralized with 88 parts of concentrated hydrochloric acid. The resulting solution was concentrated, giving 164.8 parts of sodium salt of difluorosulfoacetic acid (containing inorganic salt: 62.6% purity). To a mixture of 5.0 parts of the resulting sodium salt of difluorosulfoacetic acid, 2.6 parts of 4-oxo-1-adamantanol, and 100 parts of ethylbenzene, 0.8 part of concentrated sulfuric acid was added, and the resultant mixture was heated to reflux for 30 hours. The reaction mixture was cooled, and filtrated to obtain a residue. The residue was washed with tert-butyl methyl ether, giving 5.5 parts of sodium salt of ((4-oxo-1-adamantyl)oxycarbonyl)difluoromethanesulfonic acid. ¹H-NMR analysis revealed a purity of 35.6%.

To 5.4 parts of the resulting sodium salt of ((4-oxo-1-adamantyl)oxycarbonyl)difluoromethanesulfonic acid, a mixture of 16 parts of acetonitrile and 16 parts of ion-exchanged water was added. To the resulting mixture, 1.7 parts of triphenylsulfonium chloride, 5 parts of acetonitrile, and 5 parts of ion-exchanged water were added. The resultant mixture was stirred for 15 hours, then concentrated, and extracted with 142 parts of chloroform to obtain an organic layer. The organic layer was washed with ion-exchanged water, and the resulting organic layer was concentrated. The concentrate was washed with 24 parts of tert-butyl methyl ether, giving 1.7 parts of triphenylsulfonium ((4-oxo-1-adamantyl)oxycarbonyl)difluoromethanesulfonate (A2) in the form of a white solid.

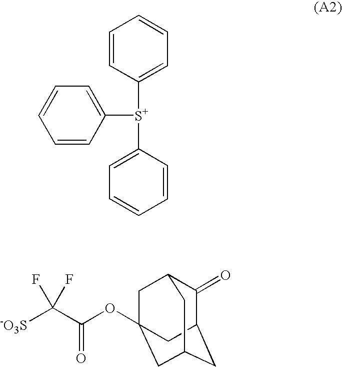

### Synthesis Example 3

### Acid Generator A3

To a mixture of 200 parts of methyl difluoro(fluorosulfonyl)acetate and 300 parts of ion-exchanged water, 460 parts of 30% sodium hydroxide aqueous solution was added in the form of drops in an ice bath. The resultant mixture was refluxed for 2.5 hours at 100° C., cooled, and then neutralized with 175 parts of concentrated hydrochloric acid. The resulting solution was concentrated, giving 328.2 parts of sodium salt of difluorosulfoacetic acid (containing inorganic salt: 63.5% purity). 39.4 parts of the resulting sodium salt of difluorosulfoacetic acid, 21.0 parts of 1-adamantanol, and 200 parts of dichloroethane were mixed, and 24.0 part of p-toluenesulfonic acid (p-TsOH) was added thereto, and the resultant mixture was heated to reflux for 7 hours, concentrated, and distilled away dichloroethane to obtain concentrated residue. To the resulting residue, tert-butyl methyl ether was added, the mixture was washed, and filtered to obtain residue. 250 parts of acetonitrile was added thereto, the resulting mixture was stirred, and filtered. The resulting filtrate was concentrated, giving 32.8 parts of sodium salt of ((1-adamantyl)methoxycarbonyl) difluoromethanesulfonic acid.

To a solution obtained by dissolving 32.8 parts of sodium salt of ((1-adamantylmethoxycarbonyldifluromethanesulfonic acid in 100 parts of ion-exchanged water, 28.3 parts of triphenylsulfonium chloride and 140 parts of methanol were added. The resulting mixture was stirred for 15 hours, and concentrated, and the concentrate was extracted 2 times with 200 parts of chloroform to obtain an organic layer. The organic layers were mixed, repeated to wash with ion-exchanged water until the organic layer obtained was neutralized, and the organic layer was concentrated. To the resulting concentrate, 300 parts of tert-butyl methyl ether was added, and the mixture was stirred, and filtrated to recover a white solid. This was dried under reduced pressure, giving 39.7 parts of triphenylsulfonium ((1-adamantyl)methoxycarbonyl)difluoromethanesulfonate (A3) as a white precipitate.

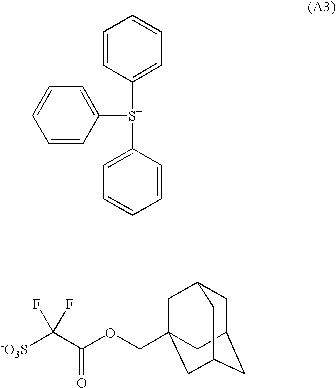

### Synthesis Example 4

### Acid Generator A4

To a mixture of 100 parts of methyl difluoro(fluorosulfonyl)acetate and 250 parts of ion-exchanged water, 230 parts of 30% sodium hydroxide aqueous solution was added in the form of drops in an ice bath. The resultant mixture was refluxed for 3 hours at 100° C., cooled, and then neutralized with 88 parts of concentrated hydrochloric acid. The resulting solution was concentrated, giving 164.8 parts of sodium salt of difluorosulfoacetic acid (containing inorganic salt: 62.6% purity). 5.0 parts of the resulting sodium salt of difluorosulfoacetic acid, 2.6 parts of 4-oxo-1-adamantanol, and 100 parts of ethylbenzene were mixed, and 0.8 part of concentrated sulfuric acid was added thereto, and the resultant mixture was heated to reflux for 30 hours. The reaction mixture was cooled to room temperature, and filtered to obtain residue. The residue was washed with tert-butyl methyl ether, giving 5.5 parts of sodium salt of ((4-oxo-adamantyl)oxycarbonyl)difluoromethanesulfonic acid. ¹H-NMR analysis revealed a purity of 35.6%.

10.0 parts of the resulting sodium salt of ((4-oxo-adamantyl)oxycarbonyl)difluoromethanesulfonic acid was dissolved in a mixture of 30 parts of acetonitrile and 20 parts of ion-exchanged. To the obtained solution, a solution of 5.0 parts of 1-(2-oxo-2-phenylethyl)tetrahydrothiophenium bromide, 10 parts of acetonitrile, and 5 parts of ion-exchanged water was added. The resultant mixture was stirred for 15 hours, then concentrated, and extracted with 98 parts of chloroform to obtain an organic layer. The organic layer was washed with ion-exchanged water, and the resulting organic layer was concentrated. The concentrate was washed with 70 parts of ethyl acetate, giving 5.2 parts of 1-(2-oxo-2-phenylethyl)tetrahydrothiophenium ((4-oxo-1-adamantyl)oxycarbonyl)difluoromethanesulfonate (A4) as a white solid.

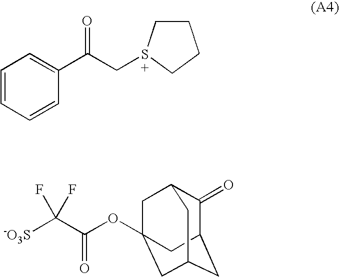

### Synthesis Example 5

### Acid Generator A5

10.4 parts of lithium aluminum hydride and 120 parts of tetrahydrofuran anhydride were mixed followed by stirring for 30 minutes at 23° C. Then, a solution obtained by dissolving 62.2 parts of sodium salt of ethyl difluoro(fluorosulfonyl)acetate in tetrahydrofuran anhydride was added thereto in the form of drops in an ice bath, and stirred for 5 hours at 23° C. To the reaction mixture, 50.0 parts of ethyl acetate and 50.0 parts of 6N hydrochloric acid were added, and the resulting mixture was stirred and separated to obtain an organic layer. The resulting organic layer was concentrated, and treated by column (Merck, silica gel 60, 200 mesh, developing solvent: chloroform/methanol=5/1), giving 84.7 parts of sodium salt of 2,2-difluoro-2-sulfoethanol (60.0% purity).

4.5 parts of 4-oxoadamantane-1-carboxylic acid was added to 90 parts of tetrahydrofuran anhydride, and dissolved by stirring at room temperature for 30 minutes. To this solution, a mixture of 3.77 parts of carbonyldiimidazol and 45 parts of tetrahydrofuran anhydride was added in the form of drops at room temperature, stirred for 4 hours at 23° C. The resulting solution was added to a mixture of 7.87 parts of sodium salt of 2,2-difluoro-2-sulfoethanol and 50 parts of tetrahydrofuran anhydride at 54 to 60° C. for 30 minutes in the form of drops. The mixture was heated at 65° C. for 18 hours, cooled, and then f filtrated. The resulting filtrate was concentrated, the concentrate was isolated by column (Merck, silica gel 60, 200 mesh, developing solvent: chloroform/methanol=5/1), giving 4.97 parts of sodium salt of 2-((4-oxo-1-adamantyl)carbonyloxy)-1,1-difluoroethanesulfonic acid (yield: 59%).

Then, 1.0 part of sodium salt of 2-((4-oxo-1-adamantyl)carbonyloxy)-1,1-difluoroethanesulfonic acid and 20 part of chloroform were mixed, stirred for 30 minutes at 23° C., and 6.3 parts of triphenylsulfonium chloride (13.1% solution) was added thereto at 23° C. The resulting solution was stirred for 12 hours at room temperature, and separated to obtain an organic layer. To the obtained organic layer, 10 parts of ion-exchanged water was added, and washed. This washing was repeated 3 times to the obtained solution, and 1 part of magnesium sulfate was added thereto, and stirred for 30 minutes at 23° C., and f filtrated. The filtrate was concentrated, giving 1.36 parts of a compound (A5).

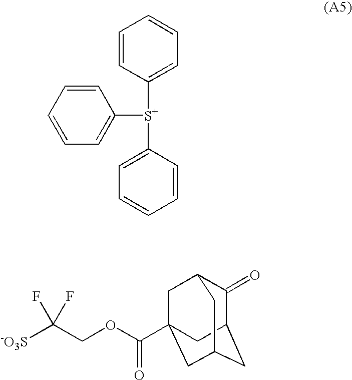

### Synthesis Example 6

### Acid Generator A6

3.51 parts of 3-hydroxyadamanthane-1-carboxylic acid and 75 parts of tetrahydrofuran anhydride were mixed, and stirred for 30 minutes at 23° C. To this, a mixture solution of 2.89 parts of carbonyldiimidazol and 50 parts of tetrahydrofuran anhydride was added in the form of drops at 23° C., stirred for 4 hours at 23° C. The solution was added to a mixture of 6.04 parts of sodium salt of 2,2-difluoro-2-sulfoethanol (60% purity) and 50 parts of tetrahydrofuran anhydride at 54° C. to 60° C. for 25 minutes in the form of drops. The resulting solution was heated at 65° C. for 18 hours, cooled, and then filtered. The resulting filtrate was concentrated, the concentrate was isolated by column (Merck, silica gel 60, 200 mesh, developing solvent: chloroform/methanol=5/1), giving 2.99 parts of sodium salt of 2-((3-hydroxy-1-adamantyl)carbonyloxy)-1,1-difluoroethanesulfonic acid.

Then, 1.0 part of sodium salt of 2-((3-hydroxy-1-adamantyl)carbonyloxy)-1,1-difluoroethanesulfonic acid and 30 part of chloroform were mixed, stirred for 30 minutes at 23° C., and 6.3 parts of triphenylsulfonium chloride (13.1% solution) was added thereto. The resulting solution was stirred for 12 hours at 23° C., and separated to obtain an organic layer. To the obtained organic layer, 10 parts of ion-exchanged water was added to wash. This washing was repeated 3 times. To the obtained solution, 1 part of magnesium sulfate was added, and the mixture was stirred for 30 minutes at 23° C., and filtrated. The filtrate was concentrated, giving 1.6 parts of a compound (A6).

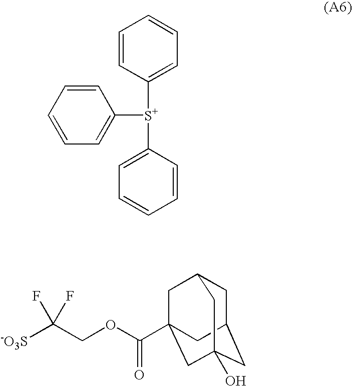

### Synthesis Example 7

### Acid Generator A7

1.0 parts of 5-(hydroxymethyl)-2-adamantanone ethylene acetal, 2.47 parts of pyridine, and 5 parts of methylene chloride anhydride were mixed, and stirred for 30 minutes at 23° C. To this, a solution of 2.37 parts of trifluoromethanesulfonic acid anhydride and 5 parts of methylene chloride anhydride was added in the form of drops under ice cooling, the mixture was stirred for 2 hours at 3° C. to 5° C. To the reacted solution, a mixture solution of 10 parts of methylene chloride and 10 parts of ion-exchanged water was added to wash. This washing was repeated 3 times. To the obtained solution, 1 part of magnesium sulfate was added, and the mixture was stirred for 30 minutes at 23° C., and filtrated. The filtrate was concentrated, the obtained concentrate was isolated by column (Merck, silica gel 60, 200 mesh, developing solvent: hexane/ethyl acetate=1/1), giving 1.19 parts of 5-(trifluoromethanesulfonyloxymethyl)-2-adamantanone ethylene acetal.

0.2285 parts of sodium hydride and 3 parts of dimethyl sulfoxide anhydride were mixed, and stirred for 30 minutes at 60° C. To this solution, 0.62 parts of sodium salt of 2,2-difluoro-2-sulfoethanol was added, the mixture was stirred for 1 hour at 60° C. To this solution, a solution of 1.00 parts of 5-(trifluoromethanesulfonyloxymethyl)-2-adamantanone ethylene acetal and 9 parts of dimethyl sulfoxide was added in the form of drops, and the mixture was stirred for 5 hours 60° C. After cooling, the reaction mixture was treated by column (Merck, silica gel 60, 200 mesh, developing solvent: chloroform/methanol=5/1), giving 0.28 parts of sodium salt.

0.2 parts of the obtained sodium salt and 10 parts of chloroform were mixed, and stirred for 30 hours at 23° C. To this solution, 1.5 parts of triphenylsulfonium chloride (12.8% solution) was added, the mixture was stirred for 36 hours at 23° C., and separated to obtain an organic layer. To thus obtained organic layer, 10 parts of ion-exchanged water was added to wash. This washing was repeated 3 times. To the obtained solution, 1 part of magnesium sulfate was added, the mixture was stirred for 30 minutes at 23° C., and filtrated. The filtrate was concentrated, giving 0.24 parts of a compound (A7).

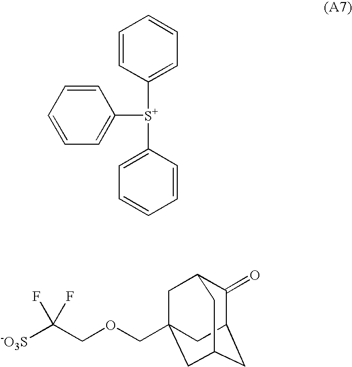

### Synthesis Example 8

### Acid generator A8

573.7 parts of triphenylsulfonium chloride (14.2% solution) and 300 parts of sodium salt of difluorosulfoacetic acid (18.0% solution) were mixed, stirred for about 20 hours at 25° C. A precipitated white solid was filtrated, washed with 100 parts of ion-exchanged water, and dried, giving 88.4 parts of triphenylsulfonium hydroxycarbonyldifluoromethanesulfonate.

9.5 parts of the obtained triphenylsulfonium hydroxycarbonyl difluoromethanesulfonate and 47.6 parts of N,N′-dimethylformamide were mixed, and 3.0 parts of potassium carbonate and 0.9 parts of potassium iodide were added thereto, the mixture was stirred for about 1 hour at 50° C., and then cooled at 40° C. To the obtained solution, a dissolving solution of 5 parts of hexahydro-2-oxo-3,5-methano-2H-cyclopenta[b]furan-6-yl chloroacetate and 40 parts of N,N′-dimethylformamide was added in the form of drops to react for 23 hours at 40° C. After reaction, the obtained reactant was cooled, 106 parts of chloroform and 106 parts of ion-exchanged water were added thereto, the mixture was stirred, and stood to separate a water layer. The water layer was extracted with 106 parts of chloroform 2 times. The obtained organic layers were mixed, washed with ion-exchanged water to neutralize a water layer. To the organic layer was added 3.5 parts of activated carbon, the mixture was stirred, and filtered. The obtained mother liquor was concentrated, 38 parts of ethyl acetate was added thereto, the mixture was stirred, and a supernatant was removed. To the obtained residue was added 38 parts of tert-butyl methyl ether, and the mixture was stirred, and a supernatant was removed. To the obtained residue was dissolved in chloroform, and this solution was concentrate, giving 4.3 parts of a compound (A8) as orange oil.

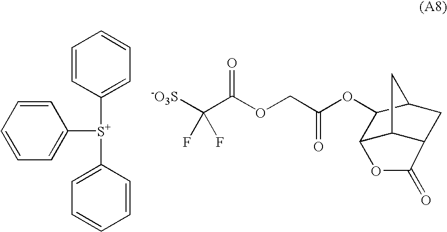

### Synthesis Example 9

### Acid Generator A9

To a mixture of 100 parts of methyl difluoro(fluorosulfonyl)acetate and 150 parts of ion-exchanged water, 230 parts of 30% sodium hydroxide aqueous solution was added in the form of drops in an ice bath. The resultant mixture was refluxed for 3 hours at 100° C., cooled, and then neutralized with 88 parts of concentrated hydrochloric acid. The resulting solution was concentrated, giving 164.4 parts of sodium salt of difluorosulfoacetic acid (containing inorganic salt: 62.7% purity). 1.0 parts of 1,1′-carbonyldiimidazol was added to 1.9 parts of the resulting sodium salt of difluorosulfoacetic acid and 9.5 parts of N,N-dimethylformamide, and the resultant mixture was stirred for 2 hours to obtain a mixture.

Also, 0.2 parts of sodium hydride was added to a mixture of 1.1 parts of (3-hydroxy-1-adamantyl)methanol and 5.5 parts of N,N-dimethylformamide, and the resultant mixture was stirred for 2 hours. To thus obtained solution, the above obtained mixture was added. The resulting mixture was stirred for 15 hours to obtain a solution containing sodium salt of ((3-hydroxy-1-adamantyl)methoxycarbonyl)difluorosulfonic acid.

To thus obtained solution containing sodium salt of ((3-hydroxy-1-adamantyl)methoxycarbonyl)difluorosulfonic acid, 17.2 parts of chloroform, 0.5 parts of tris(4-methylphenyl)sulfonium chloride and 2.5 parts of ion-exchanged water were added, the mixture was stirred for 15 hours, and separated to recover an organic layer. A residual water layer was extracted with 6.5 parts of chloroform to recover an organic layer. The obtained organic layers were mixed, washed with ion-exchanged water, and the resulting organic layer was concentrated, giving 0.15 parts of tris(4-methylphenyl)sulfonium ((3-hydroxy-1-adamantyl)methoxycarbonyl)difluoromethanesulfonate (A9).

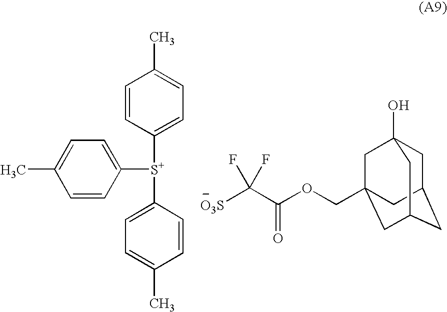

The monomers used in examples and the like below are follows.

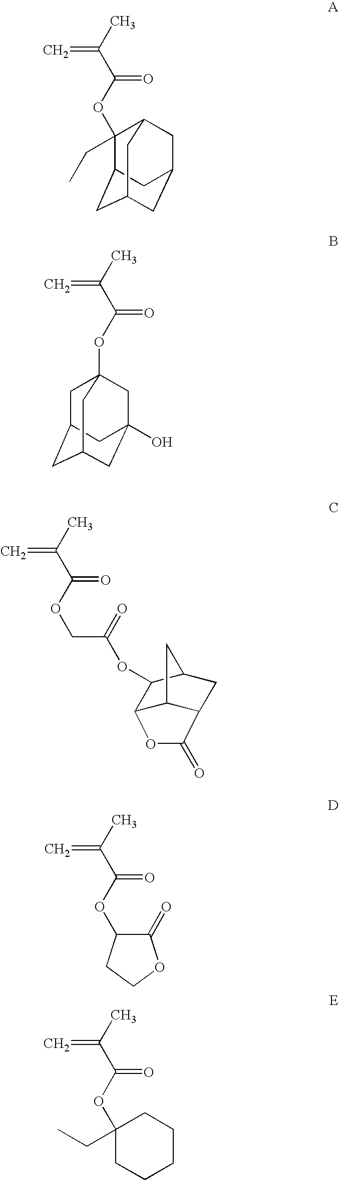

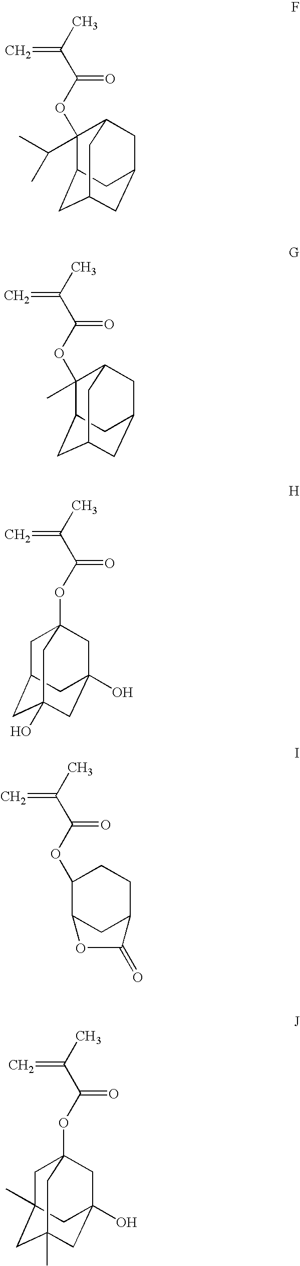

### Synthesis Example 10

### Resin B1

Monomer A, monomer H, monomer C and monomer D were mixed with molar ratio 40:10:20:30, and dioxane was added thereto in an amount equal to 1.5 weight times of the total amount of monomers. Azobisisobutyronitrile and azobis(2,4-dimethyl valeronitrile) was added as an initiator thereto in an amount of 1 mol % and 3 mol % respectively with respect to the entire amount of monomers, and the resultant mixture was heated for about 5 hours at 78° C. After that, the reaction solution was poured into a mixture of methanol and ion-exchanged water in large amounts to precipitate. These operations were repeated 3 times for purification, giving 73% yield of copolymer having a weight average molecular weight of about 8500. This copolymer, which had the structural units derived from the monomers of the following formulae, was designated Resin B 1.

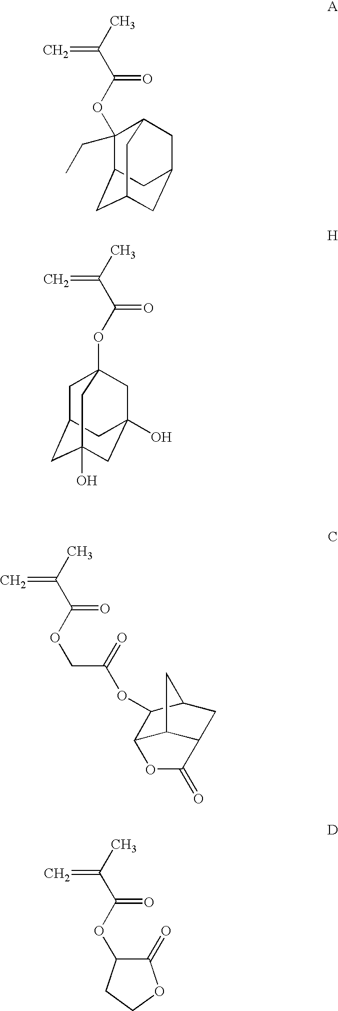

### Synthesis Example 11

### Resin B2

Monomer F, monomer E, monomer H, monomer C and monomer D were mixed with molar ratio 30:15:5:20:30, and dioxane was added thereto in an amount equal to 1.5 weight times of the total amount of monomers. Azobisisobutyronirrile and azobis(2,4-dimethylvaleronitrile) was added as an initiator thereto in an amount of 1 mol % and 3 mol % respectively with respect to the entire amount of monomers, and the resultant mixture was heated for about 5 hours at 73° C. After that, the reaction solution was poured into a mixture of methanol and ion-exchanged water in large amounts to precipitate. These operations were repeated 3 times for purification, giving 73% yield of copolymer having a weight average molecular weight of about 8500. This copolymer, which had the structural units derived from the monomers of the following formulae, was designated Resin B2.

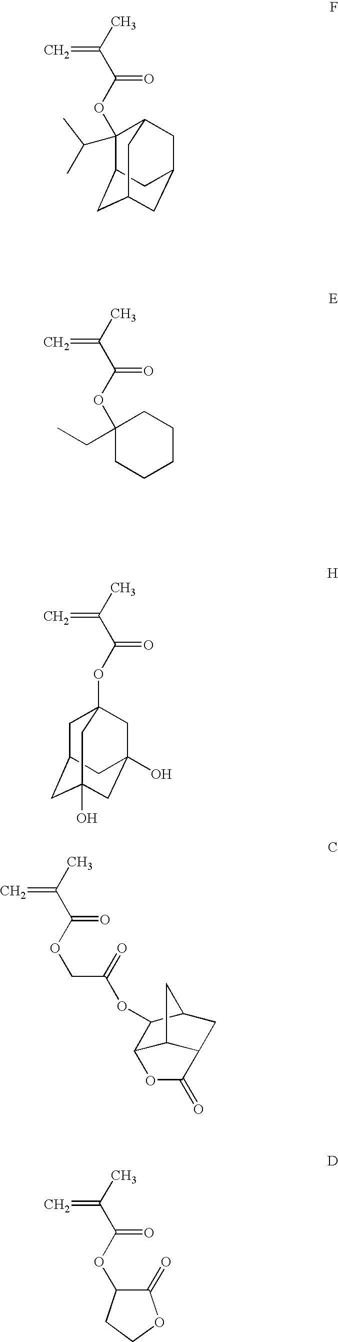

### Synthesis Example 12

### Resin B3

Monomer F, monomer G, monomer H, monomer C and monomer D were mixed with molar ratio 30:15:5:20:30, and dioxane was added thereto in an amount equal to 1.5 weight times of the total amount of monomers. Azobisisobutyronitrile and azobis(2,4-dimethyl valeronitrile) was added as an initiator thereto in an amount of 1 mol % and 3 mol % respectively with respect to the entire amount of monomers, and the resultant mixture was heated for about 5 hours at 73° C. After that, the reaction solution was poured into a mixture of methanol and ion-exchanged water in large amounts to precipitate. These operations were repeated 3 times for purification, giving 74% yield of copolymer having a weight average molecular weight of about 8200. This copolymer, which had the structural units derived from the monomers of the following formulae, was designated Resin B3.

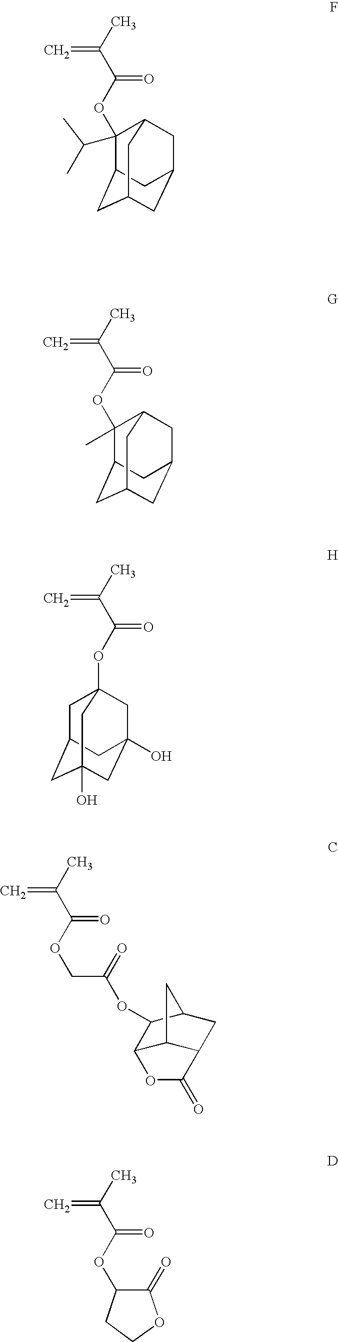

### Synthesis Example 13

### Resin B4

Monomer F, monomer E, monomer H and monomer C were mixed with molar ratio 40:10:10:40, and dioxane was added thereto in an amount equal to 1.2 weight times of the total amount of monomers. Azobisisobutyronitrile and azobis(2,4-dimethyl valeronitrile) was added as an initiator thereto in an amount of 1 mol % and 3 mol % respectively with respect to the entire amount of monomers, and the resultant mixture was heated for about 5 hours at 75° C. After that, the reaction solution was poured into a mixture of methanol and ion-exchanged water in large amounts to precipitate. These operations were repeated 3 times for purification, giving 74% yield of copolymer having a weight average molecular weight of about 7400. This copolymer, which had the structural units derived from the monomers of the following formulae, was designated Resin B4.

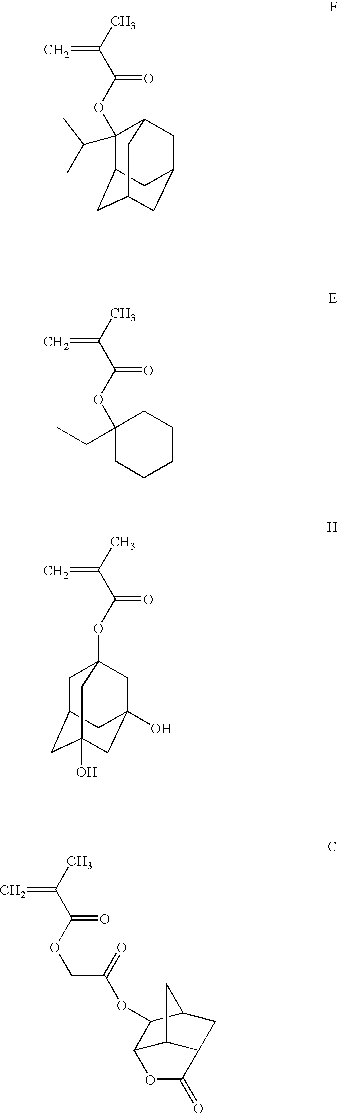

### Synthesis Example 14

### Resin B5

Monomer F, monomer E, monomer B, monomer H and monomer C were mixed with molar ratio 35:10:10:5:40, and dioxane was added thereto in an amount equal to 1.2 weight times of the total amount of monomers. Azobisisobutyronitrile and azobis(2,4-dimethyl valeronitrile) was added as an initiator thereto in an amount of 1 mol % and 3 mol % respectively with respect to the entire amount of monomers, and the resultant mixture was heated for about 5 hours at 75° C. After that, the reaction solution was poured into a mixture of methanol and ion-exchanged water in large amounts to precipitate. These operations were repeated 3 times for purification, giving 74% yield of copolymer having a weight average molecular weight of about 7400. This copolymer, which had the structural units derived from the monomers of the following formulae, was designated Resin B5.

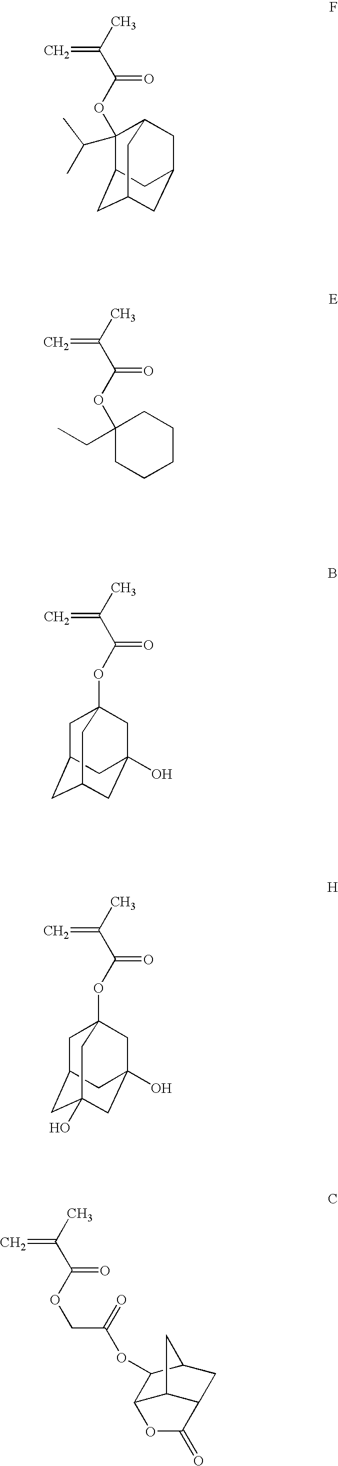

### Synthesis Example 15

### Resin B6

Monomer A, monomer B and monomer D were mixed with molar ratio 50:25:25, and dioxane was added thereto in an amount equal to 1.5 weight times of the total amount of monomers. Azobisisobutyronitrile and azobis(2,4-dimethyl valeronitrile) was added as an initiator thereto in an amount of 1 mol % and 3 mol % respectively with respect to the entire amount of monomers, and the resultant mixture was heated for about 5 hours at 77° C. After that, the reaction solution was poured into a mixture of methanol and ion-exchanged water in large amounts to precipitate. These operations were repeated 3 times for purification, giving 60% yield of copolymer having a weight average molecular weight of about 8000. This copolymer, which had the structural units derived from the monomers of the following formulae, was designated Resin B6.

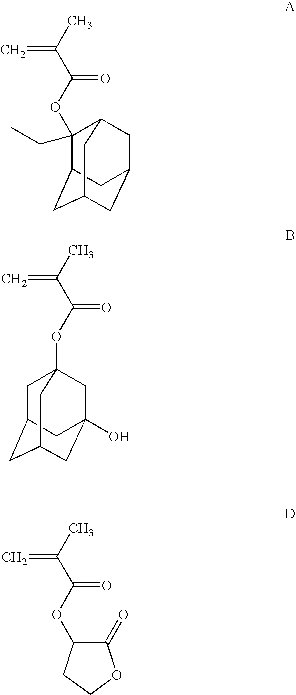

### Synthesis Example 16

### Resin B7

Monomer A, monomer H and monomer D were mixed with molar ratio 50:15:35, and dioxane was added thereto in an amount equal to 1.5 weight times of the total amount of monomers. Azobisisobutyronitrile and azobis(2,4-dimethyl valeronitrile) was added as an initiator thereto in an amount of 1 mol % and 3 mol % respectively with respect to the entire amount of monomers, and the resultant mixture was heated for about 5 hours at 76° C. After that, the reaction solution was poured into a mixture of methanol and ion-exchanged water in large amounts to precipitate. These operations were repeated 3 times for purification, giving 65% yield of copolymer having a weight average molecular weight of about 8500. This copolymer, which had the structural units derived from the monomers of the following formulae, was designated Resin B7.

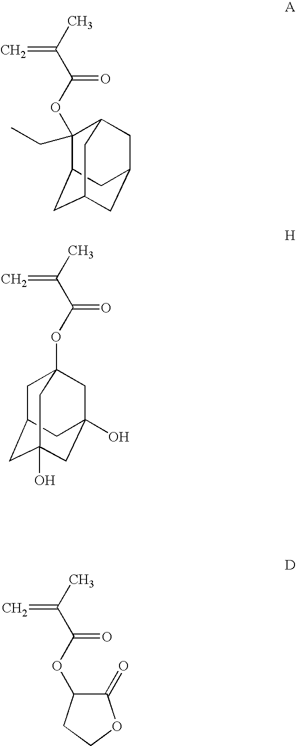

### Synthesis Example 17

### Resin B8

Monomer A, monomer D, monomer H and monomer J were mixed with molar ratio 40:25:8:27, and dioxane was added thereto in an amount equal to 1.2 weight times of the total amount of monomers. Azobisisobutyronitrile and azobis(2,4-dimethyl valeronitrile) was added as an initiator thereto in an amount of 1 mol % and 3 mol % respectively with respect to the entire amount of monomers, and the resultant mixture was heated for about 5 hours at 70° C. After that, the reaction solution was poured into a mixture of methanol and ion-exchanged water in large amounts to precipitate. These operations were repeated 3 times for purification, giving 65% yield of copolymer having a weight average molecular weight of about 10000. This copolymer, which had the structural units derived from the monomers of the following formulae, was designated Resin B8.

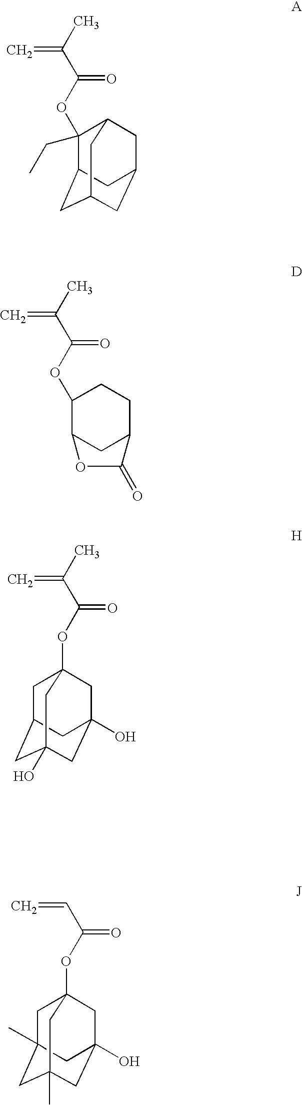

### Working Examples 1 Through 15, Comparative Examples 1 and 2, Reference Examples 1 and 2

Resist compositions were prepared by mixing and dissolving each of the components shown in Table 1, and then filtering through a fluororesin filter having 0.2 μm pore diameter.

TABLE 1

| | Acid generator | Resin | Quencher | PB/PEB |
|---|---|---|---|---|
| | (parts) | (parts) | (parts) | (° C.) |
| Ex. 1 | A1/0.70 | B1/10 | Q1/0.065 | 95/95 |
| Ex. 2 | A1/0.70 | B2/10 | Q1/0.065 | 95/95 |
| Ex. 3 | A1/0.70 | B3/10 | Q1/0.065 | 95/95 |
| Ex. 4 | A1/0.70 | B4/10 | Q1/0.065 | 95/95 |
| Ex. 5 | A1/0.70 | B5/10 | Q1/0.065 | 95/95 |
| Ex. 6 | A1/0.70 | B7/10 | Q1/0.065 | 95/95 |
| Ex. 7 | A1/0.70 | B8/10 | Q1/0.065 | 95/95 |
| Ex. 8 | A2/0.50 | B1/10 | Q1/0.065 | 95/95 |
| Ex. 9 | A3/0.45 | B1/10 | Q1/0.065 | 95/95 |
| Ex. 10 | A4/1.45 | B1/10 | Q1/0.065 | 95/95 |
| Ex. 11 | A5/0.70 | B2/10 | Q1/0.065 | 95/95 |
| Ex. 12 | A6/0.70 | B2/10 | Q1/0.065 | 95/95 |
| Ex. 13 | A7/0.70 | B2/10 | Q1/0.065 | 95/95 |
| Ex. 14 | A8/0.70 | B2/10 | Q1/0.065 | 95/95 |
| Ex. 15 | A9/0.90 | B2/10 | Q1/0.065 | 95/95 |
| Comp. Ex. 1 | A1/0.27 | B6/10 | Q1/0.0325 | 130/130 |
| Comp. Ex. 2 | C2/C3 = 0.10/0.15 | B8/10 | Q2/0.020 | 140/120 |
| Ref. Ex. 1 | C1/0.7 | B1/10 | Q1/0.065 | 95/95 |
| Ref. Ex. 2 | C1/0.3 | B1/10 | Q1/0.065 | 95/95 |

<Acid Generator>
A1 to A9: Acid Generators synthesized in Synthesis Exs. 1 to 9,
C1: triphenylsulfonium pentafluoroethanesulfonate,
C2: triphenylsulfonium perfluorooctanesulfonate,
C3: 1-(2-oxo-2-phenylethyl) tetrahydrothiophenium
perfluorobutanesulfonate,
<Resin>
B1 toB8: Resins synthesized in Synthesis Exs. 10 to 17,
<Qencher>
Q1: 2,6-diisopropylaniline,
Q2: triphenylimidazole,
<Solvent>

| | |
|---|---|
| Propylene glycol monomethyl ether acetate | 145 parts |
| 2-Heptanone | 20 parts |
| Propylene glycol monomethyl ether | 20 parts |
| γ-butyrolactone | 3.5 parts |

A composition for an organic antireflective film (“ARC-29A-8”, by Nissan Chemical Co. Ltd.) was applied onto silicon wafers and baked for 60 seconds at 205° C. to form a 78 nm thick organic antireflective film.

The above resist liquids were then applied thereon by spin coating so that the thickness of the resulting film became 150 nm after drying.

The obtained wafers were then pre-baked for 60 sec on a direct hot plate at the temperatures given in the “PB” column in Table 1.

Line and space patterns were then exposed through stepwise changes in exposure quantity using an ArF excimer stepper (“FPA5000-AS3” by Canon: NA=0.75, ⅔ Annular), on the wafers on which the resist film had thus been formed.

The exposure was followed by 60 seconds of post-exposure baking at the temperatures given in the “PEB” column in Table 1.

This was followed by 60 sec of puddle development with 2.38 wt % tetramethylammonium hydroxide aqueous solution.

Table 2 gives the results of scanning electron microscopy of the developed dark field pattern on the organic antireflective film substrate.

The dark field pattern referred to here is a pattern in which the resist layer remains around the line and space pattern following exposure and development, as obtained by exposure and development through a reticle in which lines based on a chrome layer (light-blocking layer) were formed on the outside of a glass surface (the component through which the light is transmitted).

Effective sensitivity: It was represented as the exposure amount at which a 100 nm line and space pattern resolved to 1:1.

Evaluation of Resolution: a resist pattern was exposed as the exposure amount at which a 100 nm line and space pattern resolved to 1:1 and the resist pattern was observed with a scanning electron microscope. With Comparative Example 1 as the standard (indicated with a Δ), these were evaluated with a ◯ for having more resolution than this, with a Δ for the same level, and with an X for not having as much resolution as this. Comparative Example 1 had a resolution of 90 nm, but a skirt was observed in taper shapes.

Line Edge Roughness (LER) Evaluation: the wall surface of the resist pattern after a lithography process was observed with a scanning electron microscope, and with Comparative Example 1 as the standard (indicated with a Δ), these were evaluated with a ◯ for being smoother than this, with a Δ for the same level, and with an X for not being smoother than this.

Pattern Collapse Evaluation: a 100 nm line and space pattern was exposed to light with a 1:1 exposure and the photoresist pattern was observed with a scanning electron microscope. Comparative Example 1 was the standard (indicated with a Δ), and compared to this, these were evaluated with a ◯ when the pattern was better maintained, with a Δ when it was the same, and with an X when the pattern was not maintained as well.

TABLE 2

| | Effective sensitivity | | | Pattern |
|---|---|---|---|---|
| | (mJ/cm²) | Resolution | LER | Collapse |
| Ex. 1 | 43 | ◯ | ◯ | ◯ |
| Ex. 2 | 45 | ◯ | ◯ | ◯ |
| Ex. 3 | 44 | ◯ | ◯ | ◯ |
| Ex. 4 | 43 | ◯ | ◯ | ◯ |
| Ex. 5 | 42 | ◯ | ◯ | ◯ |
| Ex. 6 | 31 | ◯ | Δ | Δ |
| Ex. 7 | 34 | ◯ | ◯ | ◯ |
| Ex. 8 | 35 | ◯ | ◯ | ◯ |
| Ex. 9 | 34 | ◯ | ◯ | ◯ |
| Ex. 10 | 35 | ◯ | ◯ | ◯ |
| Ex. 11 | 42 | ◯ | ◯ | ◯ |
| Ex. 12 | 46 | ◯ | ◯ | ◯ |
| Ex. 13 | 43 | ◯ | ◯ | ◯ |
| Ex. 14 | 41 | ◯ | ◯ | ◯ |
| Ex. 15 | 42 | ◯ | ◯ | ◯ |
| Comp. Ex. 1 | 33 | Δ | Δ | Δ |
| Comp. Ex. 2 | 35 | ◯ | X | X |
| Ref. Ex. 1 | 15 | X | X | X |
| Ref. Ex. 2 | 36 | Δ | X | X |

Since the chemically amplified photoresist composition of the present invention maintains the high resolution as is, provides better line and edge roughness, and remedies pattern collapse when it is used to form a pattern, it can be used as a suitable chemically amplified photoresist composition for excimer laser lithography such as with ArF, KrF or the like, as well as ArF liquid immersion exposure lithography. Moreover, in addition to liquid immersion exposure, it can also be used in dry exposure. Furthermore, it can also be used in double imaging, and has industrial utility.

This application claims priority to Japanese Patent Application No. 2009-26231. The entire disclosure of Japanese Patent Application No. 2009-26231 is hereby incorporated herein by reference.

What is claimed is:

1. A chemically amplified photoresist composition, comprising:
an acid generator (A) represented by the formula (I), and
a resin which comprises
a structural unit (b1) derived from a monomer that becomes soluble in an alkali by an action of an acid,
a structural unit (b2) derived from a monomer that has an adamantyl group having at least two hydroxyl groups, and
a structural unit (b3) derived from a monomer that has a lactone ring, 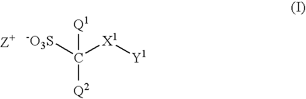
wherein Q¹ and Q² independently represent a fluorine atom or a C₁ to C₆ perfluoroalkyl group;
X¹ represents a single bond or —[CH₂]ₖ—, a —CH₂— contained in the —[CH₂]ₖ— may be replaced by —O— or —CO, and a hydrogen atom contained in the —[CH₂]ₖ— may be replaced by a C₁ to C₄ aliphatic hydrocarbon group;
k represents an integer 1 to 17;
Y¹ represents an optionally substituted C₄ to C₃₆ saturated cyclic hydrocarbon group, and a —CH₂— contained in the saturated cyclic hydrocarbon group may be replaced by —O— or —CO; and
Z⁺ represents an organic cation.

2. The chemically amplified photoresist composition of claim 1, wherein the structural unit (b1) derived from a monomer that becomes soluble in an alkali by the action of the acid represents a structural unit represented by the formula (II); 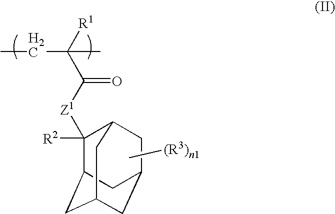
wherein Z¹ represents a single bond or —[CH₂]ₖ₁—, and a —CH₂— contained in the —[CH₂]ₖ₁— may be replaced by —CO—, —O—, —S— or —N[R^{C1}]—;
k1 represents an integer 1 to 17;
R^{c1} represents a hydrogen atom or a C₁ to C₆ aliphatic hydrocarbon group;
R¹ represents a hydrogen atom or a methyl group;
R² represents a C₁ to C₆ aliphatic hydrocarbon group;
R³ represents a methyl group; and
n1 represents an integer 0 to 14.

3. The chemically amplified photoresist composition of claim 2, wherein the monomer from which the structural unit represented by the formula (II) is derived is 2-methyl-2-adamantylacrylate, 2-methyl-2-adamantylmethacrylate, 2-ethyl-2-adamantylacrylate, 2-ethyl-2-adamantylmethacrylate, 2-isopropyl-2-adamantylacrylate or 2-isopropyl-2-adamantylmethacrylate.

4. The chemically amplified photoresist composition of claim 1, wherein the structural unit (b2) derived from a monomer that has an adamantyl group having at least two hydroxyl groups represents a structural unit represented by the formula (III); 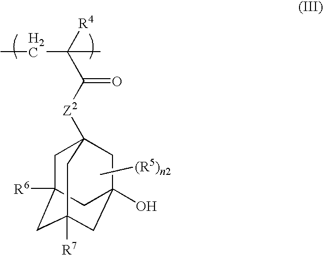
wherein R⁴ represents a hydrogen atom or a methyl group;
R⁵ represents a methyl group;
R⁶ and R⁷ independently represent a hydrogen atom, a methyl group or a hydroxyl group, provided that at least one of either R⁶ and R⁷ represents a hydroxyl group;
n2 represents an integer 0 to 10;
Z² represents a single bond or —[CH₂]ₖ₂—, and a —CH₂— contained in the —[CH₂]ₖ₂— may be replaced by —CO—, —O—, —S— or —N[R^{C2}]—;
k2 represents an integer 1 to 17.
R^{c2} represents a hydrogen atom or a C₁ to C₆ aliphatic hydrocarbon group.

5. The chemically amplified photoresist composition of claim 4, wherein the monomer from which the structural unit represented by the formula (III) is derived is 3,5-dihydroxy-1-adamantyl acrylate or 3,5-dihydroxy-1-adamantyl methacrylate.

6. The chemically amplified photoresist composition of claim 1, wherein the structural unit (b3) derived from a monomer that has a lactone ring represents a structural unit represents by the formula (IVa), the formula (IVb) or the formula (IVc); 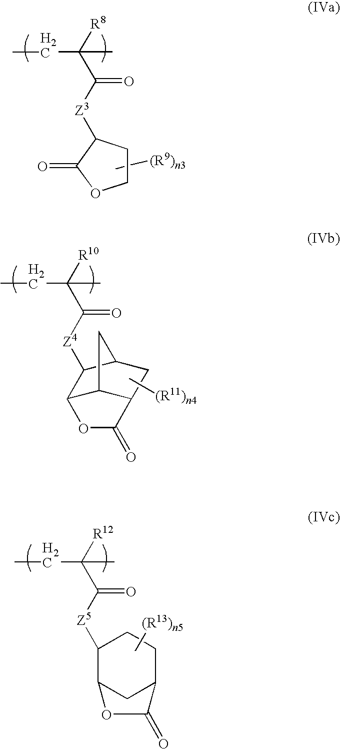
wherein R⁸, R¹⁰ and R¹² independently represent a hydrogen atom or a methyl group;
R⁹ represents a methyl group;
n3 represents an integer 0 to 5,
R¹¹ and R¹³ is independently in each occurrence a carboxy group, a cyano group or a C₁ to C₄ hydrocarbon group;
n4 and n5 represent an integer 0 to 3,
Z³, Z⁴ and Z⁵ independently represent a single bond or —[CH₂]ₖ₃—, and a —CH₂-contained in the —[CH₂]ₖ₃— may be replaced by —CO—, —O—, —S— or —N[R^{C3}]—;
k3 represents an integer 1 to 8;
R^{c3} represents a hydrogen atom or a C₁ to C₆ aliphatic hydrocarbon group.

7. The chemically amplified photoresist composition of claim 1, wherein the Y¹ of the formula (I) is a group represented by the formula (Y1). 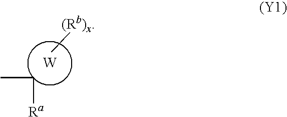
wherein ring W represents a C₃ to C₃₆ saturated cyclic hydrocarbon group, and a —CH₂— contained in the saturated cyclic hydrocarbon group may be replaced by —O— or —CO— group;
R^{a} represents a hydrogen atom or a C₁ to C₆ hydrocarbon group;
R^{b} is independently in each occurrence halogen atom, a C₁ to C₁₂ aliphatic hydrocarbon group, a C₆ to C₂₀ aromatic hydrocarbon group, a C₇ to C₂₁ aralkyl group, a glycidoxy group or a C₂ to C₄ acyl group; and,
x represents an integer 0 to 8.

8. The chemically amplified photoresist composition of claim 1, wherein the Z⁺ of the formula (I) is an arylsulfonium cation.

9. The chemically amplified photoresist composition of claim 1, wherein the anion of the formula (I) is an anion having an adamantane structure, an oxoadamantane structure or a cyclohexane structure.

10. The chemically amplified photoresist composition of claim 1, wherein the content of the acid generator is adjusted to within a range of 1 to 20 parts by weight with respect to the 100 parts by weight of the resin.

11. The chemically amplified photoresist composition of claim 1, which further contains a nitrogen-containing basic compoundd.

12. The chemically amplified photoresist composition of claim 11, which the nitrogen-containing basic compound is diisopropylaniline.

13. A method for forming pattern comprising steps of;
(1) applying the chemically amplified photoresist composition of claim 1 onto a substrate;
(2) removing solvent from the applied composition to form a composition layer;
(3) exposing to the composition layer using a exposure device;
(4) heating the exposed composition layer and,
(5) developing the heated composition layer using a developing apparatus.
